(19) United States
(12) Patent Application Publication
(10) Pub. No.: US 2023/0002676 A1
(43) Pub. Date: Jan. 5, 2023

(54) TREATMENT LIQUID AND TREATMENT LIQUID CONTAINER

(71) Applicant: FUJIFILM Corporation, Tokyo (JP)

(72) Inventor: Yasuo SUGISHIMA, Haibara-gun (JP)

(73) Assignee: FUJIFILM Corporation, Tokyo (JP)

(21) Appl. No.: 17/900,008

(22) Filed: Aug. 31, 2022

Related U.S. Application Data
(63) Continuation of application No. PCT/JP2021/004398, filed on Feb. 5, 2021.

(30) Foreign Application Priority Data
Mar. 4, 2020 (JP) 2020-036859

(51) Int. Cl. C09K 13/10; B65D 51/16

(52) U.S. Cl. CPC C09K 13/10; B65D 51/1644; H01L 21/30604

(57) ABSTRACT

The present invention provides a treatment liquid exhibiting excellent selectivity in dissolving SiGe in a case where the SiGe is etched with the treatment liquid. The present invention also provides a treatment liquid container relating to the treatment liquid.

The treatment liquid according to an embodiment of the present invention contains a fluoride ion source, an oxidant, an acetate solvent, and an additive, in which the additive is an additive that does not contain a Si atom.

### CROSS-REFERENCE TO RELATED APPLICATIONS

This application is a Continuation of PCT International Application No. PCT/JP2021/004398 filed on Feb. 5, 2021, which claims priority under 35 U.S.C. § 119(a) to Japanese Patent Application No. 2020-036859 filed on Mar. 4, 2020. Each of the above applications is hereby expressly incorporated by reference, in its entirety, into the present application.

### BACKGROUND OF THE INVENTION

### 1. Field of the Invention

The present invention relates to a treatment liquid and a treatment liquid container.

### 2. Description of the Related Art

With the progress of miniaturization of semiconductor devices, the treatment in the semiconductor device manufacturing process, such as etching or washing using treatment liquids, is increasingly required to be more accurately performed with high efficiency.

For example, U.S. Pat. No. 10,414,978B discloses an etching composition containing peracetic acid, a fluorine compound, an acetate-based organic solvent, and 0.01% to 5% by mass of a predetermined silicon compound.

### SUMMARY OF THE INVENTION

As a result of evaluating the treatment liquid (etchant) described in U.S. Pat. No. 10,414,978B, the inventors of the present invention have found that there is room for improving the selectivity in dissolving silicon-germanium (SiGe) obtained after an etching treatment is performed on SiGe by using the treatment liquid.

The present invention has been accomplished in consideration of the above circumstances, and an object thereof is to provide a treatment liquid that exhibits excellent selectivity in dissolving SiGe in a case where SiGe is etched with the treatment liquid.

Another object of the present invention is to provide a treatment liquid container relating to the treatment liquid.

In order to achieve the above objects, the inventors of the present invention conducted intensive studies. As a result, the inventors have found that the objects can be achieved by the following constitutions.

[1]

A treatment liquid containing a fluoride ion source,

an oxidant,

an acetate solvent, and

an additive,

in which the additive is an additive that does not contain a Si atom.

[2]

The treatment liquid described in [1], in which the additive is one or more kinds of substances selected from the group consisting of a nonionic polymer, an anionic polymer, a nonionic surfactant, an anionic surfactant, a cationic surfactant, an amphoteric surfactant, a nitrogen atom-containing polymer, alkylamine, aromatic amine, alkanolamine, and a nitrogen-containing heterocyclic compound, an organic carboxylic acid, a quaternary ammonium salt, and a boron-containing compound.

[3]

The treatment liquid described in [2], in which the additive contains the nonionic polymer, and

the nonionic polymer is one or more kinds of polymers selected from the group consisting of polyethylene glycol, polypropylene glycol, polyoxyethylene polyoxypropylene glycol, and polyvinyl alcohol.

[4]

The treatment liquid described in [2] or [3], in which the additive contains the anionic polymer, and

the anionic polymer is one or more kinds of polymers selected from the group consisting of polyacrylic acid, polystyrene sulfonic acid, a phenolsulfonic acid formaldehyde condensate, an aryl phenolsulfonic acid formaldehyde condensate, and salts of these.

[5]

The treatment liquid described in any one of [2] to [4], in which the additive contains the nitrogen atom-containing polymer, and

the nitrogen atom-containing polymer is one or more kinds of polymers selected from the group consisting of polyvinylpyrrolidone, polyethyleneimine, polyallylamine, polyvinylamine, polyacrylamide, a dimethylamine.epihalohydrin-based polymer, a hexadimethrine salt, polydiallylamine, a polydimethyldiallylammonium salt, poly(4-vinylpyridine), polyornithine, polylysine, polyarginine, polyhistidine, polyvinylimidazole, and polymethyldiallylamine.

[6]

The treatment liquid described in any one of [2] to [5], in which the additive contains the nonionic surfactant, and

the nonionic surfactant is one or more kinds of compounds selected from the group consisting of polyoxyethylene alkyl ether and polyoxyethylene alkyl allyl ether.

[7]

The treatment liquid described in any one of [2] to [6], in which the additive contains the anionic surfactant, and

the anionic surfactant is one or more kinds of compounds selected from the group consisting of alkyl benzenesulfonic acid, alkyl naphthalenesulfonic acid, alkyl diphenyl ether disulfonic acid, polyoxyethylene alkyl ether sulfonic acid, alkyl carboxylic acid, polyoxyethylene alkyl ether carboxylic acid, alkyl phosphonic acid, polyoxyethylene phosphonic acid, polyoxyethylene alkyl ether phosphoric acid, polyoxyethylene alkyl phenyl ether phosphoric acid, and salts of these.

[8]

The treatment liquid described in [7], in which the anionic surfactant contains at least any of the alkyl benzenesulfonic acid and a salt thereof, and

the alkyl benzenesulfonic acid is dodecyl benzenesulfonic acid.

[9]

The treatment liquid described in [7] or [8], in which the anionic surfactant contains at least any of the alkyl naphthalenesulfonic acid and a salt thereof, and

the alkyl naphthalenesulfonic acid is one or more kinds of compounds selected from the group consisting of propyl naphthalenesulfonic acid, triisopropyl naphthalenesulfonic acid, and dibutyl naphthalenesulfonic acid.

[10]

The treatment liquid described in any one of [7] to [9], in which the anionic surfactant contains at least any of the alkyl diphenyl ether disulfonic acid and a salt thereof, and the alkyl diphenyl ether disulfonic acid is dodecyl diphenyl ether disulfonic acid.

[11]

The treatment liquid described in any one of [7] to [10], in which the anionic surfactant contains at least any of the polyoxyethylene alkyl ether sulfonic acid and a salt thereof, and

the polyoxyethylene alkyl ether sulfonic acid is one or more kinds of compounds selected from the group consisting of polyoxyethylene lauryl ether sulfonic acid, polyoxyethylene oleyl ether sulfonic acid, and polyoxyethylene octyldodecyl ether sulfonic acid.

[12]

The treatment liquid described in any one of [7] to [11], in which the anionic surfactant contains at least any of the alkyl carboxylic acid and a salt thereof, and

the alkyl carboxylic acid is one or more kinds of compounds selected from the group consisting of dodecanoic acid, hexadecanoic acid, oleic acid, juniperic acid, stearic acid, 12-hydroxystearic acid, perfluorooctanoic acid, perfluoroheptanoic acid, and perfluorodccanoic acid.

[13]

The treatment liquid described in any one of [7] to [12], in which the anionic surfactant contains at least any of the polyoxyethylene alkyl ether carboxylic acid and a salt thereof, and

the polyoxyethylene alkyl ether carboxylic acid is one or more kinds of compounds selected from the group consisting of polyoxyethylene lauryl ether carboxylic acid, polyoxyethylene dodecyl ether carboxylic acid, and polyoxyethylene tridecyl ether carboxylic acid.

[14]

The treatment liquid described in any one of [7] to [13], in which the anionic surfactant contains at least any of the alkyl phosphonic acid and a salt thereof, and

the alkyl phosphonic acid is one or more kinds of compounds selected from the group consisting of bis(2-ethylhexyl)phosphate, dioctadecylphosphate, octadecylphosphate, dodecylphosphate, decyl phosphonic acid, dodecyl phosphonic acid, tetradecyl phosphonic acid, hexadecyl phosphonic acid, and octadecyl phosphonic acid.

[15]

The treatment liquid described in any one of [7] to [14], in which the anionic surfactant contains at least any of the polyoxyethylene alkyl ether phosphoric acid and a salt thereof, and

the polyoxyethylene alkyl ether phosphoric acid is polyoxyethylene lauryl ether phosphoric acid.

[16]

The treatment liquid described in any one of [2] to [15], in which the additive contains the cationic surfactant, and

the cationic surfactant is one or more kinds of compounds among a hydroxide, a chloride, and a bromide of one or more kinds of compounds selected from the group consisting of cetyltrimethylammonium, stearyltrimethylammonium, laurylpyridinium, cetylpyridinium, 4-(4-diethylaminophenylazo)-1-(4-nitrobenzyl)pyridinium, benzalkonium, benzethonium, benzyldimethyldodecylammonium, benzyldimethylhexadecylammonium, hexadecyltrimethylammonium, dimethyldioctadecylammonium, dodecyltrimethylammonium, didodecyldimethylammonium, tetraheptylammonium, tetrakis(decyl)ammonium, and dimethyldihexadecylammonium.

[17]

The treatment liquid described in any one of [2] to [16], in which the additive contains the amphoteric surfactant, and

the amphoteric surfactant is one or more kinds of compounds selected from the group consisting of cocamidopropyl betaine, N,N-dimethyldodecylamine N-oxide, lauryl dimethylaminoacetic acid betaine, and lauryldimethylamine oxide.

[18]

The treatment liquid described in any one of [2] to [17], in which the additive contains the alkylamine, and

the alkylamine is one or more kinds of compounds selected from the group consisting of ethylenediamine, diethylenetriamine, triethylenetetramine, tetraethylenepentamine, pentaethylenehexamine, tetramethylethylenediamine, hexamethylenediamine, methylamine, dimethylamine, trimethylamine, ethylamine, diethylamine, triethylamine, 2-ethylhexylamine, cyclohexylamine, phenethylamine, and m-xylylenediamine.

[19]

The treatment liquid described in any one of [2] to [18], in which the additive contains the aromatic amine, and

the aromatic amine is one or more kinds of compounds selected from the group consisting of aniline and toluidine.

[20]

The treatment liquid described in any one of [2] to [19], in which the additive contains the alkanolamine, and

the alkanolamine is one or more kinds of compounds selected from the group consisting of diethanolamine, diisopropanolamine, triisopropanolamine, 2-(2-aminoethylamino)ethanol, 2-(2-aminoethoxy)ethanol, triethanolamine, N-ethylethanolamine, N,N-dimethylethanolamine, N,N-diethylethanolamine, N-methyldiethanolamine, N-ethyldiethanolamine, cyclohexylamine diethanol, and N-methylethanolamine.

[21]

The treatment liquid described in any one of [2] to [20], in which the additive contains the nitrogen-containing heterocyclic compound, and

the nitrogen-containing heterocyclic compound is one or more kinds of compounds selected from the group consisting of pyrrolidine, piperidine, piperazine, morpholine, pyrrole, pyrazole, imidazole, pyridine, pyrimidine, pyrazine, oxazole, thiazole, and 4-dimethylaminopyridine.

[22]

The treatment liquid described in any one of [2] to [21], in which the additive contains the organic carboxylic acid, and

the organic carboxylic acid is one or more kinds of compounds selected from the group consisting of citric acid, 2-methylpropane-1,2,3-tricarboxylic acid, benzene-1,2,3-tricarboxylic acid, propane-1,2,3-tricarboxylic acid, 1,cis-2,3-propanetricarboxylic acid, butane-1,2,3,4-tetracarboxylic acid, cyclopentane tetra-1,2,3,4-carboxylic acid, benzene-1,2,4,5-tetracarboxylic acid, benzenepentacarboxylic acid, benzenehexacarboxylic acid, oxalic acid, malonic acid, succinic acid, glutaric acid, adipic acid, pimelic acid, suberic acid, azelaic acid, sebacic acid, ethylenediaminetetraacetic acid, butylenediaminetetraacetic acid, tetraacetic acid, diethylenetriaminepentaacetic acid, ethylenediaminetetrapropionic acid, (hydroxyethyl)ethylenediaminetriacetic acid, triethylenetetraminehexacetic acid, 1,3-diamino-2-hydroxypropane-N,N,N′,N′-tetraacetic acid, methyliminodiacetic acid, propylenediaminetetraacetic acid, nitrotriacetic acid, tartaric acid, gluconic acid, glyceric acid, phthalic acid, maleic acid, mandelic acid, lactic acid, salicylic acid, and gallic acid.

[23]

The treatment liquid described in any one of [2] to [21], in which the additive contains the organic carboxylic acid, and

and the organic carboxylic acid is an amino acid.

[24]

The treatment liquid described in [23], in which the amino acid is one or more kinds of amino acids selected from the group consisting of alanine, arginine, aspartic acid, cysteine, glutamine, glutamic acid, glycine, histidine, isoleucine, leucine, lysine, methionine, phenylalanine, proline, serine, threonine, tryptophan, tyrosine, and valine.

[25]

The treatment liquid described in any one of [2] to [24], in which the additive contains the quaternary ammonium salt, and

the quaternary ammonium salt is one or more kinds of compounds among a hydroxide, a chloride, and a bromide of one or more kinds of compounds selected from the group consisting of tetramethylammonium, tetraethylammonium, tetrapropylammonium, tetrabutylammonium, methyltripropylammonium, methyltributylammonium, ethyltrimethylammonium, dimethyldiethylammonium, benzyltrimethylammonium, and (2-hydroxyethyl)trimethylammonium.

[26]

The treatment liquid described in any one of [2] to [25], in which the additive contains the boron-containing compound, and

the boron-containing compound is boric acid.

[27]

The treatment liquid described in [1], in which the additive is one or more kinds of substances selected from the group consisting of polyethylene glycol, polyethyleneimine, dodecyl benzenesulfonic acid, a phenolsulfonic acid formaldehyde condensate, and dodecyl diphenyl ether disulfonic acid.

[28]

The treatment liquid described in any one of [1] to [27], in which the acetate solvent is one or more kinds of compounds selected from the group consisting of methyl acetate, ethyl acetate, n-propyl acetate, isopropyl acetate, t-butyl acetate, n-butyl acetate, isobutyl acetate, vinyl acetate, n-amyl acetate, isoamyl acetate, octyl acetate, 2-ethoxyethyl acetate, phenyl acetate, and phenethyl acetate.

[29]

The treatment liquid described in any one of [1] to [28], in which the acetate solvent is one or more kinds of compounds selected from the group consisting of ethyl acetate and n-butyl acetate.

[30]

The treatment liquid described in any one of [1] to [29], in which the oxidant is a peroxide.

[31]

The treatment liquid described in any one of [1] to [30], in which a content of the oxidant is less than 10% by mass with respect to a total mass of the treatment liquid.

[32]

The treatment liquid described in any one of [1] to [31], in which the treatment liquid is used for an object to be treated containing SiGe to remove at least a part of SiGe contained in the object to be treated.

[33]

The treatment liquid described in any one of [1] to [32], in which the treatment liquid is used for an object to be treated containing SiGe to remove at least a part of SiGe contained in the object to be treated, and

an element ratio of Si:Ge in the SiGe is in a range of 95:5 to 50:50.

[34]

The treatment liquid described in any one of [1] to [33], in which the treatment liquid is used for an object to be treated containing a metal hard mask containing one or more kinds of substances among Cu, Co, W, AlOₓ, AlN, AlOₓN_{y}, WOₓ, Ti, TiN, ZrOₓ, HfOₓ, and TaOₓ where

x represents a number of 1 to 3 and y represents a number of 1 or 2.

[35]

A treatment liquid container having a container and the treatment liquid described in any one of [1] to [34] stored in the container,

in which the container has a degassing mechanism that adjusts internal pressure of the container.

According to the present invention, it is possible to provide a treatment liquid that allows a treated portion to have excellent smoothness in a case where SiGe is etched with the treatment liquid.

Furthermore, the present invention can also provide a treatment liquid container relating to the treatment liquid.

### BRIEF DESCRIPTION OF THE DRAWINGS

FIG. 1 is a schematic cross-sectional view of the upper portion of a treatment liquid container to which a degassing cap is applied.

FIG. 2 is a cross-sectional view showing an embodiment of an object to be treated.

FIG. 3 is an example of a cross-sectional view showing an object to be treated having been treated by the present treatment method.

### DESCRIPTION OF THE PREFERRED EMBODIMENTS

Hereinafter, the present invention will be specifically described.

The following constituents will be described based on typical embodiments of the present invention in some cases, but the present invention is not limited to the embodiments.

In the present specification, the range of numerical values described using “to” means a range including the numerical values listed before and after “to” as the lower limit and the upper limit.

Furthermore, in the present invention, “ppm” means “parts-per-million (10⁻⁶)”, “ppb” means “parts-per-billion (10⁻⁹)”, and “ppt” means “parts-per-trillion (10⁻¹²)”.

In the present specification, “room temperature” is “25° C.”.

In the present specification, the pH of the treatment liquid is a value measured at room temperature (25° C.) by using F-51 (trade name) manufactured by Horiba, Ltd.

In the present specification, in a case where there is a molecular weight distribution, unless otherwise specified, a molecular weight means a weight-average molecular weight. In the present specification, the weight-average molecular weight of a resin (polymer) is a polystyrene-equivalent weight-average molecular weight determined by gel permeation chromatography (GPC).

The components of the treatment liquid mentioned in the present specification may be in a state of being ionized in the treatment liquid.

In the present specification, in a case where the term “salt” is mentioned, examples of a salt of a compound containing a cationic nitrogen atom (N⁺) or the like include a halide salt, such as fluoride, chloride, bromide, or iodide, of the compound, a hydroxide of the compound; a nitrate of the compound; a sulfate of the compound, and the like. These salts may form salts with two or more kinds of anions. Here, in a case where the salt is an additive, it is also preferable that the aforementioned salt be other than a fluoride.

Examples of a salt of a compound containing a sulfonic acid group, a phosphoric acid group, a carboxylic acid group, and the like include an alkali metal salt, such as a lithium salt, a sodium salt, or a potassium salt, of the compound; an alkaline earth metal salt, such as a calcium salt, of the compound; an ammonium salt of the compound, and the like. These salts may form salts with two or more kinds of cations.

In a polymer, only some of the groups capable of forming a salt may form a salt, or all of such groups may form a salt.

[Treatment Liquid]

The treatment liquid according to an embodiment of the present invention contains a fluoride ion source, an oxidant, an acetate solvent, and an additive.

The additive is an additive that does not contain a Si atom.

That is, it has been found that in a case where SiGe is etched in the presence of an acetate solvent by using a fluoride ion source and an oxidant, using an additive that does not contain a Si atom results in excellent dissolution selectivity for Si (silicon) of SiGe.

In a case where the aforementioned additive was an additive containing a Si atom, the treatment liquid could not sufficiently improve the dissolution selectivity for SiGe.

According to the inventors of the present invention, the reason is considered to be as below. That is, in a case where the additive containing a Si atom is used, because the additive containing a Si atom functions as an anticorrosive for the surface of SiGe in the presence of an acetate solvent, the additive may not improve the dissolution rate of SiGe, which may prevent the dissolution selectivity for silicon (Si) of SiGe from being sufficiently improved. Therefore, it is considered that using the additive containing no Si atom in the treatment liquid according to an embodiment of the present invention may have improved the dissolution selectivity for SiGe.

Furthermore, as a result of using the additive containing no Si atom in the treatment liquid according to the embodiment of the present invention, the surface smoothness of the treated portion is improved. Regarding this result, the inventors of the present invention consider that in creating a state where the acetate solvent and a SiGe dissolution product generated by partial dissolution in the middle of the treatment coexist, in a case where the aforementioned additive containing a Si atom is used, an interaction based on the Si atom may occur, and the additive may not be able to sufficiently bring about a surface smoothness improving effect. Therefore, it is considered that using the additive containing no Si atom in the treatment liquid according to an embodiment of the present invention may have improved the surface smoothness.

Hereinafter, regarding the treatment liquid according to the embodiment of the present invention, the properties of exhibiting excellent selectivity in dissolving SiGe and/or the properties of allowing a treated portion to have excellent smoothness in a case where SiGe is etched with the treatment liquid will be also described as “the effect of the present invention is excellent”.

Hereinafter, the components contained in the treatment liquid according to the embodiment of the present invention will be specifically described.

<Fluoride Ion Source>

The treatment liquid contains a fluoride ion source.

The fluoride ion source is a component that releases fluoride ions (ions containing fluorine atoms, such as F⁻ and/or HF₂⁻) in the treatment liquid.

Fluoride ions are considered to be able to assist in the removal of oxides of silicon and/or germanium formed under the action of an oxidant that will be described later.

Examples of the fluoride ion source include hydrofluoric acid (HF), ammonium fluoride (NH₄F), fluoroborate (such as KBF₄ or NH₄BF₄), fluoroboric acid, tetrabutylammonium tetrafluoroborate, aluminum hexafluoride, sodium fluoride, potassium fluoride, AlF₂, LiF₄, CaF₃, NaHF₆, NH₄HF₂, KHF₂, H₂SiF₆, and a compound represented by R¹NR²R³R⁴F.

In the R¹NR²R³R⁴F, R¹, R², R³, and R⁴ each independently represent a hydrogen atom or an alkyl group having 1 to 4 carbon atoms. The total number of carbon atoms contained in R¹, R², R³, and R⁴ is preferably 1 to 12. Examples of the compound represented by R¹NR²R³R⁴F include tetraethylammonium fluoride, methyltriethylammonium fluoride, and tetrabutylammonium fluoride.

The fluoride ion source is preferably hydrofluoric acid or ammonium fluoride.

The content of the fluoride ion source is not particularly limited. In view of further improving the effects of the present invention, the content of the fluoride ion source with respect to the total mass of the treatment liquid is preferably 0.001% to 10% by mass, more preferably 0.01% to 5% by mass, and even more preferably 0.1% to 3% by mass.

One kind of fluoride ion source may be used alone, or two or more kinds of fluoride ion sources may be used. In a case where two or more kinds of fluoride ion sources are used, the total amount thereof is preferably within the above range.

<Oxidant>

The treatment liquid contains an oxidant.

The oxidant is considered to function to etch SiGe by acting on SiGe and forming an oxide (such as silicon oxide, germanium oxide, and/or silicon-germanium composite oxide).

Examples of the oxidant include a peroxide, a persulfide (for example, a monopersulfide or a dipersulfide), a percarbonate, salts of these, and acids of these.

Among these, a peroxide (compound containing one or more peroxy groups (—O—O—)) is preferable as the oxidant. The peroxide may be a peroxy acid (such as peracetic acid, perbenzoic acid, or salts of these).

Examples of other suitable oxidants include an oxidative halide (such as iodic acid, periodic acid, or salts thereof), perboric acid, perborate, permanganate, a cerium compound, and a ferricyanide (such as potassium ferricyanide).

More specific examples of the oxidant include peracetic acid, hydrogen peroxide, periodic acid, potassium iodate, potassium permanganate, ammonium persulfate, ammonium molybdate, ferric nitrate, nitric acid, potassium nitrate, and a urea-hydrogen peroxide adduct.

Among these, peracetic acid or hydrogen peroxide is preferable as the oxidant.

The content of the oxidant is not particularly limited. In view of further improving the effects of the present invention, the content of the oxidant with respect to the total mass of the treatment liquid is preferably 0.5% by mass or more, more preferably 1% by mass or more, and even more preferably 5% by mass or more. The upper limit of the content of the oxidant with respect to the total mass of the treatment liquid is preferably 30% by mass or less, more preferably 20% by mass or less, even more preferably 15% by mass or less, and particularly preferably less than 10% by mass.

<Acetate Solvent>

The treatment liquid contains an acetate solvent.

The acetate solvent is, for example, a compound represented by “CH₃—CO—O—R^{AC}”.

In “CH₃—CO—O—R^{AC}”, R^{AC} represents an organic group. The number of carbon atoms in the organic group is preferably 1 to 20, more preferably 1 to 10, and even more preferably 1 to 8.

The organic group is preferably an alkyl group, an alkoxyalkyl group, an aryl group, an arylalkyl group, an alkenyl group, or a group consisting of a combination of these.

The above alkyl group, an alkyl group moiety in the above alkoxyalkyl group, and an alkyl group moiety in the above arylalkyl group may be each independently linear or branched. A part of the entirety of each of the above alkyl group and the alkyl group moieties may form a cyclic structure. Each of the above alkyl group and the alkyl group moieties preferably has 1 to 8 carbon atoms.

The above alkenyl group may be linear or branched, and a part or the entirety of the alkenyl group may form a cyclic structure. The alkenyl group preferably has 2 to 8 carbon atoms.

The above aryl group and an aryl group moiety in the above arylalkyl group preferably each independently have 6 to 10 carbon atoms.

Particularly, the acetate solvent is preferably one or more kinds of compounds selected from the group consisting of methyl acetate, ethyl acetate, n-propyl acetate, isopropyl acetate, t-butyl acetate, n-butyl acetate, isobutyl acetate, vinyl acetate, n-amyl acetate, isoamyl acetate, octyl acetate, 2-ethoxyethyl acetate, phenyl acetate, and phenethyl acetate, more preferably one or more kinds of compounds selected from the group consisting of methyl acetate, ethyl acetate, n-propyl acetate, isopropyl acetate, t-butyl acetate, n-butyl acetate, isobutyl acetate, n-amyl acetate, isoamyl acetate, octyl acetate, and 2-ethoxyethyl acetate, and even more preferably one or more kinds of compounds selected from the group consisting of ethyl acetate and n-butyl acetate.

The content of the acetate solvent is not particularly limited. In view of further improving the effect of the present invention, the content of the acetate solvent with respect to the total mass of the treatment liquid is preferably 1% to 70% by mass, more preferably 10% to 60% by mass, and even more preferably 20% to 45% by mass.

One kind of acetate solvent may be used alone, or two or more kinds of acetate solvents may be used. In a case where two or more kinds of acetate solvents are used, the total amount thereof is preferably within the above range.

The treatment liquid may contain an organic solvent other than the acetate solvent. In this case, the content of the organic solvent with respect to the content of the acetate solvent is preferably more than 0% by mass and 100% by mass or less, more preferably more than 0% by mass and 50% by mass or less, and even more preferably more than 0% by mass and 10% by mass or less.

<Additive (Specific Additive)>

The treatment liquid contains an additive that does not contain a Si atom.

Hereinafter, the additive that does not contain a Si atom will be also called a specific additive.

The fluoride ion source, oxidant, and acetate solvent described above are not included in the specific additive.

The additive that does not contain a Si atom may be an additive that substantially does not contain a Si atom. For example, the content of Si atoms with respect to the total mass of a compound as the additive may be 1% by mass or less, and is preferably 0.1% by mass or less. The lower limit of the content is 0% by mass or more.

The content of the specific additive is not particularly limited. In view of further improving the effect of the present invention, the content of the specific additive with respect to the total mass of the treatment liquid is preferably 0.001% to 10% by mass, more preferably 0.01% to 5% by mass, and even more preferably 0.1% to 3% by mass.

One kind of specific additive may be used alone, or two or more kinds of specific additives may be used. In a case where two or more kinds of specific additives are used, the total amount thereof is preferably within the above range.

The treatment liquid may further contain an additive containing a Si atom, in addition to the specific additive.

In this case, the content of the additive containing a Si atom with respect to the total mass of the treatment liquid is preferably more than 0% by mass and less than 10% by mass, more preferably more than 0% by mass and less than 0.01% by mass, and even more preferably more than 0% by mass and less than 0.001% by mass.

Furthermore, in this case, the content of the additive containing a Si atom with respect to the total mass of the specific additive is preferably more than 0% by mass and 100% by mass or less, more preferably more than 0% by mass and 10% by mass or less, and even more preferably more than 0% by mass and 1% by mass or less.

The specific additive is preferably one or more kinds of substances selected from the group consisting of a nonionic polymer, an anionic polymer, a nonionic surfactant, an anionic surfactant, a cationic surfactant, an amphoteric surfactant, a nitrogen atom-containing polymer, alkylamine, aromatic amine, alkanolamine, and a nitrogen-containing heterocyclic compound, organic carboxylic acid, a quaternary ammonium salt, and a boron-containing compound, more preferably one or more kinds of substances selected from the group consisting of a nonionic polymer, an anionic polymer, a nonionic surfactant, an anionic surfactant, a cationic surfactant, a nitrogen atom-containing polymer, alkylamine, aromatic amine, alkanolamine, and a nitrogen-containing heterocyclic compound, an organic carboxylic acid other than an amino acid, cysteine, a quaternary ammonium salt, and a boron-containing compound, and even more preferably one or more kinds of substances selected from the group consisting of polyethylene glycol, polyethyleneimine, dodecyl benzenesulfonic acid, a phenolsulfonic acid formaldehyde condensate, and dodecyl diphenyl ether disulfonic acid.

It should be noted that these components substantially do not contain a Si atom.

Hereinafter, each of these components will be described.

(Nonionic Polymer)

The nonionic polymer is a polymer that substantially does not contain ionic groups consisting of an anionic group and a cationic group.

Examples of the anionic group include groups represented by —COOM, —OSO₃M, —P(═O)(OR²¹)OM, and —SO₃M. M represents a hydrogen atom or a countercation. Examples of the countercation include an alkali metal ion (such as lithium, sodium, or potassium) and an ammonium ion. The above R²¹ represents a hydrogen atom or a substituent (such as an alkyl group having 1 to 3 carbon atoms).

Examples of the cationic group include a nitrogen atom-containing group. Examples of the nitrogen atom-containing group include an ammonium cation and a salt thereof.

“Substantially does not contain ionic groups” means that the content of ionic groups with respect to the total mass of the polymer is 0% to 5% by mass. The content of ionic groups is preferably 0% to 1% by mass, and more preferably 0% to 0.1% by mass.

The weight-average molecular weight of the nonionic polymer is preferably 400 to 50,000.

The nonionic polymer is preferably other than the surfactants (the nonionic surfactant, the anionic surfactant, the cationic surfactant, and the amphoteric surfactant) that will be described later.

The nonionic polymer is preferably one or more kinds of polymers selected from the group consisting of polyoxyalkylene glycol (such as polyethylene glycol, polypropylene glycol, or polyoxyethylene polyoxypropylene glycol) and polyvinyl alcohol.

The alkylene group in the polyoxyalkylene glycol is preferably a linear or branched alkylene group having 1 to 5 carbon atoms.

In the aforementioned polyvinyl alcohol, the content of the repeating unit represented by —CH₂—CH(OH)— with respect to the total content of repeating units in the polymer is preferably 51 to 100 mol %, and more preferably 75 to 100 mol %.

(Anionic Polymer)

The anionic polymer is preferably other than the specific additive described above.

The anionic polymer is a polymer containing a repeating unit containing an anionic group.

Examples of the anionic group include groups represented by —COOM, —OSO₃M, —P(═O)(OR²¹)OM, and —SO₃M. M represents a hydrogen atom or a countercation. Examples of the countercation include an alkali metal ion (such as lithium, sodium, or potassium) and an ammonium ion. The above R²¹ represents a hydrogen atom or a substituent (such as an alkyl group having 1 to 3 carbon atoms or the aforementioned countercation).

Examples of the repeating unit containing an anionic group include (meth)acrylic acid, styrene sulfonic acid, a repeating unit formed by the condensation of phenolsulfonic acid and formaldehyde, a repeating unit formed by the condensation of aryl phenolsulfonic acid and formaldehyde, and a repeating unit in which each of the above repeating units forms a salt.

Examples of the awl group in the awl phenolsulfonic acid include an aryl group having 6 to 14 carbon atoms.

In a case where the anionic polymer also contains a repeating unit other than the repeating unit containing an anionic group, it is preferable that the content (molar ratio) of the repeating unit containing an anionic group be the highest among all the repeating units.

In the anionic polymer, the content of the repeating unit containing an anionic group with respect to the total content of repeating units in the polymer is preferably 51 to 100 mol %, and more preferably 75 to 100 mol %.

The weight-average molecular weight of the anionic polymer is preferably 400 to 50,000.

The anionic polymer is preferably other than the surfactants (the nonionic surfactant, the anionic surfactant, the cationic surfactant, and the amphoteric surfactant) that will be described later.

The anionic polymer is preferably one or more kinds of polymers selected from the group consisting of polyacrylic acid, polystyrene sulfonic acid, a phenolsulfonic acid formaldehyde condensate and a salt thereof (such as a phenyl phenolsulfonic acid formaldehyde condensate), an awl phenolsulfonic acid formaldehyde condensate, and salts of these.

(Nitrogen Atom-Containing Polymer)

The nitrogen atom-containing polymer is preferably other than the specific additive described above.

The nitrogen atom-containing polymer is a polymer containing a repeating unit containing a nitrogen atom (N-containing repeating unit).

In a case where the nitrogen atom-containing polymer also contains a repeating unit other than the N-containing repeating unit, it is preferable that the content (molar ratio) of the N-containing repeating unit be the highest among all the repeating units.

In the nitrogen atom-containing polymer, the content of the N-containing repeating unit with respect to the total content of repeating units in the polymer is preferably 51 to 100 mol %, and more preferably 75 to 100 mol %.

The weight-average molecular weight of the nitrogen atom-containing polymer is preferably 400 to 50,000.

The nitrogen atom-containing polymer is preferably other than the surfactants (the nonionic surfactant, the anionic surfactant, the cationic surfactant, and the amphoteric surfactant) that will be described later.

Examples of monomers as sources of the N-containing repeating unit include vinylpyrrolidone, ethyleneimine, allylamine, vinylamine, acrylamide, hexadimethrine, diallylamine, a dimethyldiallylammonium salt (such as a halide salt, a hydroxide salt, a nitrate, or a sulfate), 4-vinylpyridine, ornithine, lysine, arginine, histidine, vinylimidazole, and methyldiallylamine As the N-containing repeating unit, a repeating unit consisting of dimethylamine and epichlorohydrin (preferably epichlorohydrin) may also be used.

The nitrogen atom-containing polymer is preferably one or more kinds of polymers selected from the group consisting of polyvinylpyrrolidone, polyethyleneimine, polyallylamine, polyvinylamine, polyacrylamide, a dimethylamine.epihalohydrin-based polymer (preferably a dimethylamine-epihalohydrin copolymer, and more preferably a dimethylamine-epichlorohydrin copolymer), a hexadimethrine salt, polydiallylamine, a polydimethyldiallylammonium salt (such as a halide salt, a hydroxide salt, a nitrate, or a sulfate), poly(4-vinylpyridine), polyornithine, polylysine, polyarginine, polyhistidine, polyvinylimidazole, and polymethyldiallylamine.

(Nonionic Surfactant)

The nonionic surfactant is preferably other than the specific additive described above.

It is preferable that the nonionic surfactant be different from the anionic surfactant, the cationic surfactant, and the amphoteric surfactant that will be described later.

The nonionic surfactant is preferably a compound represented by “R^{NI}-L^{NI}-Q^{NI}”.

In “R^{NI}-L^{NI}-Q^{NI}”, R^{NI} represents an alkyl group, an allyl group, an aryl group, or a group consisting of a combination of these. These groups may have one or more substituents. The alkyl group may be linear or branched. The number of carbon atoms in the alkyl group is preferably 6 or more, and more preferably 6 to 22. One or more of the ethylene groups in the alkyl group may be substituted with a vinylene group. The number of carbon atoms in the aforementioned aryl group is preferably 6 to 12. The number of carbon atoms in the allyl group is preferably 2 or more, and more preferably 2 to 22.

L^{NI} represents a single bond or a divalent linking group. The divalent linking group is preferably —O—, —CO—, —NR¹¹—, —S—, —SO₂—, —PO(OR¹²)—, an alkylene group, an arylene group, or a group obtained by combining these. R¹¹ represents a hydrogen atom, an alkyl group, an aryl group, or an aralkyl group. R¹² represents an alkyl group, an aryl group, or an aralkyl group.

Q^{NI} represents a nonionic hydrophilic group. The nonionic hydrophilic group is preferably a polyoxyethylene unit (preferably having a polymerization degree of 5 to 150), a polyoxypropylene unit (preferably having a polymerization degree of 5 to 150), a polyoxyethylene-polypropylene unit (preferably having a polymerization degree of 5 to 150), a polyglycerin unit (preferably having a polymerization degree of 3 to 30), or a hydrophilic sugar chain unit (for example, a hydrophilic sugar chain unit such as glucose, arabinose, fructose, sorbitol, or mannose).

The nonionic surfactant is preferably one or more kinds of compounds selected from the group consisting of polyoxyethylene alkyl ether and polyoxyethylene alkyl allyl ether.

(Anionic Surfactant)

The anionic surfactant is preferably other than the specific additive described above.

Furthermore, it is preferable that the anionic surfactant be different from the cationic surfactant and the amphoteric surfactant that will be described later.

The anionic surfactant is preferably a compound represented by “R^{NA}-L^{NA}-Q^{NA}”.

R^{NA} represents an alkyl group, an aryl group, or a group consisting of a combination of these. These groups may have one or more substituents. Examples of the substituent include a halogen atom, such as a fluorine atom, and a hydroxyl group. The alkyl group may be linear or branched. The number of carbon atoms in the alkyl group is preferably 6 or more, and more preferably 6 to 22. The number of carbon atoms in the aforementioned aryl group is preferably 6 to 12. One or more of the ethylene groups in the alkyl group may be substituted with a vinylene group.

L^{NA} represents a single bond or a divalent linking group. The divalent linking group is preferably —O—, —CO—, —NR¹¹—, —S—, —SO₂—, —PO(OR¹²)—, an alkylene group, an arylene group, or a group obtained by combining these. R¹¹ represents a hydrogen atom, an alkyl group, an aryl group, or an aralkyl group. R¹² represents an alkyl group, an aryl group, or an aralkyl group. The aforementioned alkylene group and the aforementioned arylene group may each independently have a substituent. For example, each of the alkylene group and the arylene group may have one or more anionic groups as a substituent.

L^{NA} is preferably a polyoxyalkylene group (such as a polyoxyethylene group), a phenylene group, a biphenylene group, or a naphthylene group. These groups may have one or more substituents such as an anionic group described below.

Q^{NA} represents an anionic group. Examples of the anionic group include groups represented by —COOM, —OSO₃M, —P(═O)(OR^{NA2})OM, and —SO₃M. M represents a hydrogen atom or a countercation. Examples of the countercation include an alkali metal ion (such as lithium, sodium, or potassium) and an ammonium ion. The above R^{NA2} represents an alkyl group having 1 to 3 carbon atoms, the aforementioned countercation, or a group represented by “R^{NA}-L^{NA}-”. R^{NA} and L^{NA} in the group represented by “R^{NA}-L^{NA}-” are as described above.

The anionic surfactant is preferably one or more kinds of compounds selected from the group consisting of alkyl benzenesulfonic acid, alkyl naphthalenesulfonic acid, alkyl diphenyl ether disulfonic acid, polyoxyethylene alkyl ether sulfonic acid, alkyl carboxylic acid, polyoxyethylene alkyl ether carboxylic acid, alkyl phosphonic acid, polyoxyethylene phosphonic acid, polyoxyethylene alkyl ether phosphoric acid, polyoxyethylene alkyl phenyl ether phosphoric acid, and salts of these (such as a lithium salt, a sodium salt, a potassium salt, and an ammonium salt).

It is also preferred that the anionic surfactant contain at least any of the alkyl benzenesulfonic acid and a salt thereof, and that the alkyl benzenesulfonic acid be dodecyl benzenesulfonic acid.

It is also preferable that the anionic surfactant contain at least any of the alkyl naphthalenesulfonic acid and a salt thereof, and that the alkyl naphthalenesulfonic acid be one or more kinds of compounds selected from the group consisting of propyl naphthalenesulfonic acid, triisopropyl naphthalenesulfonic acid, and dibutyl naphthalenesulfonic acid.

It is also preferred that the anionic surfactant contain at least any of the alkyl diphenyl ether disulfonic acid and a salt thereof, and that the alkyl diphenyl ether disulfonic acid be dodecyl diphenyl ether disulfonic acid.

It is also preferable that the anionic surfactant contain at least any of the polyoxyethylene alkyl ether sulfonic acid and a salt thereof, and that the polyoxyethylene alkyl ether sulfonic acid be one or more kinds of compounds selected from the group consisting of polyoxyethylene lauryl ether sulfonic acid, polyoxyethylene oleyl ether sulfonic acid, and polyoxyethylene octyldodecyl ether sulfonic acid.

It is also preferable that the anionic surfactant contain at least any of the alkyl carboxylic acid and a salt thereof The alkyl carboxylic acid is preferably alkyl monocarboxylic acid containing an alkyl group having 6 or more carbon atoms (preferably having 6 to 22 carbon atoms) that may have a substituent. As the substituent, a halogen atom, such as a fluorine atom, or a hydroxyl group is preferable. It is also preferable that the alkyl carboxylic acid be a perfluoroalkyl carboxylic acid.

The alkyl carboxylic acid is also preferably one or more kinds of compounds selected from the group consisting of dodecanoic acid, hexadecanoic acid, oleic acid, juniperic acid, stearic acid, 12-hydroxystearic acid, perfluorooctanoic acid, perfluoroheptanoic acid, and perfluorodecanoic acid.

It is also preferable that the anionic surfactant contain at least any of the polyoxyethylene alkyl ether carboxylic acid and a salt thereof, and that the polyoxyethylene alkyl ether carboxylic acid be one or more kinds of compounds selected from the group consisting of polyoxyethylene lauryl ether carboxylic acid, polyoxyethylene dodecyl ether carboxylic acid, and polyoxyethylene tridecyl ether carboxylic acid.

It is also preferable that the anionic surfactant contain at least any of the alkyl phosphonic acid and a salt thereof, and that the alkyl phosphonic acid be bis(2-ethylhexyl)phosphate, dioctadecylphosphate, octadecylphosphate, dodecylphosphate, decyl phosphonic acid, dodecyl phosphonic acid, tetradecyl phosphonic acid, hexadecyl phosphonic acid, and octadecyl phosphonic acid.

It is also preferable that the anionic surfactant contain at least any of the polyoxyethylene alkyl ether phosphoric acid and a salt thereof, and that the polyoxyethylene alkyl ether phosphoric acid be polyoxyethylene lauryl ether phosphoric acid.

(Cationic Surfactant)

The cationic surfactant is preferably other than the specific additive described above, such as the nonionic surfactant and the anionic surfactant described above.

It is also preferable that the cationic surfactant be other than the amphoteric surfactant which will be described later.

The cationic surfactant is preferably a non-polymeric compound having one or more (preferably one or two) cationic nitrogen atoms (N⁺).

The cationic nitrogen atom (N⁺) may be contained in a pyridinium ring.

The cationic surfactant containing only the cationic nitrogen atom (N⁺) which is not contained in a pyridinium ring preferably has more than 16 carbon atoms, and more preferably has 17 to 50 carbon atoms.

The cationic surfactant containing only the cationic nitrogen atom (N⁺) which is not contained in a pyridinium ring preferably has 5 or more carbon atoms, more preferably has 5 to 50 carbon atoms, and even more preferably has 10 to 50 carbon atoms.

It is preferable that the cationic nitrogen atom (N⁺) form a salt together with a counteranion. Examples of the counteranion include OH⁻ and halogen anions such as Cl⁺ and Br⁻.

The cationic surfactant is preferably a salt (for example, one or more kinds of compounds among a hydroxide, a chloride, and a bromide) of one or more kinds of compounds selected from the group consisting of cetyltrimethylammonium, stearyltrimethylammonium, laurylpyridinium, cetylpyridinium, 4-(4-diethylaminophenylazo)-1-(4-nitrobenzyl)pyridinium, benzalkonium, benzethonium, benzyldimethyldodecylammonium, benzyldimethylhexadecylammonium, hexadecyltrimethylammonium, dimethyldioctadecylammonium, dodecyltrimethylammonium, didodecyldimethylammonium, tetraheptylammonium, tetrakis(decyl)ammonium, and dimethyldihexadecylammonium.

(Amphoteric Surfactant)

The amphoteric surfactant is preferably other than the specific additive described above, such as the nonionic surfactant, the anionic surfactant, and the cationic surfactant described above.

Examples of amphoteric surfactant include a betaine-type amphoteric surfactant such as alkylbetaine or fatty acid amide propyl betaine, and an amine oxide-type amphoteric surfactant.

The amphoteric surfactant is preferably one or more kinds of compounds selected from the group consisting of cocamidopropyl betaine, N,N-dimethyldodecylamine N-oxide, lauryl dimethylaminoacetic acid betaine, and lauryldimethylamine oxide.

(Alkylamine)

It is preferable that the alkylamine be none of the aforementioned specific additive, the nitrogen-containing heterocyclic compound that will be described later, the alkanolamine that will be described later, and the amino acid that will be described later.

The alkylamine is a compound containing at least one partial structure represented by “alkyl group-N”. The alkyl group may have a substituent.

The molecular weight of the alkylamine is preferably 15 or more and less than 400, and more preferably 15 or more and 300 or less.

The alkylamine is preferably a compound represented by “R^{N}₂N(-L^{N}-NR^{LN}-)_{XN}R^{N}”.

In “R^{N}₂N(-L^{N}-NR^{LN}—)_{XN}R^{N}”, XN represents an integer of 0 to 6.

Three R^{N}'s and XN pieces of R^{LN}'s each independently represent a hydrogen atom or an alkyl group which may have a substituent.

The alkyl group in the aforementioned alkyl group which may have a substituent may be linear or branched, or the entirety or a part of the alkyl group may form a cyclic structure. The number of carbon atoms in the alkyl group is preferably 1 to 120.

The substituent in the aforementioned alkyl group which may have a substituent is preferably an aryl group (preferably having 6 to 15 carbon atoms), an aminoalkyl group (preferably having 1 to 5 carbon atoms), or a group consisting of a combination of these. It is also preferable that the substituent be other than a hydroxyl group and a carboxy group.

The total number of carbon atoms of the aforementioned alkyl group which may have a substituent is preferably 1 to 20.

XN pieces of L^{N}'s each independently represent an alkylene group having 1 to 8 carbon atoms.

Here, in a case where XN is 0, at least one of three R^{N}'s is the aforementioned alkyl group which may have a substituent.

The alkylamine is preferably one or more kinds of compounds selected from the group consisting of ethylenediamine, diethylenetriamine, triethylenetetramine, tetraethylenepentamine, pentaethylenehexamine, tetramethylethylenediamine, hexamethylenediamine, methylamine, dimethylamine, trimethylamine, ethylamine, diethylamine, triethylamine, 2-ethylhexylamine, cyclohexylamine, phenethylamine, and m-xylylenediamine.

(Aromatic Amine)

The aromatic amine is preferably other than the specific additive described above.

The aromatic amine is a compound containing at least one partial structure represented by “aromatic ring group-N”. The aromatic ring group may have a substituent.

Here, it is preferable that the aromatic amine be none of the aforementioned specific additive, the nitrogen-containing heterocyclic compound that will be described later, and the amino acid other than cysteine that will be described later.

The molecular weight of the aromatic amine is preferably 15 or more and less than 400, and more preferably 15 or more and 300 or less.

The aromatic amine is preferably a compound represented by “R^{N}₂N-aromatic ring group which may have a substituent”.

In “R^{N}₂N-aromatic ring group which may have a substituent”, two R^{N}'s each independently represent a hydrogen atom or a substituent other than an alkyl group.

The substituent in the aforementioned aromatic ring group which may have a substituent is preferably an alkyl group (preferably having 1 to 20 carbon atoms), an aryl group (preferably having 6 to 15 carbon atoms), an aminoalkyl group (preferably having 1 to 5 carbon atoms), or a group obtained by combining these.

The total number of carbon atoms of the aforementioned aromatic ring group which may have a substituent is preferably 1 to 20.

The aromatic ring group in the aromatic ring group which may have a substituent preferably has 5 to 15 carbon atoms, and may contain a heteroatom as a ring member atom.

The aromatic amine is preferably one or more kinds of compounds selected from the group consisting of aniline and toluidine.

(Alkanolamine)

The alkanolamine is preferably other than the specific additive described above.

The alkanolamine is a compound having an alkane skeleton containing a hydroxy group and an amino group.

The alkanolamine is preferably a compound in which at least one alkyl group which may have a substituent that is in the aforementioned “R^{N}₂N(-L^{N}-NR^{LN}—)_{XN}R^{N}” is an alkyl group having a hydroxyl group as a substituent.

The alkanolamine is preferably one or more kinds of compounds selected from the group consisting of diethanolamine, diisopropanolamine, triisopropanolamine, 2-(2-aminoethylamino)ethanol, 2-(2-aminoethoxy)ethanol, triethanolamine, N-ethylethanolamine, N,N-dimethylethanolamine, N,N-diethylethanolamine, N-methyldiethanolamine, N-ethyldiethanolamine, cyclohexylamine diethanol, and N-methylethanolamine

(Nitrogen-Containing Heterocyclic Compound)

The nitrogen-containing heterocyclic compound is preferably other than the specific additive described above.

The nitrogen-containing heterocyclic compound is a compound having a heterocyclic structure having at least one (preferably one to four) nitrogen atom as a ring member atom.

Here, it is preferable that the nitrogen atom as a ring member atom of the heterocyclic structure be other than the cationic nitrogen atom (N⁺).

The heterocyclic structure may have a heteroatom (such as an oxygen atom or a sulfur atom) as a ring member atom, in addition to the nitrogen atom.

The heterocyclic structure may be monocyclic or polycyclic. In a case where the heterocyclic structure is monocyclic, a 5- to 8-membered ring is preferable. In a case where the heterocyclic structure is polycyclic, the total number of rings is preferably 2 to 5, and it is also preferable that each ring be a 5- to 8-membered ring.

The heterocyclic structure may or may not have aromaticity. In a case where the heterocyclic structure is polycyclic, rings having aromaticity may be fused together, rings having no aromaticity may be fused together, or a ring having aromaticity and a ring having no aromaticity may be fused together.

The number of ring member atoms constituting the heterocyclic structure is preferably 3 to 20.

The heterocyclic structure may contain a substituent (such as primary to tertiary amino groups).

The nitrogen-containing heterocyclic compound may have only one heterocyclic structure described above or may have a plurality of heterocyclic structures described above.

The molecular weight of the nitrogen-containing heterocyclic compound is preferably 40 or more and less than 400, and more preferably 50 or more and 300 or less.

The nitrogen-containing heterocyclic compound is preferably one or more kinds of compounds selected from the group consisting of pyrrolidine, piperidine, piperazine, morpholine, pyrrole, pyrazole, imidazole, pyridine, pyrimidine, pyrazine, oxazole, thiazole, and 4-dimethylaminopyridine.

(Organic Carboxylic Acid)

The organic carboxylic acid is preferably other than the specific additive (such as the anionic polymer and the anionic surfactant) described above.

Examples of the organic carboxylic acid include a polycarboxylic acid (preferably a polycarboxylic acids other than an amino acid), a hydroxy acid, and an amino acid.

It is also preferable that the organic carboxylic acid be other than an alkyl monocarboxylic acid containing an alkyl group having 6 or more carbon atoms which may have a substituent.

The molecular weight of the organic carboxylic acid is preferably 40 or more and less than 400.

The organic carboxylic acid is preferably one or more kinds of compounds selected from the group consisting of citric acid, 2-methylpropane-1,2,3-tricarboxylic acid, benzene-1,2,3-tricarboxylic acid (hemimellitic acid), propane-1,2,3-tricarboxylic acid (tricarballylic acid), 1,cis-2,3-propanetricarboxylic acid (aconitic acid), butane-1,2,3,4-tetracarboxylic acid, cyclopentane tetra-1,2,3,4-carboxylic acid, benzene-1,2,4,5-tetracarboxylic acid (pyromellitic acid), benzenepentacarboxylic acid, benzenehexacarboxylic acid (mellitic acid), oxalic acid, malonic acid, succinic acid, glutaric acid, adipic acid, pimelic acid, suberic acid, azelaic acid, sebacic acid, ethylenediaminetetraacetic acid (EDTA), butylenediaminetetraacetic acid, (1,2-cyclohexylenediamine)tetraacetic acid (CyDTA), diethylenetriaminepentaacetic acid (DETPA), ethylenediaminetetrapropionic acid, (hydroxyethyl)ethylenediaminetriacetic acid (HEDTA), triethylenetetraminehexacetic acid (TTHA), 1,3-diamino-2-hydroxypropane-N,N,N′,N′-tetraacetic acid (DHPTA), methyliminodiacetic acid, propylenediaminetetraacetic acid, nitrotriacetic acid (NTA), tartaric acid, gluconic acid, glyceric acid, phthalic acid, maleic acid, mandelic acid, lactic acid, salicylic acid, and gallic acid.

The organic carboxylic acid which is an amino acid is preferably a compound containing a carboxy group and a primary or secondary amino group.

The organic carboxylic acid which is an amino acid is preferably one or more kinds of amino acids selected from the group consisting of alanine, arginine, asparagine, aspartic acid, cysteine, glutamine, glutamic acid, glycine, histidine, isoleucine, leucine, lysine, methionine, phenylalanine, proline, serine, threonine, tryptophan, tyrosine, and valine.

(Quaternary Ammonium Salt)

The quaternary ammonium salt is preferably other than the specific additive described above.

The quaternary ammonium salt preferably has 16 or less carbon atoms, and more preferably 4 to 16 carbon atoms.

The quaternary ammonium salt does not include a pyridinium salt.

The quaternary ammonium salt is, for example, a compound represented by “R^{T}₄N⁺.T⁻”.

In “R^{T}₄N⁺.T⁻”, four R^{T}'s each independently represent an organic group having a carbon atom as an atom directly bonded to N⁺. The organic group is preferably an alkyl group which may have a substituent or an aryl group which may have a substituent.

The alkyl group in the aforementioned alkyl group which may have a substituent may be linear or branched, or the entirety or a part of the alkyl group may form a cyclic structure. The number of carbon atoms in the alkyl group is preferably 1 to 110.

The substituent in the aforementioned alkyl group which may have a substituent is preferably a hydroxyl group or an aryl group (preferably having 6 to 10 carbon atoms).

The aryl group in the aforementioned aryl group which may have a substituent preferably has 6 to 12 carbon atoms.

The substituent in the aforementioned aryl group which may have a substituent is preferably a hydroxyl group or an alkyl group (preferably having 1 to 10 carbon atoms).

T⁻ represents a counteranion. The counteranion is preferably OH⁻.

Here, the total number of carbon atoms contained in the compound represented by “R^{T}₄N⁺.T⁻” is preferably 16 or less, and more preferably 4 to 16.

The quaternary ammonium salt is preferably a salt (for example, one or more kinds of compounds among a hydroxide, a chloride, and a bromide) of one or more kinds of compounds selected from the group consisting of tetramethylammonium, tetraethylammonium, tetrapropylammonium, tetrabutylammonium, methyltripropylammonium, methyltributylammonium, ethyltrimethylammonium, dimethyldiethylammonium, benzyltrimethylammonium, and (2-hydroxyethyl)trimethylammonium.

(Boron-Containing Compound)

The boron-containing compound is preferably other than the specific additive described above.

The boron-containing compound is a compound containing a boron atom (B).

The boron atom-containing compound is preferably a compound having “—OH” directly bonded to a boron atom.

The molecular weight of the boron-containing compound is preferably 50 or more and less than 400, and more preferably 60 or more and 300 or less.

The boron-containing compound is preferably boric acid.

<Water>

It is preferable that the treatment liquid contain water.

The water is not particularly limited, and examples thereof include distilled water, deionized water, and pure water.

The content of water in the treatment liquid is not particularly limited. The content of water with respect to the total mass of the treatment liquid is preferably 20% by mass or more, more preferably 30% by mass or more, and even more preferably 55% by mass or more. The upper limit of the content of water is less than 100% by mass, preferably 90% by mass or less, and more preferably 80% by mass or less.

<Treatment Liquid Manufacturing Method>

The method for manufacturing the treatment liquid is not particularly limited, and known manufacturing methods can be used. Examples of the manufacturing method include a method of mixing together predetermined amounts of water, fluoride ion source, oxidant, acetal solvent, specific additive, and the like. In mixing the above components, as necessary, other optional components may be mixed together.

Furthermore, in manufacturing the treatment liquid, if necessary, the treatment liquid may be purified by being filtered using a filter.

The pH of the treatment liquid is, for example, preferably less than 7, and more preferably less than 4. The lower limit of the pH is, for example, −2 or more.

In order to adjust the pH, the treatment liquid may contain a pH adjuster. Examples of the pH adjuster include an acid compound (such as an inorganic or organic acid) other than the aforementioned components, and a basic compound (such as an inorganic or organic base).

<Treatment Liquid Container, Method of Providing Treatment Liquid>

The treatment liquid may be stored in a container and kept as it is until use.

The container and the treatment liquid stored in the container are collectively called treatment liquid container. The stored treatment liquid is used after being taken out of the treatment liquid container. It is also preferable that the treatment liquid be transported as a treatment liquid container and provided from the manufacturer to the user, from the storage place to the place of use, or the like.

It is also preferable that the container have a degassing mechanism for adjusting the pressure (internal pressure) in the container. The degassing mechanism is, for example, a mechanism which releases the generated gas from the inside of the container to the outside in a case where gas is generated from the treatment liquid by the increase in temperature of the treatment liquid in the container during storage of the treatment liquid container and/or by the decomposition of some components of the treatment liquid and the like, so that the internal pressure is kept within a certain range without excessively increasing.

Examples of the degassing mechanism include a check valve.

As a cap of the container, it is also preferable to adopt a degassing cap comprising a degassing mechanism, so that the container includes a degassing mechanism.

That is, it is also preferable that the container of the treatment liquid container have a degassing cap comprising a degassing mechanism that adjusts the internal pressure of the container.

In view of ease of handling of the treatment liquid and the like, it is preferable that the treatment liquid be provided from the manufacturer to the user, from the storage place to the place of use, and the like by a method using such a treatment liquid container.

Examples of the degassing cap include a cap provided with a valve (preferably a check valve) that releases the internal gas of the container to the outside in a case where pressure (internal pressure) over a certain level is applied to the cap.

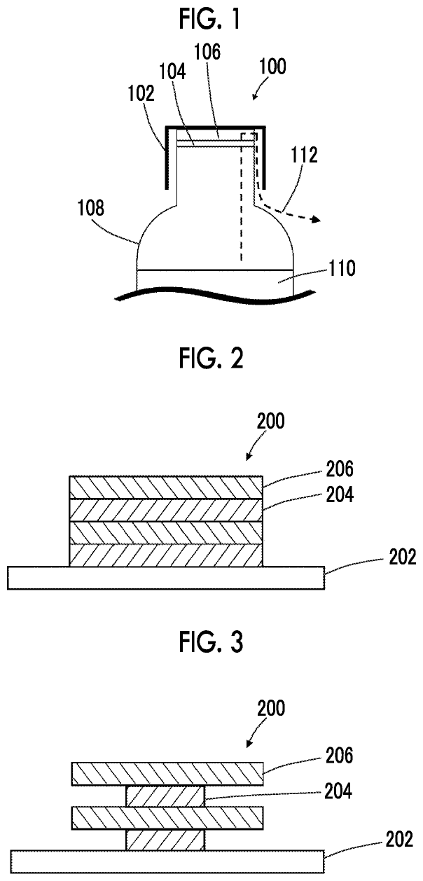

Another example of the degassing cap is illustrated in FIG. 1 which is a schematic cross-sectional view of the upper portion of a treatment liquid container to which the degassing cap is applied.

A treatment liquid container 100 has a container consisting of a cap (degassing cap) composed of a cap body 102, a waterproof breathable film 104, and a breathable layer 106 and a container body 108 sealed with the cap. The treatment liquid container 100 also has a treatment liquid 110 stored in the container body 108. The dashed arrow is a virtual flow passage 112 of the gas generated from the treatment liquid 110.

The gas generated from the treatment liquid 110 passes through the waterproof breathable film 104, and then is released to the outside of the container through the breathable layer 106 and the gap between the cap body 102 and the container body 108. In this way, the internal pressure is restrained from excessively increasing by the gas generated from the treatment liquid.

The waterproof breathable film 104 is a highly gas-permeable film that is permeable to a gas but is impermeable to a liquid.

The breathable layer 106 is a layer provided to allow the gas having passed through the waterproof breathable film 104 to rapidly move to the outside. The breathable layer 106 is formed, for example, of a porous material (such as polyethylene foam). The breathable layer 106 may not be provided.

It is also preferable that a structure for fixing the cap in a state where the cap is put on the body of the container (for example, a structure that allows the cap body 102 to be screwed on and fixed to the container body 108) be formed between the cap body 102 and the container body 108, although this structure is not shown in the drawing. This structure is preferably a structure that does not hinder the release of the gas to the outside.

It is preferable to use a container (particularly, a container body) for semiconductors which has a high internal cleanliness and is unlikely to cause elution of impurities. Examples of usable containers include a “CLEAN BOTTLE” series manufactured by AICELLO CORPORATION, and “PURE BOTTLE” manufactured by KODAMA PLASTICS Co., Ltd.

It is preferable that the inner wall of the container (particularly, the container body) be formed of one or more kinds of resins selected from the group consisting of a polyethylene resin, a polypropylene resin, and a polyethylene-polypropylene resin, or formed of a resin different from these. It is also preferable that the inner wall of the container (particularly, the container body) be formed of a metal having undergone a rustproofing treatment or a metal elution preventing treatment, such as stainless steel, Hastelloy, Inconel, or Monel.

As “resin different from these” described above, a fluororesin (perfluororesin) is preferable. In a case where a container having inner wall made of a fluororesin is used, the occurrence of problems such as elution of an ethylene or propylene oligomer can be further suppressed, than in a case where a container having inner wall formed of a polyethylene resin, a polypropylene resin, or a polyethylene-polypropylene resin is used.

Examples of the container having inner wall made of a fluororesin include a FluoroPure PFA composite drum manufactured by Entegris, and the like. In addition, it is also possible to use the containers described on page 4 of JP1991-502677A (JP-H03-502677A), page 3 of WO2004/016526A, pages 9 and 16 of the WO99/46309A, and the like.

Furthermore, in addition to the fluororesin described above, quartz and an electropolished metallic material (that is, a metallic material having undergone electropolishing) are also preferably used for the inner wall of the container (particularly, the container body).

For manufacturing the electropolished metallic material, it is preferable to use a metallic material which contains at least one kind of metal selected from the group consisting of chromium and nickel, and in which the total content of chromium and nickel is more than 25% by mass with respect to the total mass of the metallic material. Examples of such a metallic material include stainless steel and a nickel-chromium alloy.

The total content of chromium and nickel in the metallic material is preferably 30% by mass or more with respect to the total mass of the metallic material.

The upper limit of the total content of chromium and nickel in the metallic material is not particularly limited, but is preferably 90% by mass or less with respect to the total mass of the metallic material.

The stainless steel is not particularly limited, and known stainless steel can be used. Particularly, an alloy with a nickel content of 8% by mass or more is preferable, and austenite-based stainless steel with a nickel content of 8% by mass or more is more preferable.

Examples of the austenite-based stainless steel include Steel Use Stainless (SUS) 304 (Ni content: 8% by mass, Cr content: 18% by mass), SUS304L (Ni content: 9% by mass, Cr content: 18% by mass), SUS316 (Ni content: 10% by mass, Cr content: 16% by mass), and SUS316L (Ni content: 12% by mass, Cr content: 16% by mass).

The nickel-chromium alloy is not particularly limited, and known nickel-chromium alloys can be used. Among these, a nickel-chromium alloy is preferable in which the nickel content is 40% to 75% by mass and the chromium content is 1% to 30% by mass.

Examples of the nickel-chromium alloy include HASTELLOY (trade name, the same is true of the following description), MONEL (trade name, the same is true of the following description), and INCONEL (trade name, the same is true of the following description). More specifically, examples thereof include HASTELLOY C-276 (Ni content: 63% by mass, Cr content: 16% by mass), HASTELLOY C (Ni content: 60% by mass, Cr content: 17% by mass), and HASTELLOY C-22 (Ni content: 61% by mass, Cr content: 22% by mass).

Furthermore, as necessary, the nickel-chromium alloy may further contain boron, silicon, tungsten, molybdenum, copper, or cobalt, in addition to the aforementioned alloy.

The method of electropolishing the metallic material is not particularly limited, and known methods can be used. For example, it is possible to use the methods described in paragraphs “0011” to “0014” in JP2015-227501A, paragraphs “0036” to “0042” in JP2008-264929A, and the like.

It is preferable that the metallic material have undergone buffing. As the buffing method, known methods can be used without particular limitation. The size of abrasive grains used for finishing the buffing is not particularly limited, but is preferably #400 or less because such grains make it easy to further reduce the surface asperity of the metallic material.

The buffing is preferably performed before the electropolishing.

Furthermore, one of the multistage buffing carried out by changing the size of abrasive grains, acid pickling, magnetorheological finishing, and the like or a combination of two or more treatments selected from the above may be performed on the metallic material.

It is preferable that the inside of these containers (such as the container body and the cap) be washed before the containers are filled with the treatment liquid. For washing, it is preferable to use a liquid with a lower metal impurity content.

After being manufactured, the treatment liquid may be bottled using a container, such as a gallon bottle or a quart bottle, and transported or stored.

In order to prevent changes in the components of the treatment liquid during storage, the inside of the container may be purged with an inert gas (such as nitrogen or argon) having a purity of 99.99995% by volume or higher. Particularly, a gas with a low moisture content is preferable. Although the treatment liquid may be transported and stored at room temperature, in order to prevent deterioration, the temperature may be controlled in a range of −20° C. to 20° C.

The treatment liquid may be prepared as a kit composed of a plurality of separated raw materials of the treatment liquid.

Furthermore, the treatment liquid may be prepared as a concentrated solution. In a case where the treatment liquid is prepared as a concentrated solution, the concentration factor is appropriately determined depending on the composition, but is preferably 5× to 2,000×. That is, the concentrated solution is used after being diluted 5× to 2,000×.

[Method for Treating Object to be Treated]

<Object to be Treated>

The treatment liquid according to the embodiment of the present invention is preferably applied to a method for treating an object to be treated containing SiGe (hereinafter, the method will be also simply called “the present treatment method”).

In the present treatment method, it is preferable to remove (etch) at least a part of SiGe contained in the object to be treated.

SiGe is a material consisting of a combination of silicon (Si) and germanium (Ge), and is preferably used as a semiconductor material.

SiGe may intentionally or inevitably contain components other than silicon and germanium. In SiGe, the total content of silicon and germanium with respect to the total mass of SiGe is preferably 95% to 100% by mass, more preferably 99% to 100% by mass, and even more preferably 99.9% to 100% by mass.

In SiGe, the element ratio of silicon (Si):germanium (Ge) (ratio between atom % of Si atoms in SiGe and atom % of Ge atoms in SiGe, Si:Ge) is preferably 99:1 to 30:70, more preferably 95:5 to 50:50, and even more preferably 85:15 to 65:35.

The form of the object to be treated is not particularly limited as long as the object to be treated contains SiGe. Examples thereof include an object 200 to be treated shown in FIG. 2 containing a substrate 202 and SiGe 204 and other materials 206 that are alternately laminated on the substrate 202.

FIG. 2 shows an aspect in which the object 200 to be treated contains a plurality of SiGe 204 and a plurality of other materials 206. However, either or both of the plurality of SiGe 204 and the plurality of other materials 206 may be present as a single layer. Furthermore, the substrate 202 shown in FIG. 2 has a site where none of the SiGe 204 and other materials 206 exist. However, such a site may be covered with the SiGe 204. In FIG. 2, the SiGe 204 is disposed directly on the substrate 202. However, the SiGe 204 may be disposed via another layer.

The other materials 206 may be other than SiGe. Furthermore, the plurality of other materials 206 may be different layers. Particularly, it is preferable that the object 200 to be treated have at least a piece of other materials 206 which is silicon (Si).

The type of substrate contained in the object to be treated is not particularly limited. Examples of the substrate include various substrates such as a semiconductor wafer, a glass substrate for a photomask, a glass substrate for liquid crystal display, a glass substrate for plasma display, a substrate for field emission display (FED), a substrate for an optical disk, a substrate for a magnetic disk, and a substrate for a magneto-optical disk.

Examples of materials constituting the semiconductor substrate include silicon, a Group III-V compound such as GaAs, and any combination of these.

Especially, it is preferable that the substrate be consist of silicon (Si).

The size, thickness, shape, layer structure, and the like of the substrate are not particularly limited, and can be appropriately selected as desired.

The object to be treated may contain a metal hard mask. For example, the object 200 to be treated shown in FIG. 2 may further contain a metal hard mask.

Examples of the metal hard mask include a metal hard mask containing one or more kinds of substances among Cu, Co, W, AlOₓ, AlN, AlOₓN_{y}, WOₓ, Ti, TiN, ZrOₓ, HfOₓ, and TaOₓ (x represents a number of 1 to 3, and y represents a number of 1 or 2).

It is preferable that the metal hard mask contain one or more kinds of substances among Cu, Co, W, AlOₓ, AlN, AlOₓN_{y}, WOₓ, Ti, TiN, ZrOₓ, HfOₓ, and TaOₓ. The content of one or more kinds of such substances with respect to the total mass of the metal hard mask is preferably 30% to 100% by mass, more preferably 60% to 100% by mass, and even more preferably 95% to 100% by mass.

The forms of SiGe and/or other materials that the object to be treated contains are not particularly limited. For example, these materials may be in the form of a film, wiring line, or particles.

In a case where SiGe and/or other materials are in the form of a film, the thickness thereof is not particularly limited and may be appropriately selected depending on the use. For example, the thickness is 1 to 50 nm.

SiGe and/or other materials may be disposed only on one of the main surfaces of the substrate, or may be disposed on both the main surfaces of the substrate. Furthermore, SiGe and/or other materials may-be disposed on the entire main surface of the substrate, or may be disposed on a portion of the main surface of the substrate.

The object to be treated may contain various layers and/or structures as desired, in addition to SiGe and/or other materials. For example, the substrate may have a metal wire, a gate electrode, a source electrode, a drain electrode, an insulating layer, a ferromagnetic layer, and/or a non-magnetic layer, and the like.

The substrate may include the structure of an exposed integrated circuit, for example, an interconnection mechanism such as a metal wire and a dielectric material. Examples of metals and alloys used for the interconnection mechanism include aluminum, a copper-aluminum alloy, copper, titanium, tantalum, cobalt, silicon, titanium nitride, tantalum nitride, and tungsten. The substrate may include a layer of silicon oxide, silicon nitride, silicon carbide, and/or carbon-doped silicon oxide.

The method for manufacturing the object to be treated is not particularly limited. For example, the object to be treated shown in FIG. 2 may be manufactured by a method of forming an insulating film on a substrate, disposing SiGe and the like on the insulating film by a sputtering method, a chemical vapor deposition (CVD) method, a molecular beam epitaxy (MBE) method, or the like, and then performing a smoothing treatment such as CMP.

<Treatment Method>

Examples of the method for treating an object to be treated according to an embodiment of the present invention include a method of bringing an object to be treated containing at least SiGe into contact with the treatment liquid described above so that SiGe is dissolved.

The method of bringing the object to be treated into contact with the treatment liquid is not particularly limited, and examples thereof include a method of immersing the object to be treated in the treatment liquid stored in a tank, a method of spraying the treatment liquid onto the object to be treated, a method of causing the treatment liquid to flow on the object to be treated, and a combined method consisting of any of the above methods. Among these, the method of immersing the object to be treated in the treatment liquid is preferable.

In order to further enhance the washing ability of the treatment liquid, a mechanical stirring method may also be used.

Examples of the mechanical stirring method include a method of circulating the treatment liquid on an object to be treated, a method of causing the treatment liquid to flow on the object to be treated or spraying the treatment liquid onto the object to be treated, and a method of stirring the treatment liquid by using ultrasonic or megasonic waves.

The contact time between the object to be treated and the treatment liquid can be adjusted as appropriate.

The treatment time (the contact time between the treatment liquid and the object to be treated) is not particularly limited, but is preferably 0.25 to 20 minutes, and more preferably 0.5 to 15 minutes.

The temperature of the treatment liquid during the treatment is not particularly limited, but is preferably 20° C. to 75° C. and more preferably 20° C. to 60° C.

By the treatment performed as above, mainly SiGe in the object to be treated is dissolved.

The dissolution rate of SiGe is, for example, preferably 10 Å/min or more, more preferably 40 to 300 Å/min, even more preferably 50 to 200 Å/min, and particularly preferably 70 to 150 Å/min.

In a case where the object to be treated contains other materials (for example, silicon) in addition to SiGe, the other materials may or may not be dissolved together with SiGe by the present treatment. In a case where the other materials are dissolved, the dissolution of the other materials may be intentional or inevitable.

In a case where the dissolution of the other materials is unintentional, it is preferable that the amount of the inevitably dissolved other materials be small.

A substance that inevitably dissolves a material in a small amount even though the dissolution is not intended is also described as a substance to which the material has excellent resistance as a member.

For example, the treatment liquid is preferably a substance to which silicon as has excellent resistance as a member.

In the present treatment, the dissolution rate of silicon is preferably less than 10 Å/min, more preferably 0.01 to 5 Å/min, even more preferably 0.01 to 1 Å/min, and particularly preferably 0.01 to 0.5 Å/min.

In the present treatment method, SiGe contained in the object to be treated may be partially or totally dissolved.

The object 200 to be treated shown in FIG. 3 is a form of the object 200 to be treated shown in FIG. 2 that has been treated by the present treatment method.

In the object 200 to be treated shown in FIG. 3, other materials 206 are materials (such as silicon) that are not intended to dissolve, SiGe 204 is partially dissolved from lateral surfaces thereof and forms recess portions.

In the object 200 to be treated having the configuration shown in FIG. 2, in a case where other materials 206 are materials that are not intended to be dissolved, and SiGe 204 is to be totally dissolved by the present treatment method, it is also preferable that the other materials 206 be supported by other materials which are not shown in the drawing.

As necessary, the present treatment method may include a rinsing step of performing a rinsing treatment on the object to be treated by using a rinsing liquid.

For example, a rinsing step may be additionally performed after the object to be treated is brought into contact with the treatment liquid.

As the rinsing liquid, for example, water, hydrofluoric acid (preferably 0.001% to 1% by mass hydrofluoric acid), hydrochloric acid (preferably 0.001% to 1% by mass hydrochloric acid), hydrogen peroxide water (preferably 0.5% to 31% by mass hydrogen peroxide water, and more preferably 3% to 15% by mass hydrogen peroxide water), a mixed solution of hydrofluoric acid and hydrogen peroxide water (FPM), a mixed solution of sulfuric acid and hydrogen peroxide water (SPM), a mixed solution of aqueous ammonia and hydrogen peroxide water (APM), a mixed solution of hydrochloric acid and hydrogen peroxide water (HPM), aqueous carbon dioxide (preferably 10 to 60 ppm by mass aqueous carbon dioxide), aqueous ozone (preferably 10 to 60 ppm by mass aqueous ozone), aqueous hydrogen (preferably 10 to 20 ppm by mass aqueous hydrogen), an aqueous citric acid solution (preferably a 0.01% to 10% by mass aqueous citric acid solution), sulfuric acid (preferably a 1% to 10% by mass aqueous sulfuric acid solution), aqueous ammonia (preferably 0.01% to 10% by mass aqueous ammonia), isopropyl alcohol (IPA), an aqueous hypochlorous acid solution (preferably a 1% to 10% by mass aqueous hypochlorous acid solution), aqua regia (preferably aqua regia obtained by mixing together “37% by mass hydrochloric acid:60% by mass nitric acid” at a volume ratio of “2.6:1.4” to “3.4:0.6”), ultrapure water, nitric acid (preferably 0.001% to 1% by mass nitric acid), perchloric acid (preferably 0.001% to 1% by mass perchloric acid), an aqueous oxalic acid solution (preferably a 0.01% to 10% by mass aqueous oxalic acid solution), acetic acid (preferably a 0.01% to 10% by mass aqueous acetic acid solution or an undiluted acetic acid solution), or an aqueous periodic acid solution (preferably a 0.5% to 10% by mass aqueous periodic acid solution, examples of the periodic acid include orthoperiodic acid and metaperiodic acid) is preferable.

The composition of APM is, for example, preferably in a range of “aqueous ammonia:hydrogen peroxide water:water=1:1:1” to “aqueous ammonia:hydrogen peroxide water:water=1:3:45” (mass ratio).

The composition of FPM is, for example, preferably in a range of “hydrofluoric acid:hydrogen peroxide water:water=1:1:1” to “hydrofluoric acid:hydrogen peroxide water:water=1:1:200” (mass ratio).

The composition of SPM is, for example, preferably in a range of “sulfuric acid:hydrogen peroxide water:water=3:1:0” to “sulfuric acid:hydrogen peroxide water:water=1:1:10” (mass ratio).

The composition of HPM is, for example, preferably in a range of “hydrochloric acid:hydrogen peroxide water:water=1:1:1” to “hydrochloric acid:hydrogen peroxide water:water=1:1:30” (mass ratio).

The preferred compositional ratio described above means a compositional ratio determined in a case where the content of aqueous ammonia is 28% by mass, the content of hydrofluoric acid is 49% by mass, the content of sulfuric acid is 98% by mass, the content of hydrochloric acid is 37% by mass, and the content of hydrogen peroxide water is 30% by mass.

Furthermore, the volume ratio is based on a volume at room temperature.

“A:B:C=x:y:z to A:B:C=X:Y:Z” used above to describe a suitable range means that it is preferable that at least one (preferably two and more preferably all) of “A:B=x:y to A:B=X:Y”, “B:C=y:z to B:C=Y:Z”, or “A:C=x:z to A:C=X:Z” be satisfied.

The hydrofluoric acid, nitric acid, perchloric acid, and hydrochloric acid mean aqueous solutions obtained by dissolving HF, HNO₃, HClO₄, and HCl in water respectively.

The aqueous ozone, aqueous carbon dioxide, and aqueous hydrogen mean aqueous solutions obtained by dissolving O₃, CO₂, and H₂ in water respectively.

As long as the purpose of the rinsing step is not impaired, these rinsing liquids may be used by being mixed together.

The rinsing liquid may also contain an organic solvent.

Examples of the specific method of the rinsing step include a method of bringing the rinsing liquid into contact with the object to be treated.

The method of bringing the rinsing liquid into contact with the object to be treated is performed by a method of immersing the substrate in the rinsing liquid stored in a tank, a method of spraying the rinsing liquid onto the substrate, a method of causing the rinsing liquid to flow on the substrate, or a combined method consisting of any of the above methods.

The treatment time (contact time between the rinsing liquid and the object to be treated) is not particularly limited, but is 5 seconds to 5 minutes for example.

The temperature of the rinsing liquid during the treatment is not particularly limited. Generally, the temperature of the rinsing liquid is, for example, preferably 16° C. to 60° C., and more preferably 18° C. to 40° C. In a case where SPM is used as the rinsing liquid, the temperature thereof is preferably 90° C. to 250° C.

As necessary, the present treatment method may include a drying step of performing a drying treatment after the rinsing step. The method of the drying treatment is not particularly limited, and examples thereof include spin drying, causing a drying gas to flow on the substrate, heating the substrate by a heating unit such as a hot plate or an infrared lamp, isopropyl alcohol (IPA) vapor drying, Marangoni drying, Rotagoni drying, and any combination of these.

The drying time varies with the specific method to be used, but is about 30 seconds to a few minutes in general.

The present treatment method may be used for washing an object to be treated.

More specifically, for example, by being applied to an object to be treated which is a substrate having undergone etching, the treatment liquid may be used for washing for removing dry etching residues on the substrate.

At this time, the dry etching residues may or may not contain SiGe.

Furthermore, the object to be treated may or may not contain SiGe in a form other than the dry etching residues.

Examples of the washing treatment method of applying the treatment liquid to an object to be treated for washing described above include a method of bringing the object to be treated into contact with the treatment liquid. Specifically, the washing treatment method may be the same as the method of bringing an object to be treated into contact with the treatment liquid that is described above regarding the aforementioned method of dissolving SiGe.

After the washing treatment, either or both of the rinsing step and the drying treatment may be performed which are described above regarding the aforementioned method of dissolving SiGe.

In addition, the washing treatment may be performed simultaneously with the aforementioned method of dissolving SiGe.

The treatment method using the treatment liquid may be performed in combination with a semiconductor device manufacturing method, before or after the steps performed in the manufacturing method. While being performed, the present treatment method may be incorporated into those other steps. Alternatively, while those other steps are being performed, the present treatment method may be incorporated into the steps and performed.

Examples of those other steps include a step of forming each structure such as a metal wire, a gate structure, a source structure, a drain structure, an insulating layer, a ferromagnetic layer and/or a non-magnetic layer (layer formation, etching, chemical mechanical polishing, modification, and the like), a step of forming resist, an exposure step and a removing step, a heat treatment step, a washing step, an inspection step, and the like.

The present treatment method may be performed in the back end process (BEOL: back end of the line) or in the front end process (FEOL: front end of the line).

In addition, the treatment liquid may be applied, for example, to NAND, dynamic random access memory (DRAM), static random access memory (SRAM), resistive random access memory (ReRAM), ferroelectric random access memory (FRAM (registered trademark)), magnetoresistive random access memory (MRAM), phase change random access memory (PRAM), or the like, or applied to a logic circuit, a processor, or the like.

### EXAMPLES

Hereinafter, the present invention will be more specifically described based on examples. The materials, the amounts and ratios of the materials used, the details of treatments, the procedures of treatments, and the like shown in the following examples can be appropriately changed as long as the gist of the present invention is maintained. Therefore, the scope of the present invention is not limited to the following examples.

[Preparation of Treatment Liquid]

The compounds (a fluoride ion source, an oxidant, an acetate solvent, and an additive) and water shown in the following tables were mixed together so that the content of each compound conformed to the values shown in the tables, thereby preparing treatment liquids to be used in each test.

In the treatment liquid, all the components (remainders) other than the above compounds are water.

Unless otherwise specified, each polymer used as an additive contains only a representative repeating unit configuring the polymer of the name in the tables. For example, polyvinyl alcohol used in examples contains only a repeating unit represented by —CH₂—CH(OH)—. In addition, the phenolsulfonic acid formaldehyde condensate used in examples contains only a repeating unit formed by the condensation of phenolsulfonic acid and formaldehyde.

As each raw material, a semiconductor grade high-purity raw material was used. As necessary, a purification treatment was additionally performed on the raw material.

[Test X]

<Test and Evaluation>

A substrate on which silicon-germanium (Si:Ge=75:25 (element ratio)) was laminated at a film thickness of 100 nm and a substrate on which polysilicon was laminated at a film thickness of 100 nm were prepared. Each of these substrates was cut in a size of 2×2 cm, thereby obtaining test pieces.

Each test piece was immersed in the treatment liquid (25° C.) of each of examples or comparative examples for 10 minutes.

The film thickness of each of the films (the silicon-germanium film and the polysilicon film) before and after immersion was measured with an optical film thickness meter Ellipsometer M-2000 (manufactured by J. A. Woollam), and the dissolution rate (Å/min) was calculated. The higher the dissolving ability for silicon-germanium, the more preferable. The lower the dissolving ability for polysilicon, the more preferable.

Furthermore, the surface of the silicon-germanium film after immersion was observed using an atomic force microscope (AFM Dimension Icon, manufactured by Bruker) to determine the surface roughness Ra, and the surface roughness of the silicon-germanium film after treatment was evaluated.

The evaluation standard is shown below.

In any of the evaluations, the closer the grade is to A, the better the evaluation result.

Regarding the evaluation of “SiGe ER” and “Si ER”, in a case where a treatment liquid is graded C or higher in both the “SiGe ER” and “Si ER” and is graded B or higher in at least either “SiGe ER” or “Si ER”, the treatment liquid is determined as having excellent dissolution selectivity for SiGe and being applicable to an etching treatment for SiGe.

(SiGe ER (Dissolution Rate for Silicon-Germanium))

A: 70 Å/min or more

B: 50 Å/min or more and less than 70 Å/min

C: 40 Å/min or more and less than 50 Å/min

D: 10 Å/min or more and less than 40 Å/min

E: Less than 10 Å/min

(Si ER (Dissolution Rate for Polysilicon))

A: Less than 0.5 Å/min

B: 0.5 Å/min or more and less than 1 Å/min

C: 1 Å/min or more and less than 5 Å/min

D: 5 Å/min or more

(SiGe Surface Roughness (Surface Roughness of Silicon-Germanium Film After Treatment))

A: Ra (surface roughness) is 0.10 nm or less

B: Ra is more than 0.10 nm and 0.20 nm or less

C: Ra is more than 0.20 nm and 0.30 nm or less

D: Ra is more than 0.30 nm

<Result>

Table 1 shows the formulation of the treatment liquids used in the series of test X and the test results.

In Table 1, the column of “Amount (%)” shows the content (% by mass) of each component with respect to the total amount of treatment liquid.

NH4F in the column of “Fluoride ion source” means NH₄F (ammonium fluoride).

TABLE 1

| | Fluoride ion source | | Oxidant | | Acetate solvent | | Additive | | | | SiGe |
|---|---|---|---|---|---|---|---|---|---|---|---|
| | | Amount | | Amount | | Amount | | Amount | SiGe | Si | Surface |
| Table 1-1 | Type | (%) | Type | (%) | Type | (%) | Type | (%) | ER | ER | roughness |
| Example 1 | HF | 0.5 | Peracetic | 8 | Methyl | 30 | Polyethylene | 0.5 | A | B | B |
| | | | acid | | acetate | | glycol | | | | |
| Example 2 | HF | 0.5 | Peracetic | 8 | Methyl | 30 | Polyethyleneimine | 0.5 | A | B | B |
| | | | acid | | acetate | | | | | | |
| Example 3 | HF | 0.5 | Peracetic | 8 | Methyl | 30 | Dodecylbenzenesulfonic | 0.5 | A | B | B |
| | | | acid | | acetate | | acid | | | | |
| Example 4 | HF | 0.5 | Peracetic | 8 | Methyl | 30 | Dodecyl diphenyl ether | 0.5 | A | B | B |
| | | | acid | | acetate | | disulfonic acid | | | | |
| Example 5 | HF | 0.5 | Peracetic | 8 | Methyl | 30 | Phenolsulfonic acid | 0.5 | A | B | B |
| | | | acid | | acetate | | formaldehyde condensate | | | | |
| Example 6 | HF | 0.5 | Peracetic | 8 | Ethyl | 30 | Polyethylene glycol | 0.5 | A | A | A |
| | | | acid | | acetate | | | | | | |
| Example 7 | HF | 0.5 | Peracetic | 8 | Ethyl | 30 | Polypropylene glycol | 0.5 | B | A | B |
| | | | acid | | acetate | | | | | | |
| Example 8 | HF | 0.5 | Peracetic | 8 | Ethyl | 30 | Polyvinyl alcohol | 0.5 | B | A | B |
| | | | acid | | acetate | | | | | | |
| Example 9 | HF | 0.5 | Peracetic | 8 | Ethyl | 30 | Polyacrylic acid | 0.5 | B | A | B |
| | | | acid | | acetate | | | | | | |
| Example 10 | HF | 0.5 | Peracetic | 8 | Ethyl | 30 | Polystyrene sulfonic | 0.5 | B | A | B |
| | | | acid | | acetate | | acid | | | | |
| Example 11 | HF | 0.5 | Peracetic | 8 | Ethyl | 30 | Polyvinylpyrrolidone | 0.5 | B | A | B |
| | | | acid | | acetate | | | | | | |
| Example 12 | HF | 0.5 | Peracetic | 8 | Ethyl | 30 | Polyethyleneimine | 0.5 | A | A | A |
| | | | acid | | acetate | | | | | | |
| Example 13 | HF | 0.5 | Peracetic | 8 | Ethyl | 30 | Polyallylamine | 0.5 | B | A | B |
| | | | acid | | acetate | | | | | | |
| Example 14 | HF | 0.5 | Peracetic | 8 | Ethyl | 30 | Polyvinylamine | 0.5 | B | A | B |
| | | | acid | | acetate | | | | | | |
| Example 15 | HF | 0.5 | Peracetic | 8 | Ethyl | 30 | Polyacrylamide | 0.5 | B | A | B |
| | | | acid | | acetate | | | | | | |
| Example 16 | HF | 0.5 | Peracetic | 8 | Ethyl | 30 | Dimethylamine- | 0.5 | B | A | B |
| | | | acid | | acetate | | epihalohydrin copolymer | | | | |
| Example 17 | HF | 0.5 | Peracetic | 8 | Ethyl | 30 | Hexadimethrine | 0.5 | B | A | B |
| | | | acid | | acetate | | chloride | | | | |
| Example 18 | HF | 0.5 | Peracetic | 8 | Ethyl | 30 | Polydiallylamine | 0.5 | B | A | B |
| | | | acid | | acetate | | | | | | |
| Example 19 | HF | 0.5 | Peracetic | 8 | Ethyl | 30 | Polydimethyldiallylammonium | 0.5 | B | A | B |
| | | | acid | | acetate | | chloride | | | | |
| Example 20 | HF | 0.5 | Peracetic | 8 | Ethyl | 30 | Poly(4-vinylpyridine) | 0.5 | B | A | B |
| | | | acid | | acetate | | | | | | |
| Example 21 | HF | 0.5 | Peracetic | 8 | Ethyl | 30 | Polyornithine | 0.5 | B | A | B |
| | | | acid | | acetate | | | | | | |
| Example 22 | HF | 0.5 | Peracetic | 8 | Ethyl | 30 | Polylysine | 0.5 | B | A | B |
| | | | acid | | acetate | | | | | | |
| Example 23 | HF | 0.5 | Peracetic | 8 | Ethyl | 30 | Polyarginine | 0.5 | B | A | B |
| | | | acid | | acetate | | | | | | |
| Example 24 | HF | 0.5 | Peracetic | 8 | Ethyl | 30 | Polyhistidine | 0.5 | B | A | B |
| | | | acid | | acetate | | | | | | |
| Example 25 | HF | 0.5 | Peracetic | 8 | Ethyl | 30 | Polyvinylimidazole | 0.5 | B | A | B |
| | | | acid | | acetate | | | | | | |
| Example 26 | HF | 0.5 | Peracetic | 8 | Ethyl | 30 | Polymethyldiallylamine | 0.5 | B | A | B |
| | | | acid | | acetate | | | | | | |
| Example 27 | HF | 0.5 | Peracetic | 8 | Ethyl | 30 | Dodecylbenzenesulfonic | 0.5 | A | A | A |
| | | | acid | | acetate | | acid | | | | |
| Example 28 | HF | 0.5 | Peracetic | 8 | Ethyl | 30 | Propyl | 0.5 | B | A | B |
| | | | acid | | acetate | | naphthalenesulfonic acid | | | | |
| Example 29 | HF | 0.5 | Peracetic | 8 | Ethyl | 30 | Triisopropyl | 0.5 | B | A | B |
| | | | acid | | acetate | | naphthalenesulfonic acid | | | | |
| Example 30 | HF | 0.5 | Peracetic | 8 | Ethyl | 30 | Dibutyl | 0.5 | B | A | B |
| | | | acid | | acetate | | naphthalenesulfonic acid | | | | |

TABLE 2

| | Fluoride ion source | | Oxidant | | Acetate solvent | | Additive | | | | SiGe |
|---|---|---|---|---|---|---|---|---|---|---|---|
| | | Amount | | Amount | | Amount | | Amount | SiGe | Si | Surface |
| Table 1-2 | Type | (%) | Type | (%) | Type | (%) | Type | (%) | ER | ER | roughness |
| Example 31 | HF | 0.5 | Peracetic | 8 | Ethyl | 30 | Dodecyl diphenyl ether | 0.5 | A | A | A |
| | | | acid | | acetate | | disulfonic acid | | | | |
| Example 32 | HF | 0.5 | Peracetic | 8 | Ethyl | 30 | Phenolsulfonic acid | 0.5 | A | A | A |
| | | | acid | | acetate | | formaldehyde condensate | | | | |
| Example 33 | HF | 0.5 | Peracetic | 8 | Ethyl | 30 | Phenyl phenolsulfonic acid | 0.5 | B | A | B |
| | | | acid | | acetate | | formaldehyde condensate | | | | |
| Example 34 | HF | 0.5 | Peracetic | 8 | Ethyl | 30 | Polyoxyethylene lauryl | 0.5 | B | A | B |
| | | | acid | | acetate | | ether sulfonic acid | | | | |
| Example 35 | HF | 0.5 | Peracetic | 8 | Ethyl | 30 | Polyoxyethylene oleyl | 0.5 | B | A | B |
| | | | acid | | acetate | | ether sulfonic acid | | | | |
| Example 36 | HF | 0.5 | Peracetic | 8 | Ethyl | 30 | Polyoxyethylene octyldodecyl | 0.5 | B | A | B |
| | | | acid | | acetate | | ether sulfonic acid | | | | |
| Example 37 | HF | 0.5 | Peracetic | 8 | Ethyl | 30 | Dodecanoic acid | 0.5 | B | A | B |
| | | | acid | | acetate | | | | | | |
| Example 38 | HF | 0.5 | Peracetic | 8 | Ethyl | 30 | Hexadecanoic acid | 0.5 | B | A | B |
| | | | acid | | acetate | | | | | | |
| Example 39 | HF | 0.5 | Peracetic | 8 | Ethyl | 30 | Oleic acid | 0.5 | B | A | B |
| | | | acid | | acetate | | | | | | |
| Example 40 | HF | 0.5 | Peracetic | 8 | Ethyl | 30 | Juniperic acid | 0.5 | B | A | B |
| | | | acid | | acetate | | | | | | |
| Example 41 | HF | 0.5 | Peracetic | 8 | Ethyl | 30 | Stearic acid | 0.5 | B | A | B |
| | | | acid | | acetate | | | | | | |
| Example 42 | HF | 0.5 | Peracetic | 8 | Ethyl | 30 | 12-Hydroxystearic | 0.5 | B | A | B |
| | | | acid | | acetate | | acid | | | | |
| Example 43 | HF | 0.5 | Peracetic | 8 | Ethyl | 30 | Perfluorooctanoic | 0.5 | B | A | B |
| | | | acid | | acetate | | acid | | | | |
| Example 44 | HF | 0.5 | Peracetic | 8 | Ethyl | 30 | Perfluoroheptanoic | 0.5 | B | A | B |
| | | | acid | | acetate | | acid | | | | |
| Example 45 | HF | 0.5 | Peracetic | 8 | Ethyl | 30 | Perfluorodecanoic | 0.5 | B | A | B |
| | | | acid | | acetate | | acid | | | | |
| Example 46 | HF | 0.5 | Peracetic | 8 | Ethyl | 30 | Polyoxyethylene lauryl | 0.5 | B | A | B |
| | | | acid | | acetate | | ether carboxylic acid | | | | |
| Example 47 | HF | 0.5 | Peracetic | 8 | Ethyl | 30 | Polyoxyethylene dodecyl | 0.5 | B | A | B |
| | | | acid | | acetate | | ether carboxylic acid | | | | |
| Example 48 | HF | 0.5 | Peracetic | 8 | Ethyl | 30 | Polyoxyethylene tridecyl | 0.5 | B | A | B |
| | | | acid | | acetate | | ether carboxylic acid | | | | |
| Example 49 | HF | 0.5 | Peracetic | 8 | Ethyl | 30 | Bis(2-ethylhexyl)phosphate | 0.5 | B | A | B |
| | | | acid | | acetate | | | | | | |
| Example 50 | HF | 0.5 | Peracetic | 8 | Ethyl | 30 | Dioctadecylphosphate | 0.5 | B | A | B |
| | | | acid | | acetate | | | | | | |
| Example 51 | HF | 0.5 | Peracetic | 8 | Ethyl | 30 | Octadecylphosphate | 0.5 | B | A | B |
| | | | acid | | acetate | | | | | | |
| Example 52 | HF | 0.5 | Peracetic | 8 | Ethyl | 30 | Dodecylphosphate | 0.5 | B | A | B |
| | | | acid | | acetate | | | | | | |
| Example 53 | HF | 0.5 | Peracetic | 8 | Ethyl | 30 | Decyl phosphonic | 0.5 | B | A | B |
| | | | acid | | acetate | | acid | | | | |
| Example 54 | HF | 0.5 | Peracetic | 8 | Ethyl | 30 | Dodecyl phosphonic | 0.5 | B | A | B |
| | | | acid | | acetate | | acid | | | | |
| Example 55 | HF | 0.5 | Peracetic | 8 | Ethyl | 30 | Tetradecyl phosphonic | 0.5 | B | A | B |
| | | | acid | | acetate | | acid | | | | |
| Example 56 | HF | 0.5 | Peracetic | 8 | Ethyl | 30 | Hexadecyl phosphonic | 0.5 | B | A | B |
| | | | acid | | acetate | | acid | | | | |
| Example 57 | HF | 0.5 | Peracetic | 8 | Ethyl | 30 | Octadecyl phosphonic | 0.5 | B | A | B |
| | | | acid | | acetate | | acid | | | | |
| Example 58 | HF | 0.5 | Peracetic | 8 | Ethyl | 30 | Polyoxyethylene alkyl | 0.5 | B | A | B |
| | | | acid | | acetate | | phenyl ether phosphoric | | | | |
| | | | | | | | acid | | | | |
| Example 59 | HF | 0.5 | Peracetic | 8 | Ethyl | 30 | Polyoxyethylene lauryl | 0.5 | B | A | B |
| | | | acid | | acetate | | ether phosphoric acid | | | | |
| Example 60 | HF | 0.5 | Peracetic | 8 | Ethyl | 30 | Cetyltrimethylammonium | 0.5 | B | A | B |
| | | | acid | | acetate | | chloride | | | | |

TABLE 3

| | Fluoride ion source | | Oxidant | | Acetate solvent | | Additive | | | | SiGe |
|---|---|---|---|---|---|---|---|---|---|---|---|
| | | Amount | | Amount | | Amount | | Amount | SiGe | Si | Surface |
| Table 1-3 | Type | (%) | Type | (%) | Type | (%) | Type | (%) | ER | ER | roughness |
| Example 61 | HF | 0.5 | Peracetic | 8 | Ethyl | 30 | Cetyltrimethylammonium | 0.5 | B | A | B |
| | | | acid | | acetate | | bromide | | | | |
| Example 62 | HF | 0.5 | Peracetic | 8 | Ethyl | 30 | Stearyltrimethylammonium | 0.5 | B | A | B |
| | | | acid | | acetate | | chloride | | | | |
| Example 63 | HF | 0.5 | Peracetic | 8 | Ethyl | 30 | Stearyltrimethylammonium | 0.5 | B | A | B |
| | | | acid | | acetate | | bromide | | | | |
| Example 64 | HF | 0.5 | Peracetic | 8 | Ethyl | 30 | Laurylpyridinium | 0.5 | B | A | B |
| | | | acid | | acetate | | chloride | | | | |
| Example 65 | HF | 0.5 | Peracetic | 8 | Ethyl | 30 | Laurylpyridinium | 0.5 | B | A | B |
| | | | acid | | acetate | | bromide | | | | |
| Example 66 | HF | 0.5 | Peracetic | 8 | Ethyl | 30 | Cetylpyridinium | 0.5 | B | A | B |
| | | | acid | | acetate | | chloride | | | | |
| Example 67 | HF | 0.5 | Peracetic | 8 | Ethyl | 30 | Cetylpyridinium | 0.5 | B | A | B |
| | | | acid | | acetate | | bromide | | | | |
| Example 68 | HF | 0.5 | Peracetic | 8 | Ethyl | 30 | 4-(4-Diethylaminophenylazo)- | 0.5 | B | A | B |
| | | | acid | | acetate | | 1-(4-nitrobenzyl)pyridinium | | | | |
| | | | | | | | chloride | | | | |
| Example 69 | HF | 0.5 | Peracetic | 8 | Ethyl | 30 | 4-(4-Diethylaminophenylazo)- | 0.5 | B | A | B |
| | | | acid | | acetate | | 1-(4-nitrobenzyl)pyridinium | | | | |
| | | | | | | | bromide | | | | |
| Example 70 | HF | 0.5 | Peracetic | 8 | Ethyl | 30 | Benzalkonium | 0.5 | B | A | B |
| | | | acid | | acetate | | chloride | | | | |
| Example 71 | HF | 0.5 | Peracetic | 8 | Ethyl | 30 | Benzalkonium | 0.5 | B | A | B |
| | | | acid | | acetate | | bromide | | | | |
| Example 72 | HF | 0.5 | Peracetic | 8 | Ethyl | 30 | Benzethonium | 0.5 | B | A | B |
| | | | acid | | acetate | | chloride | | | | |
| Example 73 | HF | 0.5 | Peracetic | 8 | Ethyl | 30 | Benzethonium | 0.5 | B | A | B |
| | | | acid | | acetate | | bromide | | | | |
| Example 74 | HF | 0.5 | Peracetic | 8 | Ethyl | 30 | Benzyldimethyldodecylammonium | 0.5 | B | A | B |
| | | | acid | | acetate | | chloride | | | | |
| Example 75 | HF | 0.5 | Peracetic | 8 | Ethyl | 30 | Benzyldimethyldodecylammonium | 0.5 | B | A | B |
| | | | acid | | acetate | | bromide | | | | |
| Example 76 | HF | 0.5 | Peracetic | 8 | Ethyl | 30 | Benzyldimethylhexadecylammonium | 0.5 | B | A | B |
| | | | acid | | acetate | | chloride | | | | |
| Example 77 | HF | 0.5 | Peracetic | 8 | Ethyl | 30 | Benzyldimethylhexadecylammonium | 0.5 | B | A | B |
| | | | acid | | acetate | | bromide | | | | |
| Example 78 | HF | 0.5 | Peracetic | 8 | Ethyl | 30 | Cetyltrimethylammonium | 0.5 | B | A | B |
| | | | acid | | acetate | | chloride | | | | |
| Example 79 | HF | 0.5 | Peracetic | 8 | Ethyl | 30 | Cetyltrimethylammonium | 0.5 | B | A | B |
| | | | acid | | acetate | | bromide | | | | |
| Example 80 | HF | 0.5 | Peracetic | 8 | Ethyl | 30 | Dimethyldioctadecylammonium | 0.5 | B | A | B |
| | | | acid | | acetate | | chloride | | | | |
| Example 81 | HF | 0.5 | Peracetic | 8 | Ethyl | 30 | Dimethyldioctadecylammonium | 0.5 | B | A | B |
| | | | acid | | acetate | | bromide | | | | |
| Example 82 | HF | 0.5 | Peracetic | 8 | Ethyl | 30 | Dodecyltrimethylammonium | 0.5 | B | A | B |
| | | | acid | | acetate | | chloride | | | | |
| Example 83 | HF | 0.5 | Peracetic | 8 | Ethyl | 30 | Dodecyltrimethylammonium | 0.5 | B | A | B |
| | | | acid | | acetate | | bromide | | | | |
| Example 84 | HF | 0.5 | Peracetic | 8 | Ethyl | 30 | Didodecyldimethylammonium | 0.5 | B | A | B |
| | | | acid | | acetate | | chloride | | | | |
| Example 85 | HF | 0.5 | Peracetic | 8 | Ethyl | 30 | Didodecyldimethylammonium | 0.5 | B | A | B |
| | | | acid | | acetate | | bromide | | | | |
| Example 86 | HF | 0.5 | Peracetic | 8 | Ethyl | 30 | Tetraheptylammonium | 0.5 | B | A | B |
| | | | acid | | acetate | | chloride | | | | |
| Example 87 | HF | 0.5 | Peracetic | 8 | Ethyl | 30 | Tetraheptylammonium | 0.5 | B | A | B |
| | | | acid | | acetate | | bromide | | | | |
| Example 88 | HF | 0.5 | Peracetic | 8 | Ethyl | 30 | Tetrakis(decyl)ammonium | 0.5 | B | A | B |
| | | | acid | | acetate | | chloride | | | | |
| Example 89 | HF | 0.5 | Peracetic | 8 | Ethyl | 30 | Tetrakis(decyl)ammonium | 0.5 | B | A | B |
| | | | acid | | acetate | | bromide | | | | |
| Example 90 | HF | 0.5 | Peracetic | 8 | Ethyl | 30 | Dimethyldihexadecylammonium | 0.5 | B | A | B |
| | | | acid | | acetate | | chloride | | | | |

TABLE 4

| | Fluoride ion source | | Oxidant | | Acetate solvent | | Additive | | | | SiGe |
|---|---|---|---|---|---|---|---|---|---|---|---|
| | | Amount | | Amount | | Amount | | Amount | SiGe | Si | Surface |
| Table 1-4 | Type | (%) | Type | (%) | Type | (%) | Type | (%) | ER | ER | roughness |
| Example 91 | HF | 0.5 | Peracetic | 8 | Ethyl | 30 | Dimethyldihexadecylammonium | 0.5 | B | A | B |
| | | | acid | | acetate | | bromide | | | | |
| Example 92 | HF | 0.5 | Peracetic | 8 | Ethyl | 30 | Polyoxyethylene | 0.5 | B | A | B |
| | | | acid | | acetate | | lauryl amine | | | | |
| Example 93 | HF | 0.5 | Peracetic | 8 | Ethyl | 30 | Stearylamine | 0.5 | B | A | B |
| | | | acid | | acetate | | | | | | |
| Example 94 | HF | 0.5 | Peracetic | 8 | Ethyl | 30 | Cocamidopropyl | 0.5 | C | A | C |
| | | | acid | | acetate | | betaine | | | | |
| Example 95 | HF | 0.5 | Peracetic | 8 | Ethyl | 30 | N,N-Dimethyldodecylamine | 0.5 | C | A | C |
| | | | acid | | acetate | | N-oxide | | | | |
| Example 96 | HF | 0.5 | Peracetic | 8 | Ethyl | 30 | Lauryl dimethylaminoacetic | 0.5 | C | A | C |
| | | | acid | | acetate | | acid betaine | | | | |
| Example 97 | HF | 0.5 | Peracetic | 8 | Ethyl | 30 | Lauryldimethylamine | 0.5 | C | A | C |
| | | | acid | | acetate | | oxide | | | | |
| Example 98 | HF | 0.5 | Peracetic | 8 | Ethyl | 30 | Ethylenediamine | 1 | B | A | B |
| | | | acid | | acetate | | | | | | |
| Example 99 | HF | 0.5 | Peracetic | 8 | Ethyl | 30 | Diethylenetriamine | 1 | B | A | B |
| | | | acid | | acetate | | | | | | |
| Example 100 | HF | 0.5 | Peracetic | 8 | Ethyl | 30 | Triethylenetetramine | 1 | B | A | B |
| | | | acid | | acetate | | | | | | |
| Example 101 | HF | 0.5 | Peracetic | 8 | Ethyl | 30 | Tetraethylenepentamine | 1 | B | A | B |
| | | | acid | | acetate | | | | | | |
| Example 102 | HF | 0.5 | Peracetic | 8 | Ethyl | 30 | Pentaethylenehexamine | 1 | B | A | B |
| | | | acid | | acetate | | | | | | |
| Example 103 | HF | 0.5 | Peracetic | 8 | Ethyl | 30 | Tetramethylethylenediamine | 1 | B | A | B |
| | | | acid | | acetate | | | | | | |
| Example 104 | HF | 0.5 | Peracetic | 8 | Ethyl | 30 | Hexamethylenediamine | 1 | B | A | B |
| | | | acid | | acetate | | | | | | |
| Example 105 | HF | 0.5 | Peracetic | 8 | Ethyl | 30 | Methylamine | 1 | B | A | B |
| | | | acid | | acetate | | | | | | |
| Example 106 | HF | 0.5 | Peracetic | 8 | Ethyl | 30 | Dimethylamine | 1 | B | A | B |
| | | | acid | | acetate | | | | | | |
| Example 107 | HF | 0.5 | Peracetic | 8 | Ethyl | 30 | Trimethylamine | 1 | B | A | B |
| | | | acid | | acetate | | | | | | |
| Example 108 | HF | 0.5 | Peracetic | 8 | Ethyl | 30 | Ethylamine | 1 | B | A | B |
| | | | acid | | acetate | | | | | | |
| Example 109 | HF | 0.5 | Peracetic | 8 | Ethyl | 30 | Diethylamine | 1 | B | A | B |
| | | | acid | | acetate | | | | | | |
| Example 110 | HF | 0.5 | Peracetic | 8 | Ethyl | 30 | Triethylamine | 1 | B | A | B |
| | | | acid | | acetate | | | | | | |
| Example 111 | HF | 0.5 | Peracetic | 8 | Ethyl | 30 | 2-Ethylhexylamine | 1 | B | A | B |
| | | | acid | | acetate | | | | | | |
| Example 112 | HF | 0.5 | Peracetic | 8 | Ethyl | 30 | Cyclohexylamine | 1 | B | A | B |
| | | | acid | | acetate | | | | | | |
| Example 113 | HF | 0.5 | Peracetic | 8 | Ethyl | 30 | Aniline | 1 | B | A | B |
| | | | acid | | acetate | | | | | | |
| Example 114 | HF | 0.5 | Peracetic | 8 | Ethyl | 30 | Phenethylamine | 1 | B | A | B |
| | | | acid | | acetate | | | | | | |
| Example 115 | HF | 0.5 | Peracetic | 8 | Ethyl | 30 | Toluidine | 1 | B | A | B |
| | | | acid | | acetate | | | | | | |
| Example 116 | HF | 0.5 | Peracetic | 8 | Ethyl | 30 | m-Xylylenediamine | 1 | B | A | B |
| | | | acid | | acetate | | | | | | |
| Example 117 | HF | 0.5 | Peracetic | 8 | Ethyl | 30 | Diethanolamine | 1 | B | A | B |
| | | | acid | | acetate | | | | | | |
| Example 118 | HF | 0.5 | Peracetic | 8 | Ethyl | 30 | Diisopropanolamine | 1 | B | A | B |
| | | | acid | | acetate | | | | | | |
| Example 119 | HF | 0.5 | Peracetic | 8 | Ethyl | 30 | Triisopropanolamine | 1 | B | A | B |
| | | | acid | | acetate | | | | | | |
| Example 120 | HF | 0.5 | Peracetic | 8 | Ethyl | 30 | 2-(2-Aminoethylamino)ethanol | 1 | B | A | B |
| | | | acid | | acetate | | | | | | |

TABLE 5

| | Fluoride ion source | | Oxidant | | Acetate solvent | | Additive | | | | SiGe |
|---|---|---|---|---|---|---|---|---|---|---|---|
| | | Amount | | Amount | | Amount | | Amount | SiGe | Si | Surface |
| Table 1-5 | Type | (%) | Type | (%) | Type | (%) | Type | (%) | ER | ER | roughness |
| Example 121 | HF | 0.5 | Peracetic | 8 | Ethyl | 30 | 2-(2-Aminoethoxy)ethanol | 1 | B | A | B |
| | | | acid | | acetate | | | | | | |
| Example 122 | HF | 0.5 | Peracetic | 8 | Ethyl | 30 | Triethanolamine | 1 | B | A | B |
| | | | acid | | acetate | | | | | | |
| Example 123 | HF | 0.5 | Peracetic | 8 | Ethyl | 30 | N-Ethylethanolamine | 1 | B | A | B |
| | | | acid | | acetate | | | | | | |
| Example 124 | HF | 0.5 | Peracetic | 8 | Ethyl | 30 | N,N-dimethylethanolamine | 1 | B | A | B |
| | | | acid | | acetate | | | | | | |
| Example 125 | HF | 0.5 | Peracetic | 8 | Ethyl | 30 | N,N-diethylethanolamine | 1 | B | A | B |
| | | | acid | | acetate | | | | | | |
| Example 126 | HF | 0.5 | Peracetic | 8 | Ethyl | 30 | N-methyldiethanolamine | 1 | B | A | B |
| | | | acid | | acetate | | | | | | |
| Example 127 | HF | 0.5 | Peracetic | 8 | Ethyl | 30 | N-ethyldiethanolamine | 1 | B | A | B |
| | | | acid | | acetate | | | | | | |
| Example 128 | HF | 0.5 | Peracetic | 8 | Ethyl | 30 | Cyclohexylamine | 1 | B | A | B |
| | | | acid | | acetate | | diethanol | | | | |
| Example 129 | HF | 0.5 | Peracetic | 8 | Ethyl | 30 | N-methylethanolamine | 1 | B | A | B |
| | | | acid | | acetate | | | | | | |
| Example 130 | HF | 0.5 | Peracetic | 8 | Ethyl | 30 | Pyrrolidine | 1 | B | A | B |
| | | | acid | | acetate | | | | | | |
| Example 131 | HF | 0.5 | Peracetic | 8 | Ethyl | 30 | Piperidine | 1 | B | A | B |
| | | | acid | | acetate | | | | | | |
| Example 132 | HF | 0.5 | Peracetic | 8 | Ethyl | 30 | Piperazine | 1 | B | A | B |
| | | | acid | | acetate | | | | | | |
| Example 133 | HF | 0.5 | Peracetic | 8 | Ethyl | 30 | Morpholine | 1 | B | A | B |
| | | | acid | | acetate | | | | | | |
| Example 134 | HF | 0.5 | Peracetic | 8 | Ethyl | 30 | Pyrrole | 1 | B | A | B |
| | | | acid | | acetate | | | | | | |
| Example 135 | HF | 0.5 | Peracetic | 8 | Ethyl | 30 | Pyrazole | 1 | B | A | B |
| | | | acid | | acetate | | | | | | |
| Example 136 | HF | 0.5 | Peracetic | 8 | Ethyl | 30 | Imidazole | 1 | B | A | B |
| | | | acid | | acetate | | | | | | |
| Example 137 | HF | 0.5 | Peracetic | 8 | Ethyl | 30 | Pyridine | 1 | B | A | B |
| | | | acid | | acetate | | | | | | |
| Example 138 | HF | 0.5 | Peracetic | 8 | Ethyl | 30 | Pyrimidine | 1 | B | A | B |
| | | | acid | | acetate | | | | | | |
| Example 139 | HF | 0.5 | Peracetic | 8 | Ethyl | 30 | Pyrazine | 1 | B | A | B |
| | | | acid | | acetate | | | | | | |
| Example 140 | HF | 0.5 | Peracetic | 8 | Ethyl | 30 | Oxazole | 1 | B | A | B |
| | | | acid | | acetate | | | | | | |
| Example 141 | HF | 0.5 | Peracetic | 8 | Ethyl | 30 | Thiazole | 1 | B | A | B |
| | | | acid | | acetate | | | | | | |
| Example 142 | HF | 0.5 | Peracetic | 8 | Ethyl | 30 | 4-Dimethylaminopyridine | 1 | B | A | B |
| | | | acid | | acetate | | | | | | |
| Example 143 | HF | 0.5 | Peracetic | 8 | Ethyl | 30 | Citric acid | 1 | B | A | B |
| | | | acid | | acetate | | | | | | |
| Example 144 | HF | 0.5 | Peracetic | 8 | Ethyl | 30 | 2-Methylpropane-1,2,3- | 1 | B | A | B |
| | | | acid | | acetate | | tricarboxylic acid | | | | |
| Example 145 | HF | 0.5 | Peracetic | 8 | Ethyl | 30 | Benzene-1,2,3-tricarboxylic | 1 | B | A | B |
| | | | acid | | acetate | | acid (hemimellitic acid) | | | | |
| Example 146 | HF | 0.5 | Peracetic | 8 | Ethyl | 30 | Propane-1,2,3-tricarboxylic | 1 | B | A | B |
| | | | acid | | acetate | | acid (tricarballylic acid) | | | | |
| Example 147 | HF | 0.5 | Peracetic | 8 | Ethyl | 30 | 1,cis-2,3-Propanetricarboxylic | 1 | B | A | B |
| | | | acid | | acetate | | acid (aconitic acid) | | | | |
| Example 148 | HF | 0.5 | Peracetic | 8 | Ethyl | 30 | Butane-1,2,3,4- | 1 | B | A | B |
| | | | acid | | acetate | | tetracarboxylic acid | | | | |
| Example 149 | HF | 0.5 | Peracetic | 8 | Ethyl | 30 | Cyclopentane tetra- | 1 | B | A | B |
| | | | acid | | acetate | | 1,2,3,4-carboxylic acid | | | | |
| Example 150 | HF | 0.5 | Peracetic | 8 | Ethyl | 30 | Benzene-1,2,4,5- | 1 | B | A | B |
| | | | acid | | acetate | | tetracarboxylic acid | | | | |
| | | | | | | | (pyromellitic acid) | | | | |

TABLE 6

| | Fluoride ion | | | | | | | | | | |
|---|---|---|---|---|---|---|---|---|---|---|---|
| | source | | Oxidant | | Acetate solvent | | Additive | | | | SiGe |
| | | Amount | | Amount | | Amount | | Amount | SiGe | Si | Surface |
| Table 1-6 | Type | (%) | Type | (%) | Type | (%) | Type | (%) | ER | ER | roughness |
| Example | HF | 0.5 | Peracetic | 8 | Ethyl | 30 | Benzenepentacarboxylic acid | 1 | B | A | B |
| 151 | | | acid | | acetate | | | | | | |
| Example | HF | 0.5 | Peracetic | 8 | Ethyl | 30 | Benzenehexacarboxylic acid | 1 | B | A | B |
| 152 | | | acid | | acetate | | (mellitic acid) | | | | |
| Example | HF | 0.5 | Peracetic | 8 | Ethyl | 30 | Oxalic acid | 1 | B | A | B |
| 153 | | | acid | | acetate | | | | | | |
| Example | HF | 0.5 | Peracetic | 8 | Ethyl | 30 | Malonic acid | 1 | B | A | B |
| 154 | | | acid | | acetate | | | | | | |
| Example | HF | 0.5 | Peracetic | 8 | Ethyl | 30 | Succinc acid | 1 | B | A | B |
| 155 | | | acid | | acetate | | | | | | |
| Example | HF | 0.5 | Peracetic | 8 | Ethyl | 30 | Glutaric acid | 1 | B | A | B |
| 156 | | | acid | | acetate | | | | | | |
| Example | HF | 0.5 | Peracetic | 8 | Ethyl | 30 | Adipic acid | 1 | B | A | B |
| 157 | | | acid | | acetate | | | | | | |
| Example | HF | 0.5 | Peracetic | 8 | Ethyl | 30 | Pimelic acid | 1 | B | A | B |
| 158 | | | acid | | acetate | | | | | | |
| Example | HF | 0.5 | Peracetic | 8 | Ethyl | 30 | Suberic acid | 1 | B | A | B |
| 159 | | | acid | | acetate | | | | | | |
| Example | HF | 0.5 | Peracetic | 8 | Ethyl | 30 | Azelaic acid | 1 | B | A | B |
| 160 | | | acid | | acetate | | | | | | |
| Example | HF | 0.5 | Peracetic | 8 | Ethyl | 30 | Sebacic acid | 1 | B | A | B |
| 161 | | | acid | | acetate | | | | | | |
| Example | HF | 0.5 | Peracetic | 8 | Ethyl | 30 | Ethylenediaminetetraacetic acid | 1 | B | A | B |
| 162 | | | acid | | acetate | | (EDTA) | | | | |
| Example | HF | 0.5 | Peracetic | 8 | Ethyl | 30 | Butylenediaminetetraacetic acid | 1 | B | A | B |
| 163 | | | acid | | acetate | | | | | | |
| Example | HF | 0.5 | Peracetic | 8 | Ethyl | 30 | (1,2-Cyclohexylenediamine)tetra- | 1 | B | A | B |
| 164 | | | acid | | acetate | | acetic acid (CyDTA) | | | | |
| Example | HF | 0.5 | Peracetic | 8 | Ethyl | 30 | Diethylenetriaminepentaacetic acid | 1 | B | A | B |
| 165 | | | acid | | acetate | | (DETPA) | | | | |
| Example | HF | 0.5 | Peracetic | 8 | Ethyl | 30 | Ethylenediaminetetrapropionic acid | 1 | B | A | B |
| 166 | | | acid | | acetate | | | | | | |
| Example | HF | 0.5 | Peracetic | 8 | Ethyl | 30 | (Hydroxyethyl)ethylenediaminetri- | 1 | B | A | B |
| 167 | | | acid | | acetate | | acetic acid (HEDTA) | | | | |
| Example | HF | 0.5 | Peracetic | 8 | Ethyl | 30 | Triethylenetetraminehexacetic acid | 1 | B | A | B |
| 168 | | | acid | | acetate | | (TTHA) | | | | |
| Example | HF | 0.5 | Peracetic | 8 | Ethyl | 30 | l,3-Diamino-2-hydroxypropane- | 1 | B | A | B |
| 169 | | | acid | | acetate | | N,N,N′,N′-tetraacetic acid (DHPTA) | | | | |
| Example | HF | 0.5 | Peracetic | 8 | Ethyl | 30 | Methyliminodiacetic acid | 1 | B | A | B |
| 170 | | | acid | | acetate | | | | | | |
| Example | HF | 0.5 | Peracetic | 8 | Ethyl | 30 | Propylenediaminetetraacetic acid | 1 | B | A | B |
| 171 | | | acid | | acetate | | | | | | |
| Example | HF | 0.5 | Peracetic | 8 | Ethyl | 30 | Nitrotriacetic acid (NTA) | 1 | B | A | B |
| 172 | | | acid | | acetate | | | | | | |
| Example | HF | 0.5 | Peracetic | 8 | Ethyl | 30 | Tartaric acid | 1 | B | A | B |
| 173 | | | acid | | acetate | | | | | | |
| Example | HF | 0.5 | Peracetic | 8 | Ethyl | 30 | Gluconic acid | 1 | B | A | B |
| 174 | | | acid | | acetate | | | | | | |
| Example | HF | 0.5 | Peracetic | 8 | Ethyl | 30 | Glyceric acid | 1 | B | A | B |
| 175 | | | acid | | acetate | | | | | | |
| Example | HF | 0.5 | Peracetic | 8 | Ethyl | 30 | Phthalic acid | 1 | B | A | B |
| 176 | | | acid | | acetate | | | | | | |
| Example | HF | 0.5 | Peracetic | 8 | Ethyl | 30 | Maleic acid | 1 | B | A | B |
| 177 | | | acid | | acetate | | | | | | |
| Example | HF | 0.5 | Peracetic | 8 | Ethyl | 30 | Mandelic acid | 1 | B | A | B |
| 178 | | | acid | | acetate | | | | | | |
| Example | HF | 0.5 | Peracetic | 8 | Ethyl | 30 | Lactic acid | 1 | B | A | B |
| 179 | | | acid | | acetate | | | | | | |
| Example | HF | 0.5 | Peracetic | 8 | Ethyl | 30 | Salicylic acid | 1 | B | A | B |
| 180 | | | acid | | acetate | | | | | | |

TABLE 7

| | Fluoride ion | | | | | | | | | | |
|---|---|---|---|---|---|---|---|---|---|---|---|
| | source | | Oxidant | | Acetate solvent | | Additive | | | | SiGe |
| | | Amount | | Amount | | Amount | | Amount | SiGe | Si | Surface |
| Table 1-7 | Type | (%) | Type | (%) | Type | (%) | Type | (%) | ER | ER | roughness |
| Example | HF | 0.5 | Peracetic | 8 | Ethyl | 30 | Gallic acid | 1 | B | A | B |
| 181 | | | acid | | acetate | | | | | | |
| Example | HF | 0.5 | Peracetic | 8 | Ethyl | 30 | Alanine | 1 | C | A | C |
| 182 | | | acid | | acetate | | | | | | |
| Example | HF | 0.5 | Peracetic | 8 | Ethyl | 30 | Arginine | 1 | C | A | C |
| 183 | | | acid | | acetate | | | | | | |
| Example | HF | 0.5 | Peracetic | 8 | Ethyl | 30 | Asparagine | 1 | C | A | C |
| 184 | | | acid | | acetate | | | | | | |
| Example | HF | 0.5 | Peracetic | 8 | Ethyl | 30 | Aspartic acid | 1 | C | A | C |
| 185 | | | acid | | acetate | | | | | | |
| Example | HF | 0.5 | Peracetic | 8 | Ethyl | 30 | Cysteine | 1 | B | A | B |
| 186 | | | acid | | acetate | | | | | | |
| Example | HF | 0.5 | Peracetic | 8 | Ethyl | 30 | Glutamine | 1 | C | A | C |
| 187 | | | acid | | acetate | | | | | | |
| Example | HF | 0.5 | Peracetic | 8 | Ethyl | 30 | Glutamic acid | 1 | C | A | C |
| 188 | | | acid | | acetate | | | | | | |
| Example | HF | 0.5 | Peracetic | 8 | Ethyl | 30 | Glycine | 1 | C | A | C |
| 189 | | | acid | | acetate | | | | | | |
| Example | HF | 0.5 | Peracetic | 8 | Ethyl | 30 | Histidine | 1 | C | A | C |
| 190 | | | acid | | acetate | | | | | | |
| Example | HF | 0.5 | Peracetic | 8 | Ethyl | 30 | Isoleucine | 1 | C | A | C |
| 191 | | | acid | | acetate | | | | | | |
| Example | HF | 0.5 | Peracetic | 8 | Ethyl | 30 | Leucine | 1 | C | A | C |
| 192 | | | acid | | acetate | | | | | | |
| Example | HF | 0.5 | Peracetic | 8 | Ethyl | 30 | Lysine | 1 | C | A | C |
| 193 | | | acid | | acetate | | | | | | |
| Example | HF | 0.5 | Peracetic | 8 | Ethyl | 30 | Methionine | 1 | C | A | C |
| 194 | | | acid | | acetate | | | | | | |
| Example | HF | 0.5 | Peracetic | 8 | Ethyl | 30 | Phenylalanine | 1 | C | A | C |
| 195 | | | acid | | acetate | | | | | | |
| Example | HF | 0.5 | Peracetic | 8 | Ethyl | 30 | Proline | 1 | C | A | C |
| 196 | | | acid | | acetate | | | | | | |
| Example | HF | 0.5 | Peracetic | 8 | Ethyl | 30 | Serine | 1 | C | A | C |
| 197 | | | acid | | acetate | | | | | | |
| Example | HF | 0.5 | Peracetic | 8 | Ethyl | 30 | Threonine | 1 | C | A | C |
| 198 | | | acid | | acetate | | | | | | |
| Example | HF | 0.5 | Peracetic | 8 | Ethyl | 30 | Tryptophan | 1 | c | A | C |
| 199 | | | acid | | acetate | | | | | | |
| Example | HF | 0.5 | Peracetic | 8 | Ethyl | 30 | Tyrosine | 1 | c | A | C |
| 200 | | | acid | | acetate | | | | | | |
| Example | HF | 0.5 | Peracetic | 8 | Ethyl | 30 | Valine | 1 | c | A | C |
| 201 | | | acid | | acetate | | | | | | |
| Example | HF | 0.5 | Peracetic | 8 | Ethyl | 30 | Tetramethylammonium | 1 | B | A | B |
| 202 | | | acid | | acetate | | hydroxide | | | | |
| Example | HF | 0.5 | Peracetic | 8 | Ethyl | 30 | Tetrapropylammonium | 1 | B | A | B |
| 203 | | | acid | | acetate | | hydroxide | | | | |
| Example | HF | 0.5 | Peracetic | 8 | Ethyl | 30 | Tetrabutylammonium | 1 | B | A | B |
| 204 | | | acid | | acetate | | hydroxide | | | | |
| Example | HF | 0.5 | Peracetic | 8 | Ethyl | 30 | Methyltripropylammonium | 1 | B | A | B |
| 205 | | | acid | | acetate | | hydroxide | | | | |
| Example | HF | 0.5 | Peracetic | 8 | Ethyl | 30 | Methyltributylammonium | 1 | B | A | B |
| 206 | | | acid | | acetate | | hydroxide | | | | |
| Example | HF | 0.5 | Peracetic | 8 | Ethyl | 30 | Ethyltrimethylammonium | 1 | B | A | B |
| 207 | | | acid | | acetate | | hydroxide | | | | |
| Example | HF | 0.5 | Peracetic | 8 | Ethyl | 30 | Dimethyldiethylammonium | 1 | B | A | B |
| 208 | | | acid | | acetate | | hydroxide | | | | |
| Example | HF | 0.5 | Peracetic | 8 | Ethyl | 30 | Benzyltrimethylammonium | 1 | B | A | B |
| 209 | | | acid | | acetate | | hydroxide | | | | |
| Example | HF | 0.5 | Peracetic | 8 | Ethyl | 30 | (2-Hydroxyethyl)trimethyl- | 1 | B | A | B |
| 210 | | | acid | | acetate | | ammonium hydroxide | | | | |

TABLE 8

| | Fluoride ion | | | | | | | | | | |
|---|---|---|---|---|---|---|---|---|---|---|---|
| | source | | Oxidant | | Acetate solvent | | Additive | | | | SiGe |
| | | Amount | | Amount | | Amount | | Amount | SiGe | Si | Surface |
| Table 1-8 | Type | (%) | Type | (%) | Type | (%) | Type | (%) | ER | ER | roughness |
| Example | HF | 0.5 | Peracetic | 8 | Ethyl | 30 | Boric acid | 1 | B | A | B |
| 211 | | | acid | | acetate | | | | | | |
| Example | HF | 0.5 | Peracetic | 8 | n-Propyl | 30 | Polyethylene glycol | 0.5 | A | B | B |
| 212 | | | acid | | acetate | | | | | | |
| Example | HF | 0.5 | Peracetic | 8 | n-Propyl | 30 | Polyethyleneimine | 0.5 | A | B | B |
| 213 | | | acid | | acetate | | | | | | |
| Example | HF | 0.5 | Peracetic | 8 | n-Propyl | 30 | Dodecylbenzenesulfonic | 0.5 | A | B | B |
| 214 | | | acid | | acetate | | acid | | | | |
| Example | HF | 0.5 | Peracetic | 8 | n-Propyl | 30 | Dodecyl diphenyl ether | 0.5 | A | B | B |
| 215 | | | acid | | acetate | | disulfonic acid | | | | |
| Example | HF | 0.5 | Peracetic | 8 | n-Propyl | 30 | Phenolsulfonic acid | 0.5 | A | B | B |
| 216 | | | acid | | acetate | | formaldehyde condensate | | | | |
| Example | HF | 0.5 | Peracetic | 8 | Isopropyl | 30 | Polyethylene glycol | 0.5 | A | B | B |
| 217 | | | acid | | acetate | | | | | | |
| Example | HF | 0.5 | Peracetic | 8 | Isopropyl | 30 | Polyethyleneimine | 0.5 | A | B | B |
| 218 | | | acid | | acetate | | | | | | |
| Example | HF | 0.5 | Peracetic | 8 | Isopropyl | 30 | Dodecylbenzenesulfonic | 0.5 | A | B | B |
| 219 | | | acid | | acetate | | acid | | | | |
| Example | HF | 0.5 | Peracetic | 8 | Isopropyl | 30 | Dodecyl diphenyl ether | 0.5 | A | B | B |
| 220 | | | acid | | acetate | | disulfonic acid | | | | |
| Example | HF | 0.5 | Peracetic | 8 | Isopropyl | 30 | Phenolsulfonic acid | 0.5 | A | B | B |
| 221 | | | acid | | acetate | | formaldehyde condensate | | | | |
| Example | HF | 0.5 | Peracetic | 8 | t-Butyl | 30 | Polyethylene glycol | 0.5 | A | B | B |
| 222 | | | acid | | acetate | | | | | | |
| Example | HF | 0.5 | Peracetic | 8 | t-Butyl | 30 | Polyethyleneimine | 0.5 | A | B | B |
| 223 | | | acid | | acetate | | | | | | |
| Example | HF | 0.5 | Peracetic | 8 | t-Butyl | 30 | Dodecylbenzenesulfonic | 0.5 | A | B | B |
| 224 | | | acid | | acetate | | acid | | | | |
| Example | HF | 0.5 | Peracetic | 8 | t-Butyl | 30 | Dodecyl diphenyl ether | 0.5 | A | B | B |
| 225 | | | acid | | acetate | | disulfonic acid | | | | |
| Example | HF | 0.5 | Peracetic | 8 | t-Butyl | 30 | Phenolsulfonic acid | 0.5 | A | B | B |
| 226 | | | acid | | acetate | | formaldehyde condensate | | | | |
| Example | HF | 0.5 | Peracetic | 8 | n-Butyl | 30 | Polyethylene glycol | 0.5 | A | A | A |
| 227 | | | acid | | acetate | | | | | | |
| Example | HF | 0.5 | Peracetic | 8 | n-Butyl | 30 | Polypropylene glycol | 0.5 | B | A | B |
| 228 | | | acid | | acetate | | | | | | |
| Example | HF | 0.5 | Peracetic | 8 | n-Butyl | 30 | Polyvinyl alcohol | 0.5 | B | A | B |
| 229 | | | acid | | acetate | | | | | | |
| Example | HF | 0.5 | Peracetic | 8 | n-Butyl | 30 | Polyacrylic acid | 0.5 | B | A | B |
| 230 | | | acid | | acetate | | | | | | |
| Example | HF | 0.5 | Peracetic | 8 | n-Butyl | 30 | Polystyrene sulfonic acid | 0.5 | B | A | B |
| 231 | | | acid | | acetate | | | | | | |
| Example | HF | 0.5 | Peracetic | 8 | n-Butyl | 30 | Polyvinylpyrrolidone | 0.5 | B | A | B |
| 232 | | | acid | | acetate | | | | | | |
| Example | HF | 0.5 | Peracetic | 8 | n-Butyl | 30 | Polyethyleneimine | 0.5 | A | A | A |
| 233 | | | acid | | acetate | | | | | | |
| Example | HF | 0.5 | Peracetic | 8 | n-Butyl | 30 | Polyallylamine | 0.5 | B | A | B |
| 234 | | | acid | | acetate | | | | | | |
| Example | HF | 0.5 | Peracetic | 8 | n-Butyl | 30 | Polyvinylamine | 0.5 | B | A | B |
| 235 | | | acid | | acetate | | | | | | |
| Example | HF | 0.5 | Peracetic | 8 | n-Butyl | 30 | Polyacrylamide | 0.5 | B | A | B |
| 236 | | | acid | | acetate | | | | | | |
| Example | HF | 0.5 | Peracetic | 8 | n-Butyl | 30 | Dimethylamine- | 0.5 | B | A | B |
| 237 | | | acid | | acetate | | epihalohydrin copolymer | | | | |
| Example | HF | 0.5 | Peracetic | 8 | n-Butyl | 30 | Hexadimethrine chloride | 0.5 | B | A | B |
| 238 | | | acid | | acetate | | | | | | |
| Example | HF | 0.5 | Peracetic | 8 | n-Butyl | 30 | Polydiallylamine | 0.5 | B | A | B |
| 239 | | | acid | | acetate | | | | | | |
| Example | HF | 0.5 | Peracetic | 8 | n-Butyl | 30 | Polydimethyldiallyl- | 0.5 | B | A | B |
| 240 | | | acid | | acetate | | ammonium chloride | | | | |

TABLE 9

| | Fluoride ion | | | | | | | | | | |
|---|---|---|---|---|---|---|---|---|---|---|---|
| | source | | Oxidant | | Acetate solvent | | Additive | | | | SiGe |
| | | Amount | | Amount | | Amount | | Amount | SiGe | Si | Surface |
| Table 1-9 | Type | (%) | Type | (%) | Type | (%) | Type | (%) | ER | ER | roughness |
| Example | HF | 0.5 | Peracetic | 8 | n-Butyl | 30 | Poly(4-vinylpyridine) | 0.5 | B | A | B |
| 241 | | | acid | | acetate | | | | | | |
| Example | HF | 0.5 | Peracetic | 8 | n-Butyl | 30 | Polyornithine | 0.5 | B | A | B |
| 242 | | | acid | | acetate | | | | | | |
| Example | HF | 0.5 | Peracetic | 8 | n-Butyl | 30 | Polylysine | 0.5 | B | A | B |
| 243 | | | acid | | acetate | | | | | | |
| Example | HF | 0.5 | Peracetic | 8 | n-Butyl | 30 | Polyarginine | 0.5 | B | A | B |
| 244 | | | acid | | acetate | | | | | | |
| Example | HF | 0.5 | Peracetic | 8 | n-Butyl | 30 | Polyhistidine | 0.5 | B | A | B |
| 245 | | | acid | | acetate | | | | | | |
| Example | HF | 0.5 | Peracetic | 8 | n-Butyl | 30 | Polyvinylimidazole | 0.5 | B | A | B |
| 246 | | | acid | | acetate | | | | | | |
| Example | HF | 0.5 | Peracetic | 8 | n-Butyl | 30 | Polymethyldiallylamine | 0.5 | B | A | B |
| 247 | | | acid | | acetate | | | | | | |
| Example | HF | 0.5 | Peracetic | 8 | n-Butyl | 30 | Dodecylbenzenesulfonic | 0.5 | A | A | A |
| 248 | | | acid | | acetate | | acid | | | | |
| Example | HF | 0.5 | Peracetic | 8 | n-Butyl | 30 | Propyl naphthalenesulfonic | 0.5 | B | A | B |
| 249 | | | acid | | acetate | | acid | | | | |
| Example | HF | 0.5 | Peracetic | 8 | n-Butyl | 30 | Triisopropyl | 0.5 | B | A | B |
| 250 | | | acid | | acetate | | naphthalenesulfonic acid | | | | |
| Example | HF | 0.5 | Peracetic | 8 | n-Butyl | 30 | Dibutyl naphthalenesulfonic | 0.5 | B | A | B |
| 251 | | | acid | | acetate | | acid | | | | |
| Example | HF | 0.5 | Peracetic | 8 | n-Butyl | 30 | Dodecyl diphenyl ether | 0.5 | A | A | A |
| 252 | | | acid | | acetate | | disulfonic acid | | | | |
| Example | HF | 0.5 | Peracetic | 8 | n-Butyl | 30 | Phenolsulfonic acid | 0.5 | A | A | A |
| 253 | | | acid | | acetate | | formaldehyde condensate | | | | |
| Example | HF | 0.5 | Peracetic | 8 | n-Butyl | 30 | Phenyl phenolsulfonic acid | 0.5 | B | A | B |
| 254 | | | acid | | acetate | | formaldehyde condensate | | | | |
| Example | HF | 0.5 | Peracetic | 8 | n-Butyl | 30 | Polyoxyethylene lauryl | 0.5 | B | A | B |
| 255 | | | acid | | acetate | | ether sulfonic acid | | | | |
| Example | HF | 0.5 | Peracetic | 8 | n-Butyl | 30 | Polyoxyethylene oleyl | 0.5 | B | A | B |
| 256 | | | acid | | acetate | | ether sulfonic acid | | | | |
| Example | HF | 0.5 | Peracetic | 8 | n-Butyl | 30 | Polyoxyethylene octyldodecyl | 0.5 | B | A | B |
| 257 | | | acid | | acetate | | ether sulfonic acid | | | | |
| Example | HF | 0.5 | Peracetic | 8 | n-Butyl | 30 | Dodecanoic acid | 0.5 | B | A | B |
| 258 | | | acid | | acetate | | | | | | |
| Example | HF | 0.5 | Peracetic | 8 | n-Butyl | 30 | Hexadecanoic acid | 0.5 | B | A | B |
| 259 | | | acid | | acetate | | | | | | |
| Example | HF | 0.5 | Peracetic | 8 | n-Butyl | 30 | Oleic acid | 0.5 | B | A | B |
| 260 | | | acid | | acetate | | | | | | |
| Example | HF | 0.5 | Peracetic | 8 | n-Butyl | 30 | Juniperic acid | 0.5 | B | A | B |
| 261 | | | acid | | acetate | | | | | | |
| Example | HF | 0.5 | Peracetic | 8 | n-Butyl | 30 | Stearic acid | 0.5 | B | A | B |
| 262 | | | acid | | acetate | | | | | | |
| Example | HF | 0.5 | Peracetic | 8 | n-Butyl | 30 | 12-Hydroxystearic acid | 0.5 | B | A | B |
| 263 | | | acid | | acetate | | | | | | |
| Example | HF | 0.5 | Peracetic | 8 | n-Butyl | 30 | Perfluorooctanoic acid | 0.5 | B | A | B |
| 264 | | | acid | | acetate | | | | | | |
| Example | HF | 0.5 | Peracetic | 8 | n-Butyl | 30 | Perfluoroheptanoic acid | 0.5 | B | A | B |
| 265 | | | acid | | acetate | | | | | | |
| Example | HF | 0.5 | Peracetic | 8 | n-Butyl | 30 | Perfluorodecanoic acid | 0.5 | B | A | B |
| 266 | | | acid | | acetate | | | | | | |
| Example | HF | 0.5 | Peracetic | 8 | n-Butyl | 30 | Polyoxyethylene lauryl | 0.5 | B | A | B |
| 267 | | | acid | | acetate | | ether carboxylic acid | | | | |
| Example | HF | 0.5 | Peracetic | 8 | n-Butyl | 30 | Polyoxyethylene dodecyl | 0.5 | B | A | B |
| 268 | | | acid | | acetate | | ether carboxylic acid | | | | |
| Example | HF | 0.5 | Peracetic | 8 | n-Butyl | 30 | Polyoxyethylene tridecyl | 0.5 | B | A | B |
| 269 | | | acid | | acetate | | ether carboxylic acid | | | | |
| Example | HF | 0.5 | Peracetic | 8 | n-Butyl | 30 | Bis(2-ethylhexyl)phosphate | 0.5 | B | A | B |
| 270 | | | acid | | acetate | | | | | | |

TABLE 10

| | Fluoride ion | | | | | | | | | | |
|---|---|---|---|---|---|---|---|---|---|---|---|
| | source | | Oxidant | | Acetate solvent | | Additive | | | | SiGe |
| | | Amount | | Amount | | Amount | | Amount | SiGe | Si | Surface |
| Table 1-10 | Type | (%) | Type | (%) | Type | (%) | Type | (%) | ER | ER | roughness |
| Example | HF | 0.5 | Peracetic | 8 | n-Butyl | 30 | Dioctadecylphosphate | 0.5 | B | A | B |
| 271 | | | acid | | acetate | | | | | | |
| Example | HF | 0.5 | Peracetic | 8 | n-Butyl | 30 | Octadecylphosphate | 0.5 | B | A | B |
| 272 | | | acid | | acetate | | | | | | |
| Example | HF | 0.5 | Peracetic | 8 | n-Butyl | 30 | Dodecylphosphate | 0.5 | B | A | B |
| 273 | | | acid | | acetate | | | | | | |
| Example | HF | 0.5 | Peracetic | 8 | n-Butyl | 30 | Decyl phosphonic acid | 0.5 | B | A | B |
| 274 | | | acid | | acetate | | | | | | |
| Example | HF | 0.5 | Peracetic | 8 | n-Butyl | 30 | Dodecyl phosphonic acid | 0.5 | B | A | B |
| 275 | | | acid | | acetate | | | | | | |
| Example | HF | 0.5 | Peracetic | 8 | n-Butyl | 30 | Tetradecyl phosphonic acid | 0.5 | B | A | B |
| 276 | | | acid | | acetate | | | | | | |
| Example | HF | 0.5 | Peracetic | 8 | n-Butyl | 30 | Hexadecyl phosphonic acid | 0.5 | B | A | B |
| 277 | | | acid | | acetate | | | | | | |
| Example | HF | 0.5 | Peracetic | 8 | n-Butyl | 30 | Octadecyl phosphonic acid | 0.5 | B | A | B |
| 278 | | | acid | | acetate | | | | | | |
| Example | HF | 0.5 | Peracetic | 8 | n-Butyl | 30 | Polyoxyethylene alkyl phenyl | 0.5 | B | A | B |
| 279 | | | acid | | acetate | | ether phosphoric acid | | | | |
| Example | HF | 0.5 | Peracetic | 8 | n-Butyl | 30 | Polyoxyethylene lauryl ether | 0.5 | B | A | B |
| 280 | | | acid | | acetate | | phosphoric acid | | | | |
| Example | HF | 0.5 | Peracetic | 8 | n-Butyl | 30 | Cetyltrimethylammonium | 0.5 | B | A | B |
| 281 | | | acid | | acetate | | chloride | | | | |
| Example | HF | 0.5 | Peracetic | 8 | n-Butyl | 30 | Cetyltrimethylammonium | 0.5 | B | A | B |
| 282 | | | acid | | acetate | | bromide | | | | |
| Example | HF | 0.5 | Peracetic | 8 | n-Butyl | 30 | Stearyltrimethylammonium | 0.5 | B | A | B |
| 283 | | | acid | | acetate | | chloride | | | | |
| Example | HF | 0.5 | Peracetic | 8 | n-Butyl | 30 | Stearyltrimethylammonium | 0.5 | B | A | B |
| 284 | | | acid | | acetate | | bromide | | | | |
| Example | HF | 0.5 | Peracetic | 8 | n-Butyl | 30 | Laurylpyridinium chloride | 0.5 | B | A | B |
| 285 | | | acid | | acetate | | | | | | |
| Example | HF | 0.5 | Peracetic | 8 | n-Butyl | 30 | Laurylpyridinium bromide | 0.5 | B | A | B |
| 286 | | | acid | | acetate | | | | | | |
| Example | HF | 0.5 | Peracetic | 8 | n-Butyl | 30 | Cetylpyridinium chloride | 0.5 | B | A | B |
| 287 | | | acid | | acetate | | | | | | |
| Example | HF | 0.5 | Peracetic | 8 | n-Butyl | 30 | Cetylpyridinium bromide | 0.5 | B | A | B |
| 288 | | | acid | | acetate | | | | | | |
| Example | HF | 0.5 | Peracetic | 8 | n-Butyl | 30 | 4-(4-Diethylaminophenylazo)-1- | 0.5 | B | A | B |
| 289 | | | acid | | acetate | | (4-nitrobenzyl)pyridinium chloride | | | | |
| Example | HF | 0.5 | Peracetic | 8 | n-Butyl | 30 | 4-(4-Diethylaminophenylazo)-1- | 0.5 | B | A | B |
| 290 | | | acid | | acetate | | (4-nitrobenzyl)pyridinium bromide | | | | |
| Example | HF | 0.5 | Peracetic | 8 | n-Butyl | 30 | Benzalkonium chloride | 0.5 | B | A | B |
| 291 | | | acid | | acetate | | | | | | |
| Example | HF | 0.5 | Peracetic | 8 | n-Butyl | 30 | Benzalkonium bromide | 0.5 | B | A | B |
| 292 | | | acid | | acetate | | | | | | |
| Example | HF | 0.5 | Peracetic | 8 | n-Butyl | 30 | Benzethonium chloride | 0.5 | B | A | B |
| 293 | | | acid | | acetate | | | | | | |
| Example | HF | 0.5 | Peracetic | 8 | n-Butyl | 30 | Benzethonium bromide | 0.5 | B | A | B |
| 294 | | | acid | | acetate | | | | | | |
| Example | HF | 0.5 | Peracetic | 8 | n-Butyl | 30 | Benzyldimethyldodecyl- | 0.5 | B | A | B |
| 295 | | | acid | | acetate | | ammonium chloride | | | | |
| Example | HF | 0.5 | Peracetic | 8 | n-Butyl | 30 | Benzyldimethyldodecyl- | 0.5 | B | A | B |
| 296 | | | acid | | acetate | | ammonium bromide | | | | |
| Example | HF | 0.5 | Peracetic | 8 | n-Butyl | 30 | Benzyldimethylhexadecyl- | 0.5 | B | A | B |
| 297 | | | acid | | acetate | | ammonium chloride | | | | |
| Example | HF | 0.5 | Peracetic | 8 | n-Butyl | 30 | Benzyldimethylhexadecyl- | 0.5 | B | A | B |
| 298 | | | acid | | acetate | | ammonium bromide | | | | |
| Example | HF | 0.5 | Peracetic | 8 | n-Butyl | 30 | Cetyltrimethylammonium | 0.5 | B | A | B |
| 299 | | | acid | | acetate | | chloride | | | | |
| Example | HF | 0.5 | Peracetic | 8 | n-Butyl | 30 | Cetyltrimethylammonium | 0.5 | B | A | B |
| 300 | | | acid | | acetate | | bromide | | | | |

TABLE 11

| | Fluoride ion | | | | | | | | | | |
|---|---|---|---|---|---|---|---|---|---|---|---|
| | source | | Oxidant | | Acetate solvent | | Additive | | | | SiGe |
| | | Amount | | Amount | | Amount | | Amount | SiGe | Si | Surface |
| Table 1-11 | Type | (%) | Type | (%) | Type | (%) | Type | (%) | ER | ER | roughness |
| Example | HF | 0.5 | Peracetic | 8 | n-Butyl | 30 | Dimethyldioctadecyl- | 0.5 | B | A | B |
| 301 | | | acid | | acetate | | ammonium chloride | | | | |
| Example | HF | 0.5 | Peracetic | 8 | n-Butyl | 30 | Dimethyldioctadecyl- | 0.5 | B | A | B |
| 302 | | | acid | | acetate | | ammonium bromide | | | | |
| Example | HF | 0.5 | Peracetic | 8 | n-Butyl | 30 | Dodecyltrimethyl- | 0.5 | B | A | B |
| 303 | | | acid | | acetate | | ammonium chloride | | | | |
| Example | HF | 0.5 | Peracetic | 8 | n-Butyl | 30 | Dodecyltrimethyl- | 0.5 | B | A | B |
| 304 | | | acid | | acetate | | ammonium bromide | | | | |
| Example | HF | 0.5 | Peracetic | 8 | n-Butyl | 30 | Didodecyldimethyl- | 0.5 | B | A | B |
| 305 | | | acid | | acetate | | ammonium chloride | | | | |
| Example | HF | 0.5 | Peracetic | 8 | n-Butyl | 30 | Didodecyldimethyl- | 0.5 | B | A | B |
| 306 | | | acid | | acetate | | ammonium bromide | | | | |
| Example | HF | 0.5 | Peracetic | 8 | n-Butyl | 30 | Tetraheptylammonium | 0.5 | B | A | B |
| 307 | | | acid | | acetate | | chloride | | | | |
| Example | HF | 0.5 | Peracetic | 8 | n-Butyl | 30 | Tetraheptylammonium | 0.5 | B | A | B |
| 308 | | | acid | | acetate | | bromide | | | | |
| Example | HF | 0.5 | Peracetic | 8 | n-Butyl | 30 | tetrakis(decyl)ammonium | 0.5 | B | A | B |
| 309 | | | acid | | acetate | | chloride | | | | |
| Example | HF | 0.5 | Peracetic | 8 | n-Butyl | 30 | retrakis(decyl)ammonium | 0.5 | B | A | B |
| 310 | | | acid | | acetate | | bromide | | | | |
| Example | HF | 0.5 | Peracetic | 8 | n-Butyl | 30 | Dimethyldihexadecyl- | 0.5 | B | A | B |
| 311 | | | acid | | acetate | | ammonium chloride | | | | |
| Example | HF | 0.5 | Peracetic | 8 | n-Butyl | 30 | Dimethyldihexadecyl- | 0.5 | B | A | B |
| 312 | | | acid | | acetate | | ammonium bromide | | | | |
| Example | HF | 0.5 | Peracetic | 8 | n-Butyl | 30 | Polyoxyethylene lauryl | 0.5 | B | A | B |
| 313 | | | acid | | acetate | | amine | | | | |
| Example | HF | 0.5 | Peracetic | 8 | n-Butyl | 30 | Stearylamine | 0.5 | B | A | B |
| 314 | | | acid | | acetate | | | | | | |
| Example | HF | 0.5 | Peracetic | 8 | n-Butyl | 30 | Cocamidopropyl betaine | 0.5 | C | A | C |
| 315 | | | acid | | acetate | | | | | | |
| Example | HF | 0.5 | Peracetic | 8 | n-Butyl | 30 | N,N-Dimethyldodecyl- | 0.5 | C | A | C |
| 316 | | | acid | | acetate | | amine N-oxide | | | | |
| Example | HF | 0.5 | Peracetic | 8 | n-Butyl | 30 | Lauryl dimethylamino- | 0.5 | C | A | C |
| 317 | | | acid | | acetate | | acetic acid betaine | | | | |
| Example | HF | 0.5 | Peracetic | 8 | n-Butyl | 30 | Lauryldimethylamine | 0.5 | C | A | C |
| 318 | | | acid | | acetate | | oxide | | | | |
| Example | HF | 0.5 | Peracetic | 8 | n-Butyl | 30 | Ethylenediamine | 1 | B | A | B |
| 319 | | | acid | | acetate | | | | | | |
| Example | HF | 0.5 | Peracetic | 8 | n-Butyl | 30 | Diethylenetriamine | 1 | B | A | B |
| 320 | | | acid | | acetate | | | | | | |
| Example | HF | 0.5 | Peracetic | 8 | n-Butyl | 30 | Triethylenetetramine | 1 | B | A | B |
| 321 | | | acid | | acetate | | | | | | |
| Example | HF | 0.5 | Peracetic | 8 | n-Butyl | 30 | Tetraethylenepentamine | 1 | B | A | B |
| 322 | | | acid | | acetate | | | | | | |
| Example | HF | 0.5 | Peracetic | 8 | n-Butyl | 30 | Pentaethylenehexamine | 1 | B | A | B |
| 323 | | | acid | | acetate | | | | | | |
| Example | HF | 0.5 | Peracetic | 8 | n-Butyl | 30 | retramethylethylenedi- | 1 | B | A | B |
| 324 | | | acid | | acetate | | amine | | | | |
| Example | HF | 0.5 | Peracetic | 8 | n-Butyl | 30 | Hexamethylenediamine | 1 | B | A | B |
| 325 | | | acid | | acetate | | | | | | |
| Example | HF | 0.5 | Peracetic | 8 | n-Butyl | 30 | Methylamine | 1 | B | A | B |
| 326 | | | acid | | acetate | | | | | | |
| Example | HF | 0.5 | Peracetic | 8 | n-Butyl | 30 | Dimethylamine | 1 | B | A | B |
| 327 | | | acid | | acetate | | | | | | |
| Example | HF | 0.5 | Peracetic | 8 | n-Butyl | 30 | Trimethylamine | 1 | B | A | B |
| 328 | | | acid | | acetate | | | | | | |
| Example | HF | 0.5 | Peracetic | 8 | n-Butyl | 30 | Ethylamine | 1 | B | A | B |
| 329 | | | acid | | acetate | | | | | | |
| Example | HF | 0.5 | Peracetic | 8 | n-Butyl | 30 | Diethylamine | 1 | B | A | B |
| 330 | | | acid | | acetate | | | | | | |

TABLE 12

| | Fluoride ion | | | | | | | | | | |
|---|---|---|---|---|---|---|---|---|---|---|---|
| | source | | Oxidant | | Acetate solvent | | Additive | | | | SiGe |
| | | Amount | | Amount | | Amount | | Amount | SiGe | Si | Surface |
| Table 1-12 | Type | (%) | Type | (%) | Type | (%) | Type | (%) | ER | ER | roughness |
| Example | HF | 0.5 | Peracetic | 8 | n-Butyl | 30 | Triethylamine | 1 | B | A | B |
| 331 | | | acid | | acetate | | | | | | |
| Example | HF | 0.5 | Peracetic | 8 | n-Butyl | 30 | 2-Ethylhexylamine | 1 | B | A | B |
| 332 | | | acid | | acetate | | | | | | |
| Example | HF | 0.5 | Peracetic | 8 | n-Butyl | 30 | Cyclohexylamine | 1 | B | A | B |
| 333 | | | acid | | acetate | | | | | | |
| Example | HF | 0.5 | Peracetic | 8 | n-Butyl | 30 | Aniline | 1 | B | A | B |
| 334 | | | acid | | acetate | | | | | | |
| Example | HF | 0.5 | Peracetic | 8 | n-Butyl | 30 | Phenethylamine | 1 | B | A | B |
| 335 | | | acid | | acetate | | | | | | |
| Example | HF | 0.5 | Peracetic | 8 | n-Butyl | 30 | Toluidine | 1 | B | A | B |
| 336 | | | acid | | acetate | | | | | | |
| Example | HF | 0.5 | Peracetic | 8 | n-Butyl | 30 | m-Xylylenediamine | 1 | B | A | B |
| 337 | | | acid | | acetate | | | | | | |
| Example | HF | 0.5 | Peracetic | 8 | n-Butyl | 30 | Diethanolamine | 1 | B | A | B |
| 338 | | | acid | | acetate | | | | | | |
| Example | HF | 0.5 | Peracetic | 8 | n-Butyl | 30 | Diisopropanolamine | 1 | B | A | B |
| 339 | | | acid | | acetate | | | | | | |
| Example | HF | 0.5 | Peracetic | 8 | n-Butyl | 30 | Triisopropanolamine | 1 | B | A | B |
| 340 | | | acid | | acetate | | | | | | |
| Example | HF | 0.5 | Peracetic | 8 | n-Butyl | 30 | 2-(2-Aminoethylamino)ethanol | 1 | B | A | B |
| 341 | | | acid | | acetate | | | | | | |
| Example | HF | 0.5 | Peracetic | 8 | n-Butyl | 30 | 2-(2-Aminoethoxy)ethanol | 1 | B | A | B |
| 342 | | | acid | | acetate | | | | | | |
| Example | HF | 0.5 | Peracetic | 8 | n-Butyl | 30 | Triethanolamine | 1 | B | A | B |
| 343 | | | acid | | acetate | | | | | | |
| Example | HF | 0.5 | Peracetic | 8 | n-Butyl | 30 | N-ethylethanolamine | 1 | B | A | B |
| 344 | | | acid | | acetate | | | | | | |
| Example | HF | 0.5 | Peracetic | 8 | n-Butyl | 30 | N,N-dimethylethanolamine | 1 | B | A | B |
| 345 | | | acid | | acetate | | | | | | |
| Example | HF | 0.5 | Peracetic | 8 | n-Butyl | 30 | N,N-diethylethanolamine | 1 | B | A | B |
| 346 | | | acid | | acetate | | | | | | |
| Example | HF | 0.5 | Peracetic | 8 | n-Butyl | 30 | N-methyldiethanolamine | 1 | B | A | B |
| 347 | | | acid | | acetate | | | | | | |
| Example | HF | 0.5 | Peracetic | 8 | n-Butyl | 30 | N-ethyldiethanolamine | 1 | B | A | B |
| 348 | | | acid | | acetate | | | | | | |
| Example | HF | 0.5 | Peracetic | 8 | n-Butyl | 30 | Cyclohexylamine diethanol | 1 | B | A | B |
| 349 | | | acid | | acetate | | | | | | |
| Example | HF | 0.5 | Peracetic | 8 | n-Butyl | 30 | N-methylethanolamine | 1 | B | A | B |
| 350 | | | acid | | acetate | | | | | | |
| Example | HF | 0.5 | Peracetic | 8 | n-Butyl | 30 | Pyrrolidine | 1 | B | A | B |
| 351 | | | acid | | acetate | | | | | | |
| Example | HF | 0.5 | Peracetic | 8 | n-Butyl | 30 | Piperidine | 1 | B | A | B |
| 352 | | | acid | | acetate | | | | | | |
| Example | HF | 0.5 | Peracetic | 8 | n-Butyl | 30 | Piperazine | 1 | B | A | B |
| 353 | | | acid | | acetate | | | | | | |
| Example | HF | 0.5 | Peracetic | 8 | n-Butyl | 30 | Morpholine | 1 | B | A | B |
| 354 | | | acid | | acetate | | | | | | |
| Example | HF | 0.5 | Peracetic | 8 | n-Butyl | 30 | Pyrrole | 1 | B | A | B |
| 355 | | | acid | | acetate | | | | | | |
| Example | HF | 0.5 | Peracetic | 8 | n-Butyl | 30 | Pyrazole | 1 | B | ' A | B |
| 356 | | | acid | | acetate | | | | | | |
| Example | HF | 0.5 | Peracetic | 8 | n-Butyl | 30 | Imidazole | 1 | B | A | B |
| 357 | | | acid | | acetate | | | | | | |
| Example | HF | 0.5 | Peracetic | 8 | n-Butyl | 30 | yridine | 1 | B | A | B |
| 358 | | | acid | | acetate | | | | | | |
| Example | HF | 0.5 | Peracetic | 8 | n-Butyl | 30 | Pyrimidine | 1 | B | A | B |
| 359 | | | acid | | acetate | | | | | | |
| Example | HF | 0.5 | Peracetic | 8 | n-Butyl | 30 | Pyrazine | 1 | B | A | B |
| 360 | | | acid | | acetate | | | | | | |

TABLE 13

| | Fluoride ion | | | | | | | | | | |
|---|---|---|---|---|---|---|---|---|---|---|---|
| | source | | Oxidant | | Acetate solvent | | Additive | | | | SiGe |
| | | Amount | | Amount | | Amount | | Amount | SiGe | Si | Surface |
| Table 1-13 | Type | (%) | Type | (%) | Type | (%) | Type | (%) | ER | ER | roughness |
| Example | HF | 0.5 | Peracetic | 8 | n-Butyl | 30 | Oxazole | 1 | B | A | B |
| 361 | | | acid | | acetate | | | | | | |
| Example | HF | 0.5 | Peracetic | 8 | n-Butyl | 30 | Thiazole | 1 | B | A | B |
| 362 | | | acid | | acetate | | | | | | |
| Example | HF | 0.5 | Peracetic | 8 | n-Butyl | 30 | 4-dimethylaminopyridine | 1 | B | A | B |
| 363 | | | acid | | acetate | | | | | | |
| Example | HF | 0.5 | Peracetic | 8 | n-Butyl | 30 | Citric acid | 1 | B | A | B |
| 364 | | | acid | | acetate | | | | | | |
| Example | HF | 0.5 | Peracetic | 8 | n-Butyl | 30 | 2-Methylpropane-1,2,3- | 1 | B | A | B |
| 365 | | | acid | | acetate | | tricarboxylic acid | | | | |
| Example | HF | 0.5 | Peracetic | 8 | n-Butyl | 30 | Benzene-1,2,3-tricarboxylic | 1 | B | A | B |
| 366 | | | acid | | acetate | | acid (hemimellitic acid) | | | | |
| Example | HF | 0.5 | Peracetic | 8 | n-Butyl | 30 | Propane-1,2,3-tricarboxylic | 1 | B | A | B |
| 367 | | | acid | | acetate | | acid (tricarballylic acid) | | | | |
| Example | HF | 0.5 | Peracetic | 8 | n-Butyl | 30 | l,cis-2,3-Propanetricarboxylic | 1 | B | A | B |
| 368 | | | acid | | acetate | | acid (aconitic acid) | | | | |
| Example | HF | 0.5 | Peracetic | 8 | n-Butyl | 30 | Butane-1,2,3,4-tetracarboxylic | 1 | B | A | B |
| 369 | | | acid | | acetate | | acid | | | | |
| Example | HF | 0.5 | Peracetic | 8 | n-Butyl | 30 | Cyclopentane tetra-1,2,3,4- | 1 | B | A | B |
| 370 | | | acid | | acetate | | carboxylic acid | | | | |
| Example | HF | 0.5 | Peracetic | 8 | n-Butyl | 30 | Benzene-1,2,4,5-tetracarboxylic | 1 | B | A | B |
| 371 | | | acid | | acetate | | acid (pyromellitic acid) | | | | |
| Example | HF | 0.5 | Peracetic | 8 | n-Butyl | 30 | Benzenepentacarboxylic acid | 1 | B | A | B |
| 372 | | | acid | | acetate | | | | | | |
| Example | HF | 0.5 | Peracetic | 8 | n-Butyl | 30 | Benzenehexacarboxylic acid | 1 | B | A | B |
| 373 | | | acid | | acetate | | (mellitic acid) | | | | |
| Example | HF | 0.5 | Peracetic | 8 | n-Butyl | 30 | Dxalic acid | 1 | B | A | B |
| 374 | | | acid | | acetate | | | | | | |
| Example | HF | 0.5 | Peracetic | 8 | n-Butyl | 30 | Malonic acid | 1 | B | A | B |
| 375 | | | acid | | acetate | | | | | | |
| Example | HF | 0.5 | Peracetic | 8 | n-Butyl | 30 | Succinc acid | 1 | B | A | B |
| 376 | | | acid | | acetate | | | | | | |
| Example | HF | 0.5 | Peracetic | 8 | n-Butyl | 30 | Glutaric acid | 1 | B | A | B |
| 377 | | | acid | | acetate | | | | | | |
| Example | HF | 0.5 | Peracetic | 8 | n-Butyl | 30 | Adipic acid | 1 | B | A | B |
| 378 | | | acid | | acetate | | | | | | |
| Example | HF | 0.5 | Peracetic | 8 | n-Butyl | 30 | Pimelic acid | 1 | B | A | B |
| 379 | | | acid | | acetate | | | | | | |
| Example | HF | 0.5 | Peracetic | 8 | n-Butyl | 30 | Suberic acid | 1 | B | A | B |
| 380 | | | acid | | acetate | | | | | | |
| Example | HF | 0.5 | Peracetic | 8 | n-Butyl | 30 | Azelaic acid | 1 | B | A | B |
| 381 | | | acid | | acetate | | | | | | |
| Example | HF | 0.5 | Peracetic | 8 | n-Butyl | 30 | Sebacic acid | 1 | B | A | B |
| 382 | | | acid | | acetate | | | | | | |
| Example | HF | 0.5 | Peracetic | 8 | n-Butyl | 30 | Ethylenediaminetetraacetic | 1 | B | A | B |
| 383 | | | acid | | acetate | | acid (EDTA) | | | | |
| Example | HF | 0.5 | Peracetic | 8 | n-Butyl | 30 | Butylenediaminetetraacetic | 1 | B | A | B |
| 384 | | | acid | | acetate | | acid | | | | |
| Example | HF | 0.5 | Peracetic | 8 | n-Butyl | 30 | (1,2-Cyclohexylenedi- | 1 | B | A | B |
| 385 | | | acid | | acetate | | amine)tetraacetic acid (CyDTA) | | | | |
| Example | HF | 0.5 | Peracetic | 8 | n-Butyl | 30 | Diethylenetriaminepentaacetic | 1 | B | A | B |
| 386 | | | acid | | acetate | | acid (DETPA) | | | | |
| Example | HF | 0.5 | Peracetic | 8 | n-Butyl | 30 | Ethylenediaminetetrapropionic | 1 | B | A | B |
| 387 | | | acid | | acetate | | acid | | | | |
| Example | HF | 0.5 | Peracetic | 8 | n-Butyl | 30 | Hydroxyethyl)ethylenediamine- | 1 | B | A | B |
| 388 | | | acid | | acetate | | triacetic acid (HEDTA) | | | | |
| Example | HF | 0.5 | Peracetic | 8 | n-Butyl | 30 | Triethylenetetraminehexacetic | 1 | B | A | B |
| 389 | | | acid | | acetate | | acid (TTHA) | | | | |
| Example | HF | 0.5 | Peracetic | 8 | n-Butyl | 30 | l,3-Diamino-2-hydroxypropane- | 1 | B | A | B |
| 390 | | | acid | | acetate | | N,N,N′,N′-tetraacetic acid (DHPTA) | | | | |

TABLE 14

| | Fluoride ion | | | | | | | | | | |
|---|---|---|---|---|---|---|---|---|---|---|---|
| | source | | Oxidant | | Acetate solvent | | Additive | | | | SiGe |
| | | Amount | | Amount | | Amount | | Amount | SiGe | Si | Surface |
| Table 1-14 | Type | (%) | Type | (%) | Type | (%) | Type | (%) | ER | ER | roughness |
| Example | HF | 0.5 | Peracetic | 8 | n-Butyl | 30 | Methyliminodiacetic acid | 1 | B | A | B |
| 391 | | | acid | | acetate | | | | | | |
| Example | HF | 0.5 | Peracetic | 8 | n-Butyl | 30 | Propylenediaminetetraacetic acid | 1 | B | A | B |
| 392 | | | acid | | acetate | | | | | | |
| Example | HF | 0.5 | Peracetic | 8 | n-Butyl | 30 | Nitrotriacetic acid (NTA) | 1 | B | A | B |
| 393 | | | acid | | acetate | | | | | | |
| Example | HF | 0.5 | Peracetic | 8 | n-Butyl | 30 | Tartaric acid | 1 | B | A | B |
| 394 | | | acid | | acetate | | | | | | |
| Example | HF | 0.5 | Peracetic | 8 | n-Butyl | 30 | Gluconic acid | 1 | B | A | B |
| 395 | | | acid | | acetate | | | | | | |
| Example | HF | 0.5 | Peracetic | 8 | n-Butyl | 30 | Glyceric acid | 1 | B | A | B |
| 396 | | | acid | | acetate | | | | | | |
| Example | HF | 0.5 | Peracetic | 8 | n-Butyl | 30 | Phthalic acid | 1 | B | A | B |
| 397 | | | acid | | acetate | | | | | | |
| Example | HF | 0.5 | Peracetic | 8 | n-Butyl | 30 | Maleic acid | 1 | B | A | B |
| 398 | | | acid | | acetate | | | | | | |
| Example | HF | 0.5 | Peracetic | 8 | n-Butyl | 30 | Mandelic acid | 1 | B | A | B |
| 399 | | | acid | | acetate | | | | | | |
| Example | HF | 0.5 | Peracetic | 8 | n-Butyl | 30 | Lactic acid | 1 | B | A | B |
| 400 | | | acid | | acetate | | | | | | |
| Example | HF | 0.5 | Peracetic | 8 | n-Butyl | 30 | Salicylic acid | 1 | B | A | B |
| 401 | | | acid | | acetate | | | | | | |
| Example | HF | 0.5 | Peracetic | 8 | n-Butyl | 30 | Gallic acid | 1 | B | A | B |
| 402 | | | acid | | acetate | | | | | | |
| Example | HF | 0.5 | Peracetic | 8 | n-Butyl | 30 | Alanine | 1 | C | A | C |
| 403 | | | acid | | acetate | | | | | | |
| Example | HF | 0.5 | Peracetic | 8 | n-Butyl | 30 | Arginine | 1 | C | A | C |
| 404 | | | acid | | acetate | | | | | | |
| Example | HF | 0.5 | Peracetic | 8 | n-Butyl | 30 | Asparagine | 1 | C | A | C |
| 405 | | | acid | | acetate | | | | | | |
| Example | HF | 0.5 | Peracetic | 8 | n-Butyl | 30 | Aspartic acid | 1 | C | A | C |
| 406 | | | acid | | acetate | | | | | | |
| Example | HF | 0.5 | Peracetic | 8 | n-Butyl | 30 | Cysteine | 1 | B | A | B |
| 407 | | | acid | | acetate | | | | | | |
| Example | HF | 0.5 | Peracetic | 8 | n-Butyl | 30 | Glutamine | 1 | C | A | C |
| 408 | | | acid | | acetate | | | | | | |
| Example | HF | 0.5 | Peracetic | 8 | n-Butyl | 30 | Glutamic acid | 1 | C | A | C |
| 409 | | | acid | | acetate | | | | | | |
| Example | HF | 0.5 | Peracetic | 8 | n-Butyl | 30 | Glycine | 1 | C | A | C |
| 410 | | | acid | | acetate | | | | | | |
| Example | HF | 0.5 | Peracetic | 8 | n-Butyl | 30 | Histidine | 1 | C | A | C |
| 411 | | | acid | | acetate | | | | | | |
| Example | HF | 0.5 | Peracetic | 8 | n-Butyl | 30 | soleucine | 1 | C | A | C |
| 412 | | | acid | | acetate | | | | | | |
| Example | HF | 0.5 | Peracetic | 8 | n-Butyl | 30 | Leucine | 1 | C | A | C |
| 413 | | | acid | | acetate | | | | | | |
| Example | HF | 0.5 | Peracetic | 8 | n-Butyl | 30 | Lysine | 1 | C | A | C |
| 414 | | | acid | | acetate | | | | | | |
| Example | HF | 0.5 | Peracetic | 8 | n-Butyl | 30 | Methionine | 1 | C | A | C |
| 415 | | | acid | | acetate | | | | | | |
| Example | HF | 0.5 | Peracetic | 8 | n-Butyl | 30 | Phenylalanine | 1 | C | A | C |
| 416 | | | acid | | acetate | | | | | | |
| Example | HF | 0.5 | Peracetic | 8 | n-Butyl | 30 | Proline | 1 | C | A | C |
| 417 | | | acid | | acetate | | | | | | |
| Example | HF | 0.5 | Peracetic | 8 | n-Butyl | 30 | Serine | 1 | C | A | C |
| 418 | | | acid | | acetate | | | | | | |
| Example | HF | 0.5 | Peracetic | 8 | n-Butyl | 30 | Threonine | 1 | C | A | C |
| 419 | | | acid | | acetate | | | | | | |
| Example | HF | 0.5 | Peracetic | 8 | n-Butyl | 30 | Tryptophan | 1 | C | A | C |
| 420 | | | acid | | acetate | | | | | | |

TABLE 15

| | Fluoride ion | | | | | | | | | | |
|---|---|---|---|---|---|---|---|---|---|---|---|
| | source | | Oxidant | | Acetate solvent | | Additive | | | | SiGe |
| | | Amount | | Amount | | Amount | | Amount | SiGe | Si | Surface |
| Table 1-15 | Type | (%) | Type | (%) | Type | (%) | Type | (%) | ER | ER | roughness |
| Example | HF | 0.5 | Peracetic | 8 | n-Butyl | 30 | Tyrosine | 1 | C | A | C |
| 421 | | | acid | | acetate | | | | | | |
| Example | HF | 0.5 | Peracetic | 8 | n-Butyl | 30 | Valine | 1 | C | A | C |
| 422 | | | acid | | acetate | | | | | | |
| Example | HF | 0.5 | Peracetic | 8 | n-Butyl | 30 | Tetramethylammonium | 1 | B | A | B |
| 423 | | | acid | | acetate | | hydroxide | | | | |
| Example | HF | 0.5 | Peracetic | 8 | n-Butyl | 30 | Tetrapropylammonium | 1 | B | A | B |
| 424 | | | acid | | acetate | | hydroxide | | | | |
| Example | HF | 0.5 | Peracetic | 8 | n-Butyl | 30 | Tetrabutylammonium | 1 | B | A | B |
| 425 | | | acid | | acetate | | hydroxide | | | | |
| Example | HF | 0.5 | Peracetic | 8 | n-Butyl | 30 | Methyltripropylammonium | 1 | B | A | B |
| 426 | | | acid | | acetate | | hydroxide | | | | |
| Example | HF | 0.5 | Peracetic | 8 | n-Butyl | 30 | Methyltributylammonium | 1 | B | A | B |
| 427 | | | acid | | acetate | | hydroxide | | | | |
| Example | HF | 0.5 | Peracetic | 8 | n-Butyl | 30 | Ethyltrimethylammonium | 1 | B | A | B |
| 428 | | | acid | | acetate | | hydroxide | | | | |
| Example | HF | 0.5 | Peracetic | 8 | n-Butyl | 30 | Dimethyldiethylammonium | 1 | B | A | B |
| 429 | | | acid | | acetate | | hydroxide | | | | |
| Example | HF | 0.5 | Peracetic | 8 | n-Butyl | 30 | Benzyltrimethylammonium | 1 | B | A | B |
| 430 | | | acid | | acetate | | hydroxide | | | | |
| Example | HF | 0.5 | Peracetic | 8 | n-Butyl | 30 | (2-Hydroxyethyl)trimethyl- | 1 | B | A | B |
| 431 | | | acid | | acetate | | ammonium hydroxide | | | | |
| Example | HF | 0.5 | Peracetic | 8 | n-Butyl | 30 | Boric acid | 1 | B | A | B |
| 432 | | | acid | | acetate | | | | | | |
| Example | HF | 0.5 | Peracetic | 8 | Isobutyl | 30 | Polyethylene glycol | 0.5 | A | B | B |
| 433 | | | acid | | acetate | | | | | | |
| Example | HF | 0.5 | Peracetic | 8 | Isobutyl | 30 | Polyethyleneimine | 0.5 | A | B | B |
| 434 | | | acid | | acetate | | | | | | |
| Example | HF | 0.5 | Peracetic | 8 | Isobutyl | 30 | Dodecylbenzenesulfonic | 0.5 | A | B | B |
| 435 | | | acid | | acetate | | acid | | | | |
| Example | HF | 0.5 | Peracetic | 8 | Isobutyl | 30 | Dodecyl diphenyl ether | 0.5 | A | B | B |
| 436 | | | acid | | acetate | | disulfonic acid | | | | |
| Example | HF | 0.5 | Peracetic | 8 | Isobutyl | 30 | Phenolsulfonic acid | 0.5 | A | B | B |
| 437 | | | acid | | acetate | | formaldehyde condensate | | | | |
| Example | HF | 0.5 | Peracetic | 8 | Vinyl | 30 | Polyethylene glycol | 0.5 | A | C | C |
| 438 | | | acid | | acetate | | | | | | |
| Example | HF | 0.5 | Peracetic | 8 | Vinyl | 30 | Polyethyleneimine | 0.5 | A | C | C |
| 439 | | | acid | | acetate | | | | | | |
| Example | HF | 0.5 | Peracetic | 8 | Vinyl | 30 | Dodecylbenzenesulfonic | 0.5 | A | C | C |
| 440 | | | acid | | acetate | | acid | | | | |
| Example | HF | 0.5 | Peracetic | 8 | Vinyl | 30 | Dodecyl diphenyl ether | 0.5 | A | C | C |
| 441 | | | acid | | acetate | | disulfonic acid | | | | |
| Example | HF | 0.5 | Peracetic | 8 | Vinyl | 30 | Phenolsulfonic acid | 0.5 | A | C | C |
| 442 | | | acid | | acetate | | formaldehyde condensate | | | | |
| Example | HF | 0.5 | Peracetic | 8 | n-Amyl | 30 | Polyethylene glycol | 0.5 | A | B | B |
| 443 | | | acid | | acetate | | | | | | |
| Example | HF | 0.5 | Peracetic | 8 | n-Amyl | 30 | Polyethyleneimine | 0.5 | A | B | B |
| 444 | | | acid | | acetate | | | | | | |
| Example | HF | 0.5 | Peracetic | 8 | n-Amyl | 30 | Dodecylbenzenesulfonic | 0.5 | A | B | B |
| 445 | | | acid | | acetate | | acid | | | | |
| Example | HF | 0.5 | Peracetic | 8 | n-Amyl | 30 | Dodecyl diphenyl ether | 0.5 | A | B | B |
| 446 | | | acid | | acetate | | disulfonic acid | | | | |
| Example | HF | 0.5 | Peracetic | 8 | n-Amyl | 30 | henolsulfonic acid | 0.5 | A | B | B |
| 447 | | | acid | | acetate | | formaldehyde condensate | | | | |
| Example | HF | 0.5 | Peracetic | 8 | Isoamyl | 30 | Polyethylene glycol | 0.5 | A | B | B |
| 448 | | | acid | | acetate | | | | | | |
| Example | HF | 0.5 | Peracetic | 8 | Isoamyl | 30 | olyethyleneimine | 0.5 | A | B | B |
| 449 | | | acid | | acetate | | | | | | |
| Example | HF | 0.5 | Peracetic | 8 | Isoamyl | 30 | Dodecylbenzenesulfonic | 0.5 | A | B | B |
| 450 | | | acid | | acetate | | acid | | | | |

TABLE 16

| | Fluoride ion | | | | | | | | | | |
|---|---|---|---|---|---|---|---|---|---|---|---|
| | source | | Oxidant | | Acetate solvent | | Additive | | | | SiGe |
| | | Amount | | Amount | | Amount | | Amount | SiGe | Si | Surface |
| Table 1-16 | Type | (%) | Type | (%) | Type | (%) | Type | (%) | ER | ER | roughness |
| Example | HF | 0.5 | Peracetic | 8 | Isoamyl | 30 | Dodecyl diphenyl ether | 0.5 | A | B | B |
| 451 | | | acid | | acetate | | disulfonic acid | | | | |
| Example | HF | 0.5 | Peracetic | 8 | Isoamyl | 30 | Phenolsulfonic acid | 0.5 | A | B | B |
| 452 | | | acid | | acetate | | formaldehyde condensate | | | | |
| Example | HF | 0.5 | Peracetic | 8 | Octyl | 30 | Polyethylene glycol | 0.5 | A | B | B |
| 453 | | | acid | | acetate | | | | | | |
| Example | HF | 0.5 | Peracetic | 8 | Octyl | 30 | Polyethyleneimine | 0.5 | A | B | B |
| 454 | | | acid | | acetate | | | | | | |
| Example | HF | 0.5 | Peracetic | 8 | Octyl | 30 | Dodecylbenzenesulfonic | 0.5 | A | B | B |
| 455 | | | acid | | acetate | | acid | | | | |
| Example | HF | 0.5 | Peracetic | 8 | Octyl | 30 | Dodecyl diphenyl ether | 0.5 | A | B | B |
| 456 | | | acid | | acetate | | disulfonic acid | | | | |
| Example | HF | 0.5 | Peracetic | 8 | Octyl | 30 | Phenolsulfonic acid | 0.5 | A | B | B |
| 457 | | | acid | | acetate | | formaldehyde condensate | | | | |
| Example | HF | 0.5 | Peracetic | 8 | 2-Ethoxyethyl | 30 | Polyethylene glycol | 0.5 | A | B | B |
| 458 | | | acid | | acetate | | | | | | |
| Example | HF | 0.5 | Peracetic | 8 | 2-Ethoxyethyl | 30 | Polyethyleneimine | 0.5 | A | B | B |
| 459 | | | acid | | acetate | | | | | | |
| Example | HF | 0.5 | Peracetic | 8 | 2-Ethoxyethyl | 30 | Dodecylbenzenesulfonic | 0.5 | A | B | B |
| 460 | | | acid | | acetate | | acid | | | | |
| Example | HF | 0.5 | Peracetic | 8 | 2-Ethoxyethyl | 30 | Dodecyl diphenyl ether | 0.5 | A | B | B |
| 461 | | | acid | | acetate | | disulfonic acid | | | | |
| Example | HF | 0.5 | Peracetic | 8 | 2-Ethoxyethyl | 30 | Phenolsulfonic acid | 0.5 | A | B | B |
| 462 | | | acid | | acetate | | formaldehyde condensate | | | | |
| Example | HF | 0.5 | Peracetic | 8 | Phenyl | 30 | Polyethylene glycol | 0.5 | A | C | C |
| 463 | | | acid | | acetate | | | | | | |
| Example | HF | 0.5 | Peracetic | 8 | Phenyl | 30 | Polyethyleneimine | 0.5 | A | C | C |
| 464 | | | acid | | acetate | | | | | | |
| Example | HF | 0.5 | Peracetic | 8 | Phenyl | 30 | Dodecylbenzenesulfonic | 0.5 | A | C | C |
| 465 | | | acid | | acetate | | acid | | | | |
| Example | HF | 0.5 | Peracetic | 8 | Phenyl | 30 | Dodecyl diphenyl ether | 0.5 | A | C | C |
| 466 | | | acid | | acetate | | disulfonic acid | | | | |
| Example | HF | 0.5 | Peracetic | 8 | Phenyl | 30 | Phenolsulfonic acid | 0.5 | A | C | C |
| 467 | | | acid | | acetate | | formaldehyde condensate | | | | |
| Example | HF | 0.5 | Peracetic | 8 | Phenethyl | 30 | Polyethylene glycol | 0.5 | A | C | C |
| 468 | | | acid | | acetate | | | | | | |
| Example | HF | 0.5 | Peracetic | 8 | Phenethyl | 30 | Polyethyleneimine | 0.5 | A | C | C |
| 469 | | | acid | | acetate | | | | | | |
| Example | HF | 0.5 | Peracetic | 8 | Phenethyl | 30 | Dodecylbenzenesulfonic | 0.5 | A | C | C |
| 470 | | | acid | | acetate | | acid | | | | |
| Example | HF | 0.5 | Peracetic | 8 | Phenethyl | 30 | Dodecyl diphenyl ether | 0.5 | A | C | C |
| 471 | | | acid | | acetate | | disulfonic acid | | | | |
| Example | HF | 0.5 | Peracetic | 8 | Phenethyl | 30 | Phenolsulfonic acid | 0.5 | A | C | C |
| 472 | | | acid | | acetate | | formaldehyde condensate | | | | |
| Example | HF | 1 | Peracetic | 8 | Ethyl | 30 | Polyethylene glycol | 0.5 | A | A | A |
| 473 | | | acid | | acetate | | | | | | |
| Example | HF | 1 | Peracetic | 8 | Ethyl | 30 | Polyethyleneimine | 0.5 | A | A | A |
| 474 | | | acid | | acetate | | | | | | |
| Example | HF | 1 | Peracetic | 8 | Ethyl | 30 | Dodecylbenzenesulfonic | 0.5 | A | A | A |
| 475 | | | acid | | acetate | | acid | | | | |
| Example | HF | 1 | Peracetic | 8 | Ethyl | 30 | Dodecyl diphenyl ether | 0.5 | A | A | A |
| 476 | | | acid | | acetate | | disulfonic acid | | | | |
| Example | HF | 1 | Peracetic | 8 | Ethyl | 30 | Phenolsulfonic acid | 0.5 | A | A | A |
| 477 | | | acid | | acetate | | formaldehyde condensate | | | | |
| Example | HF | 1 | Peracetic | 8 | n-Butyl | 30 | Polyethylene glycol | 0.5 | A | A | A |
| 478 | | | acid | | acetate | | | | | | |
| Example | HF | 1 | Peracetic | 8 | n-Butyl | 30 | Polyethyleneimine | 0.5 | A | A | A |
| 479 | | | acid | | acetate | | | | | | |
| Example | HF | 1 | Peracetic | 8 | n-Butyl | 30 | Dodecylbenzenesulfonic | 0.5 | A | A | A |
| 480 | | | acid | | acetate | | acid | | | | |

TABLE 17

| | Fluoride ion | | | | | | | | | | |
|---|---|---|---|---|---|---|---|---|---|---|---|
| | source | | Oxidant | | Acetate solvent | | Additive | | | | SiGe |
| | | Amount | | Amount | | Amount | | Amount | SiGe | Si | Surface |
| Table 1-17 | Type | (%) | Type | (%) | Type | (%) | Type | (%) | ER | ER | roughness |
| Example | HF | 1 | Peracetic | 8 | n-Butyl | 30 | Dodecyl diphenyl ether | 0.5 | A | A | A |
| 481 | | | acid | | acetate | | disulfonic acid | | | | |
| Example | HF | 1 | Peracetic | 8 | n-Butyl | 30 | Phenolsulfonic acid | 0.5 | A | A | A |
| 482 | | | acid | | acetate | | formaldehyde condensate | | | | |
| Example | HF | 0.5 | Peracetic | 4 | Ethyl | 30 | Polyethylene glycol | 0.5 | B | A | A |
| 483 | | | acid | | acetate | | | | | | |
| Example | HF | 0.5 | Peracetic | 4 | Ethyl | 30 | Polyethyleneimine | 0.5 | B | A | A |
| 484 | | | acid | | acetate | | | | | | |
| Example | HF | 0.5 | Peracetic | 4 | Ethyl | 30 | Dodecylbenzenesulfonic | 0.5 | B | A | A |
| 485 | | | acid | | acetate | | acid | | | | |
| Example | HF | 0.5 | Peracetic | 4 | Ethyl | 30 | Dodecyl diphenyl ether | 0.5 | B | A | A |
| 486 | | | acid | | acetate | | disulfonic acid | | | | |
| Example | HF | 0.5 | Peracetic | 4 | Ethyl | 30 | Phenolsulfonic acid | 0.5 | B | A | A |
| 487 | | | acid | | acetate | | formaldehyde condensate | | | | |
| Example | HF | 0.5 | Peracetic | 4 | n-Butyl | 30 | Polyethylene glycol | 0.5 | B | A | A |
| 488 | | | acid | | acetate | | | | | | |
| Example | HF | 0.5 | Peracetic | 4 | n-Butyl | 30 | Polyethyleneimine | 0.5 | B | A | A |
| 489 | | | acid | | acetate | | | | | | |
| Example | HF | 0.5 | Peracetic | 4 | n-Butyl | 30 | Dodecylbenzenesulfonic | 0.5 | B | A | A |
| 490 | | | acid | | acetate | | acid | | | | |
| Example | HF | 0.5 | Peracetic | 4 | n-Butyl | 30 | Dodecyl diphenyl ether | 0.5 | B | A | A |
| 491 | | | acid | | acetate | | disulfonic acid | | | | |
| Example | HF | 0.5 | Peracetic | 4 | n-Butyl | 30 | henolsulfonic acid | 0.5 | B | A | A |
| 492 | | | acid | | acetate | | formaldehyde condensate | | | | |
| Example | NH4F | 0.5 | Peracetic | 8 | Ethyl | 30 | Polyethylene glycol | 0.5 | A | A | A |
| 493 | | | acid | | acetate | | | | | | |
| Example | NH4F | 0.5 | Peracetic | 8 | Ethyl | 30 | olyethyleneimine | 0.5 | A | A | A |
| 494 | | | acid | | acetate | | | | | | |
| Example | NH4F | 0.5 | Peracetic | 8 | Ethyl | 30 | Dodecylbenzenesulfonic | 0.5 | A | A | A |
| 495 | | | acid | | acetate | | acid | | | | |
| Example | NH4F | 0.5 | Peracetic | 8 | Ethyl | 30 | Dodecyl diphenyl ether | 0.5 | A | A | A |
| 496 | | | acid | | acetate | | disulfonic acid | | | | |
| Example | NH4F | 0.5 | Peracetic | 8 | Ethyl | 30 | Phenolsulfonic acid | 0.5 | A | A | A |
| 497 | | | acid | | acetate | | formaldehyde condensate | | | | |
| Example | NH4F | 0.5 | Peracetic | 8 | n-Butyl | 30 | Polyethylene glycol | 0.5 | A | A | A |
| 498 | | | acid | | acetate | | | | | | |
| Example | NH4F | 0.5 | Peracetic | 8 | n-Butyl | 30 | Polyethyleneimine | 0.5 | A | A | A |
| 499 | | | acid | | acetate | | | | | | |
| Example | NH4F | 0.5 | Peracetic | 8 | n-Butyl | 30 | Dodecylbenzenesulfonic | 0.5 | A | A | A |
| 500 | | | acid | | acetate | | acid | | | | |
| Example | NH4F | 0.5 | Peracetic | 8 | n-Butyl | 30 | Dodecyl diphenyl ether | 0.5 | A | A | A |
| 501 | | | acid | | acetate | | disulfonic acid | | | | |
| Example | NH4F | 0.5 | Peracetic | 8 | n-Butyl | 30 | Phenolsulfonic acid | 0.5 | A | A | A |
| 502 | | | acid | | acetate | | formaldehyde condensate | | | | |
| Example | HF | 0.5 | Hydrogen | 8 | Ethyl | 30 | Polyethylene glycol | 0.5 | A | A | A |
| 503 | | | peroxide | | acetate | | | | | | |
| Example | HF | 0.5 | Hydrogen | 8 | Ethyl | 30 | Polyethyleneimine | 0.5 | A | A | A |
| 504 | | | peroxide | | acetate | | | | | | |
| Example | HF | 0.5 | Hydrogen | 8 | Ethyl | 30 | Dodecylbenzenesulfonic | 0.5 | A | A | A |
| 505 | | | peroxide | | acetate | | acid | | | | |
| Example | HF | 0.5 | Hydrogen | 8 | Ethyl | 30 | Dodecyl diphenyl ether | 0.5 | A | A | A |
| 506 | | | peroxide | | acetate | | disulfonic acid | | | | |
| Example | HF | 0.5 | Hydrogen | 8 | Ethyl | 30 | Phenolsulfonic acid | 0.5 | A | A | A |
| 507 | | | peroxide | | acetate | | formaldehyde condensate | | | | |
| Example | HF | 0.5 | Hydrogen | 8 | n-Butyl | 30 | Polyethylene glycol | 0.5 | A | A | A |
| 508 | | | peroxide | | acetate | | | | | | |
| Example | HF | 0.5 | Hydrogen | 8 | n-Butyl | 30 | Polyethyleneimine | 0.5 | A | A | A |
| 509 | | | peroxide | | acetate | | | | | | |
| Example | HF | 0.5 | Hydrogen | 8 | n-Butyl | 30 | Dodecylbenzenesulfonic | 0.5 | A | A | A |
| 510 | | | peroxide | | acetate | | acid | | | | |

TABLE 18

| | Fluoride ion | | | | | | | | | | |
|---|---|---|---|---|---|---|---|---|---|---|---|
| | source | | Oxidant | | Acetate solvent | | Additive | | | | SiGe |
| | | Amount | | Amount | | Amount | | Amount | SiGe | Si | Surface |
| Table 1-18 | Type | (%) | Type | (%) | Type | (%) | Type | (%) | ER | ER | roughness |
| Example | HF | 0.5 | Hydrogen | 8 | n-Butyl | 30 | Dodecyl diphenyl ether | 0.5 | A | A | A |
| 511 | | | peroxide | | acetate | | disulfonic acid | | | | |
| Example | HF | 0.5 | Hydrogen | 8 | n-Butyl | 30 | Phenolsulfonic acid | 0.5 | A | A | A |
| 512 | | | peroxide | | acetate | | formaldehyde condensate | | | | |
| Example | HF | 0.5 | Peracetic | 8 | Ethyl | 30 | Polyethylene glycol | 1 | A | A | A |
| 513 | | | acid | | acetate | | | | | | |
| Example | HF | 0.5 | Peracetic | 8 | Ethyl | 30 | Polyethyleneimine | 1 | A | A | A |
| 514 | | | acid | | acetate | | | | | | |
| Example | HF | 0.5 | Peracetic | 8 | Ethyl | 30 | Dodecylbenzenesulfonic | 1 | A | A | A |
| 515 | | | acid | | acetate | | acid | | | | |
| Example | HF | 0.5 | Peracetic | 8 | Ethyl | 30 | Dodecyl diphenyl ether | 1 | A | A | A |
| 516 | | | acid | | acetate | | disulfonic acid | | | | |
| Example | HF | 0.5 | Peracetic | 8 | Ethyl | 30 | Phenolsulfonic acid | 1 | A | A | A |
| 517 | | | acid | | acetate | | formaldehyde condensate | | | | |
| Example | HF | 0.5 | Peracetic | 8 | n-Butyl | 30 | Polyethylene glycol | 1 | A | A | A |
| 518 | | | acid | | acetate | | | | | | |
| Example | HF | 0.5 | Peracetic | 8 | n-Butyl | 30 | Polyethyleneimine | 1 | A | A | A |
| 519 | | | acid | | acetate | | | | | | |
| Example | HF | 0.5 | Peracetic | 8 | n-Butyl | 30 | Dodecylbenzenesulfonic | 1 | A | A | A |
| 520 | | | acid | | acetate | | acid | | | | |
| Example | HF | 0.5 | Peracetic | 8 | n-Butyl | 30 | Dodecyl diphenyl ether | 1 | A | A | A |
| 521 | | | acid | | acetate | | disulfonic acid | | | | |
| Example | HF | 0.5 | Peracetic | 8 | n-Butyl | 30 | Phenolsulfonic acid | 1 | A | A | A |
| 522 | | | acid | | acetate | | formaldehyde condensate | | | | |
| Example | HF | 0.5 | Peracetic | 8 | Ethyl | 50 | Polyethylene glycol | 0.5 | B | A | A |
| 523 | | | acid | | acetate | | | | | | |
| Example | HF | 0.5 | Peracetic | 8 | Ethyl | 50 | Polyethyleneimine | 0.5 | B | A | A |
| 524 | | | acid | | acetate | | | | | | |
| Example | HF | 0.5 | Peracetic | 8 | Ethyl | 50 | Dodecylbenzenesulfonic | 0.5 | B | A | A |
| 525 | | | acid | | acetate | | acid | | | | |
| Example | HF | 0.5 | Peracetic | 8 | Ethyl | 50 | Dodecyl diphenyl ether | 0.5 | B | A | A |
| 526 | | | acid | | acetate | | disulfonic acid | | | | |
| Example | HF | 0.5 | Peracetic | 8 | Ethyl | 50 | Phenolsulfonic acid | 0.5 | B | A | A |
| 527 | | | acid | | acetate | | formaldehyde condensate | | | | |
| Example | HF | 0.5 | Peracetic | 8 | n-Butyl | 50 | Polyethylene glycol | 0.5 | B | A | A |
| 528 | | | acid | | acetate | | | | | | |
| Example | HF | 0.5 | Peracetic | 8 | n-Butyl | 50 | Polyethyleneimine | 0.5 | B | A | A |
| 529 | | | acid | | acetate | | | | | | |
| Example | HF | 0.5 | Peracetic | 8 | n-Butyl | 50 | Dodecylbenzenesulfonic | 0.5 | B | A | A |
| 530 | | | acid | | acetate | | acid | | | | |
| Example | HF | 0.5 | Peracetic | 8 | n-Butyl | 50 | Dodecyl diphenyl ether | 0.5 | B | A | A |
| 531 | | | acid | | acetate | | disulfonic acid | | | | |
| Example | HF | 0.5 | Peracetic | 8 | n-Butyl | 50 | Phenolsulfonic acid | 0.5 | B | A | A |
| 532 | | | acid | | acetate | | formaldehyde condensate | | | | |

TABLE 19

| | Fluoride ion | | | | | | | | | | |
|---|---|---|---|---|---|---|---|---|---|---|---|
| | source | | Oxidant | | Acetate solvent | | Additive | | | | SiGe |
| | | Amount | | Amount | | Amount | | Amount | SiGe | Si | Surface |
| Table 1-19 | Type | (%) | Type | (%) | Type | (%) | Type | (%) | ER | ER | roughness |
| Example | HF | 0.5 | Peracetic | 8 | Ethyl | 30 | Polyethylene glycol | 0.5 | A | A | A |
| 533 | NH4F | 0.5 | acid | | acetate | | | | | | |
| Example | HF | 0.5 | Peracetic | 8 | Ethyl | 30 | Polyethyleneimine | 0.5 | A | A | A |
| 534 | NH4F | 0.5 | acid | | acetate | | | | | | |
| Example | HF | 0.5 | Peracetic | 8 | Ethyl | 30 | Dodecylbenzenesulfonic | 0.5 | A | A | A |
| 535 | NH4F | 0.5 | acid | | acetate | | acid | | | | |
| Example | HF | 0.5 | Peracetic | 8 | Ethyl | 30 | Dodecyl diphenyl ether | 0.5 | A | A | A |
| 536 | NH4F | 0.5 | acid | | acetate | | disulfonic acid | | | | |
| Example | HF | 0.5 | Peracetic | 8 | Ethyl | 30 | Phenolsulfonic acid | 0.5 | A | A | A |
| 537 | NH4F | 0.5 | acid | | acetate | | formaldehyde condensate | | | | |
| Example | HF | 0.5 | Peracetic | 8 | n-Butyl | 30 | Polyethylene glycol | 0.5 | A | A | A |
| 538 | NH4F | 0.5 | acid | | acetate | | | | | | |
| Example | HF | 0.5 | Peracetic | 8 | n-Butyl | 30 | Polyethyleneimine | 0.5 | A | A | A |
| 539 | NH4F | 0.5 | acid | | acetate | | | | | | |
| Example | HF | 0.5 | Peracetic | 8 | n-Butyl | 30 | Dodecylbenzenesulfonic | 0.5 | A | A | A |
| 540 | NH4F | 0.5 | acid | | acetate | | acid | | | | |
| Example | HF | 0.5 | Peracetic | 8 | n-Butyl | 30 | Dodecyl diphenyl ether | 0.5 | A | A | A |
| 541 | NH4F | 0.5 | acid | | acetate | | disulfonic acid | | | | |
| Example | HF | 0.5 | Peracetic | 8 | n-Butyl | 30 | Phenolsulfonic acid | 0.5 | A | A | A |
| 542 | NH4F | 0.5 | acid | | acetate | | formaldehyde condensate | | | | |
| Example | HF | 0.5 | Peracetic | 8 | Ethyl | 30 | Polyethylene glycol | 0.5 | A | A | A |
| 543 | | | acid | | acetate | | Polyethyleneimine | 0.5 | | | |
| Example | HF | 0.5 | Peracetic | 8 | Ethyl | 30 | Dodecylbenzenesulfonic | 0.5 | A | A | A |
| 544 | | | acid | | acetate | | acid | | | | |
| | | | | | | | Dodecyl diphenyl ether | 0.5 | | | |
| | | | | | | | disulfonic acid | | | | |

TABLE 20

| | Fluoride ion | | | | | | | | | | |
|---|---|---|---|---|---|---|---|---|---|---|---|
| | source | | Oxidant | | Acetate solvent | | Additive | | | | SiGe |
| | | Amount | Type | Amount | Type | Amount | Type | Amount | SiGe | Si | Surface |
| Table 1-20 | Type | (%) | | (%) | | (%) | | (%) | ER | ER | roughness |
| Example | HF | 0.5 | Peracetic | 8 | Ethyl | 30 | Dodecylbenzenesulfonic | 0.5 | A | A | A |
| 545 | | | acid | | acetate | | acid | | | | |
| | | | | | | | Dodecyl diphenyl ether | 0.5 | | | |
| | | | | | | | disulfonic acid | | | | |
| | | | | | | | Phenolsulfonic acid | 0.5 | | | |
| | | | | | | | formaldehyde condensate | | | | |
| Example | HF | 0.5 | Peracetic | 8 | n-Butyl | 30 | Polyethylene glycol | 0.5 | A | A | A |
| 546 | | | acid | | acetate | | Polyethyleneimine | 0.5 | | | |
| Example | HF | 0.5 | Peracetic | 8 | n-Butyl | 30 | Dodecylbenzenesulfonic | 0.5 | A | A | A |
| 547 | | | acid | | acetate | | acid | | | | |
| | | | | | | | Dodecyl diphenyl ether | 0.5 | | | |
| | | | | | | | disulfonic acid | | | | |
| Example | HF | 0.5 | Peracetic | 8 | n-Butyl | 30 | Dodecylbenzenesulfonic | 0.5 | A | A | A |
| 548 | | | acid | | acetate | | acid | | | | |
| | | | | | | | Dodecyl diphenyl ether | 0.5 | | | |
| | | | | | | | disulfonic acid | | | | |
| | | | | | | | Phenolsulfonic acid | 0.5 | | | |
| | | | | | | | formaldehyde condensate | | | | |
| Example | HF | 0.5 | Peracetic | 8 | Ethyl | 30 | Polyethylene glycol | 0.5 | B | A | A |
| 549 | | | acid | | acetate | | | | | | |
| | | | | | n-Butyl | 30 | | | | | |
| | | | | | acetate | | | | | | |
| Example | HF | 0.5 | Peracetic | 8 | Ethyl | 30 | Polyethyleneimine | 0.5 | B | A | A |
| 550 | | | acid | | acetate | | | | | | |
| | | | | | n-Butyl | 30 | | | | | |
| | | | | | acetate | | | | | | |
| Example | HF | 0.5 | Peracetic | 8 | Ethyl | 30 | Dodecylbenzenesulfonic | 0.5 | B | A | A |
| 551 | | | acid | | acetate | | acid | | | | |
| | | | | | n-Butyl | 30 | | | | | |
| | | | | | acetate | | | | | | |
| Example | HF | 0.5 | Peracetic | 8 | Ethyl | 30 | Dodecyl diphenyl ether | 0.5 | B | A | A |
| 552 | | | acid | | acetate | | disulfonic acid | | | | |
| | | | | | n-Butyl | 30 | | | | | |
| | | | | | acetate | | | | | | |
| Example | HF | 0.5 | Peracetic | 8 | Ethyl | 30 | Phenolsulfonic acid | 0.5 | B | A | A |
| 553 | | | acid | | acetate | | formaldehyde condensate | | | | |
| | | | | | n-Butyl | 30 | | | | | |
| | | | | | acetate | | | | | | |
| Comparative | — | — | Peracetic | 8 | — | | | | E | A | D |
| Example 1 | | | acid | | | | | | | | |
| Comparative | HF | 0.5 | — | — | — | | | | E | C | D |
| Example 2 | | | | | | | | | | | |
| Comparative | HF | 0.5 | Peracetic | 8 | — | | | | D | C | D |
| Example 3 | | | acid | | | | | | | | |
| Comparative | HF | 0.5 | Peracetic | 8 | — | | 3-Aminopropylsilanetriol | 0.5 | C | C | D |
| Example 4 | | | acid | | | | | | | | |
| Comparative | HF | 0.5 | Peracetic | 8 | — | | 3-Aminopropyltriethoxysilane | 0.5 | C | C | D |
| Example 5 | | | acid | | | | | | | | |
| Comparative | HF | 0.5 | Peracetic | 8 | — | | methyltris(methylethylketox- | 0.5 | C | C | D |
| Example 6 | | | acid | | | | ime)silane | | | | |
| Comparative | HF | 0.5 | Peracetic | 8 | — | | Hexamethyldisilazane | 0.5 | C | C | D |
| Example 7 | | | acid | | | | | | | | |
| Comparative | HF | 0.5 | Peracetic | 8 | n-Butyl | 30 | 3-Aminopropylsilanetriol | 0.5 | C | C | D |
| Example 8 | | | acid | | acetate | | | | | | |

From the results shown in the tables, it has been confirmed that with the treatment liquid according to the embodiment of the present invention, the objects of the present invention can be achieved.

It has been confirmed that, in view of further improving the effect of the present invention, the specific additive is preferably one or more kinds of substances selected from the group consisting of a nonionic polymer, an anionic polymer, a nonionic surfactant, an anionic surfactant, a cationic surfactant, a nitrogen atom-containing polymer, alkylamine, alkanolamine, and a nitrogen-containing heterocyclic compound, an organic carboxylic acid other than an amino acid, cysteine, a quaternary ammonium salt, and a boron-containing compound, and more preferably one or more kinds of substances selected from the group consisting of polyethylene glycol, polyethyleneimine, dodecyl benzenesulfonic acid, a phenolsulfonic acid formaldehyde condensate, and dodecyl diphenyl ether disulfonic acid (refer to the comparison of results of Examples 6 to 211, and the like).

It has been confirmed that, in view of further improving the effect of the present invention, one or more kinds of compounds selected from the group consisting of methyl acetate, ethyl acetate, n-propyl acetate, isopropyl acetate, t-butyl acetate, n-butyl acetate, isobutyl acetate, n-amyl acetate, isoamyl acetate, octyl acetate, and 2-ethoxyethyl acetate are preferable, and one or more kinds of compounds selected from the group consisting of ethyl acetate and n-butyl acetate are more preferable (refer to the comparison of results of Examples 5, 32, 216, 221, 226, 253, 437, 442, 447, 452, 457, 462, 467, and 472, and the like).

It has been confirmed that, in view of further improving the effect of the present invention, the content of the oxidant is preferably 5% to 15% by mass with respect to the total mass of the treatment liquid (refer to the comparison between the results of Example 6 and the results of Example 483, and the like).

It has been confirmed that, in view of further improving the effect of the present invention, the content of the acetate solvent is preferably 20% to 45% by mass with respect to the total mass of the treatment liquid (refer to the comparison between the results of Example 6 and the results of Example 523, and the like).

[Test Y]

The dissolution rate for silicon-germanium and the surface roughness of the treated silicon-germanium film were evaluated in the same manner as in Test X, except that only the treatment liquid of Example 27 in Test X was used as a treatment liquid, and the ratio between silicon and germanium (Si:Ge (element ratio)) in silicon-germanium was changed.

The results are shown in the following table.

In the table, the column of “SiGe ratio” shows the ratio between silicon and germanium (Si:Ge (element ratio)) in the silicon-germanium film used for the test.

TABLE 2

| | SiGe | SiGe | SiGe |
|---|---|---|---|
| | ratio | ER | Surface roughness |
| Example B1 | 95:5 | B | B |
| Example B2 | 75:25 | A | A |
| Example B3 | 50:50 | A | B |
| Example B4 | 98:2 | C | B |
| Example B5 | 45:55 | A | C |

From the results shown in the table, it has been confirmed that, in view of further improving the effect of the present invention, the ratio between silicon and germanium (Si:Ge (element ratio)) in SiGe treated with the treatment liquid is preferably 95:5 to 50:50 and more preferably 85:15 to 65:35.

[Test Z]

Two high-density polyethylene (HDPE) bottles having a volume of 20 L were prepared, and each of these bottles was filled with 15 L of the treatment liquid of Example 27 in Test X. The degassing cap shown in FIG. 1 capable of being screwed on and fixed to a bottle was put on one of the two bottles. A cap that does not comprise a degassing mechanism and is capable of being screwed on and fixed to a bottle was put on the other bottle.

The two obtained bottles were left to stand at room temperature (25° C.) for 30 days, and then the appearance of each bottle was observed. As a result, no change was observed in the appearance of the bottle with the degassing cap. On the other hand, the bottle with the cap that does not comprise a degassing mechanism was found to be inflated.

From these results, it has been confirmed that it is preferable to store and/or provide the treatment liquid in the form of a treatment liquid container in which the treatment liquid is stored in a container having a degassing cap.

### EXPLANATION OF REFERENCES

100 treatment liquid container

102 cap body

104 waterproof breathable film

106 breathable layer

108 bottle body

110 treatment liquid

112 flow passage

200 object to be treated

202 substrate

204 SiGe

206 other materials

What is claimed is:

1. A treatment liquid comprising:
a fluoride ion source;
an oxidant;
an acetate solvent; and
an additive,
wherein the additive is an additive that does not contain a Si atom.

2. The treatment liquid according to claim 1,
wherein the additive is one or more kinds of substances selected from the group consisting of a nonionic polymer, an anionic polymer, a nonionic surfactant, an anionic surfactant, a cationic surfactant, an amphoteric surfactant, a nitrogen atom-containing polymer, alkylamine, aromatic amine, alkanolamine, and a nitrogen-containing heterocyclic compound, an organic carboxylic acid, a quaternary ammonium salt, and a boron-containing compound.

3. The treatment liquid according to claim 2,
wherein the additive contains the nonionic polymer, and
the nonionic polymer is one or more kinds of polymers selected from the group consisting of polyethylene glycol, polypropylene glycol, polyoxyethylene polyoxypropylene glycol, and polyvinyl alcohol.

4. The treatment liquid according to claim 2,
wherein the additive contains the anionic polymer, and
the anionic polymer is one or more kinds of polymers selected from the group consisting of polyacrylic acid, polystyrene sulfonic acid, a phenolsulfonic acid formaldehyde condensate, an aryl phenolsulfonic acid formaldehyde condensate, and salts of these.

5. The treatment liquid according to claim 2,
wherein the additive contains the nitrogen atom-containing polymer, and
the nitrogen atom-containing polymer is one or more kinds of polymers selected from the group consisting of polyvinylpyrrolidone, polyethyleneimine, polyallylamine, polyvinylamine, polyacrylamide, a dimethylamine.epihalohydrin-based polymer, a hexadimethrine salt, polydiallylamine, a polydimethyldiallylammonium salt, poly(4-vinylpyridine), polyornithine, polylysine, polyarginine, polyhistidine, polyvinylimidazole, and polymethyldiallylamine

6. The treatment liquid according to claim 2,
wherein the additive contains the nonionic surfactant, and
the nonionic surfactant is one or more kinds of compounds selected from the group consisting of polyoxyethylene alkyl ether and polyoxyethylene alkyl allyl ether.

7. The treatment liquid according to claim 2,
wherein the additive contains the anionic surfactant, and
the anionic surfactant is one or more kinds of compounds selected from the group consisting of alkyl benzenesulfonic acid, alkyl naphthalenesulfonic acid, alkyl diphenyl ether disulfonic acid, polyoxyethylene alkyl ether sulfonic acid, alkyl carboxylic acid, polyoxyethylene alkyl ether carboxylic acid, alkyl phosphonic acid, polyoxyethylene phosphonic acid, polyoxyethylene alkyl ether phosphoric acid, polyoxyethylene alkyl phenyl ether phosphoric acid, and salts of these.

8. The treatment liquid according to claim 7,
wherein the anionic surfactant contains at least any of the alkyl benzenesulfonic acid and a salt thereof, and
the alkyl benzenesulfonic acid is dodecyl benzenesulfonic acid.

9. The treatment liquid according to claim 7,
wherein the anionic surfactant contains at least any of the alkyl naphthalenesulfonic acid and a salt thereof, and
the alkyl naphthalenesulfonic acid is one or more kinds of compounds selected from the group consisting of propyl naphthalenesulfonic acid, triisopropyl naphthalenesulfonic acid, and dibutyl naphthalenesulfonic acid.

10. The treatment liquid according to claim 7,
wherein the anionic surfactant contains at least any of the alkyl diphenyl ether disulfonic acid and a salt thereof, and
the alkyl diphenyl ether disulfonic acid is dodecyl diphenyl ether disulfonic acid.

11. The treatment liquid according to claim 7,
wherein the anionic surfactant contains at least any of the polyoxyethylene alkyl ether sulfonic acid and a salt thereof, and
the polyoxyethylene alkyl ether sulfonic acid is one or more kinds of compounds selected from the group consisting of polyoxyethylene lauryl ether sulfonic acid, polyoxyethylene oleyl ether sulfonic acid, and polyoxyethylene octyldodecyl ether sulfonic acid.

12. The treatment liquid according to claim 7,
wherein the anionic surfactant contains at least any of the alkyl carboxylic acid and a salt thereof, and
the alkyl carboxylic acid is one or more kinds of compounds selected from the group consisting of dodecanoic acid, hexadecanoic acid, oleic acid, juniperic acid, stearic acid, 12-hydroxystearic acid, perfluorooctanoic acid, perfluoroheptanoic acid, and perfluorodecanoic acid.

13. The treatment liquid according to claim 7,
wherein the anionic surfactant contains at least any of the polyoxyethylene alkyl ether carboxylic acid and a salt thereof, and
the polyoxyethylene alkyl ether carboxylic acid is one or more kinds of compounds selected from the group consisting of polyoxyethylene lauryl ether carboxylic acid, polyoxyethylene dodecyl ether carboxylic acid, and polyoxyethylene tridecyl ether carboxylic acid.

14. The treatment liquid according to claim 7,
wherein the anionic surfactant contains at least any of the alkyl phosphonic acid and a salt thereof, and
the alkyl phosphonic acid is one or more kinds of compounds selected from the group consisting of bis(2-ethylhexyl)phosphate, dioctadecylphosphate, octadecylphosphate, dodecylphosphate, decyl phosphonic acid, dodecyl phosphonic acid, tetradecyl phosphonic acid, hexadecyl phosphonic acid, and octadecyl phosphonic acid.

15. The treatment liquid according to claim 7,
wherein the anionic surfactant contains at least any of the polyoxyethylene alkyl ether phosphoric acid and a salt thereof, and
the polyoxyethylene alkyl ether phosphoric acid is polyoxyethylene lauryl ether phosphoric acid.

16. The treatment liquid according to claim 2,
wherein the additive contains the cationic surfactant, and
the cationic surfactant is one or more kinds of compounds among a hydroxide, a chloride, and a bromide of one or more kinds of compounds selected from the group consisting of cetyltrimethylammonium, stearyltrimethylammonium, laurylpyridinium, cetylpyridinium, 4-(4-diethylaminophenylazo)-1-(4-nitrobenzyl)pyridinium, benzalkonium, benzethonium, benzyldimethyldodecylammonium, benzyldimethylhexadecylammonium, hexadecyltrimethylammonium, dimethyldioctadecylammonium, dodecyltrimethylammonium, didodecyldimethylammonium, tetraheptylammonium, tetrakis(decyl)ammonium, and dimethyldihexadecylammonium.

17. The treatment liquid according to claim 2,
wherein the additive contains the amphoteric surfactant, and
the amphoteric surfactant is one or more kinds of compounds selected from the group consisting of cocamidopropyl betaine, N,N-dimethyldodecylamine N-oxide, lauryl dimethylaminoacetic acid betaine, and lauryldimethylamine oxide.

18. The treatment liquid according to claim 2,
wherein the additive contains the alkylamine, and
the alkylamine is one or more kinds of compounds selected from the group consisting of ethylenediamine, diethylenetriamine, triethylenetetramine, tetraethylenepentamine, pentaethylenehexamine, tetramethylethylenediamine, hexamethylenediamine, methylamine, dimethylamine, trimethylamine, ethylamine, diethylamine, triethylamine, 2-ethylhexylamine, cyclohexylamine, phenethylamine, and m-xylylenediamine.

19. The treatment liquid according to claim 2,
wherein the additive contains the aromatic amine, and
the aromatic amine is one or more kinds of compounds selected from the group consisting of aniline and toluidine.

20. The treatment liquid according to claim 2,
wherein the additive contains the alkanolamine, and
the alkanolamine is one or more kinds of compounds selected from the group consisting of diethanolamine, diisopropanolamine, triisopropanolamine, 2-(2-aminoethylamino)ethanol, 2-(2-aminoethoxy)ethanol, triethanolamine, N-ethylethanolamine, N,N-dimethylethanolamine, N,N-diethylethanolamine, N-methyldiethanolamine, N-ethyldiethanolamine, cyclohexylamine diethanol, and N-methylethanolamine.

21. The treatment liquid according to claim 2,
wherein the additive contains the nitrogen-containing heterocyclic compound, and
the nitrogen-containing heterocyclic compound is one or more kinds of compounds selected from the group consisting of pyrrolidine, piperidine, piperazine, morpholine, pyrrole, pyrazole, imidazole, pyridine, pyrimidine, pyrazine, oxazole, thiazole, and 4-dimethylaminopyridine.

22. The treatment liquid according to claim 2,
wherein the additive contains the organic carboxylic acid, and
the organic carboxylic acid is one or more kinds of compounds selected from the group consisting of citric acid, 2-methylpropane-1,2,3-tricarboxylic acid, benzene-1,2,3-tricarboxylic acid, propane-1,2,3-tricarboxylic acid, 1,cis-2,3-propanetricarboxylic acid, butane-1,2,3,4-tetracarboxylic acid, cyclopentane tetra-1,2,3,4-carboxylic acid, benzene-1,2,4,5-tetracarboxylic acid, benzenepentacarboxylic acid, benzenehexacarboxylic acid, oxalic acid, malonic acid, succinic acid, glutaric acid, adipic acid, pimelic acid, suberic acid, azelaic acid, sebacic acid, ethylenediaminetetraacetic acid, butylenediaminetetraacetic acid, tetraacetic acid, diethylenetriaminepentaacetic acid, ethylenediaminetetrapropionic acid, (hydroxyethyl)ethylenediaminetriacetic acid, triethylenetetraminehexacetic acid, 1,3-diamino-2-hydroxypropane-N,N,N′,N′-tetraacetic acid, methyliminodiacetic acid, propylenediaminetetraacetic acid, nitrotriacetic acid, tartaric acid, gluconic acid, glyceric acid, phthalic acid, maleic acid, mandelic acid, lactic acid, salicylic acid, and gallic acid.

23. The treatment liquid according to claim 2,
wherein the additive contains the organic carboxylic acid, and
the organic carboxylic acid is an amino acid.

24. The treatment liquid according to claim 23,
wherein the amino acid is one or more kinds of amino acids selected from the group consisting of alanine, arginine, aspartic acid, cysteine, glutamine, glutamic acid, glycine, histidine, isoleucine, leucine, lysine, methionine, phenylalanine, proline, serine, threonine, tryptophan, tyrosine, and valine.

25. The treatment liquid according to claim 2,
wherein the additive contains the quaternary ammonium salt, and
the quaternary ammonium salt is one or more kinds of compounds among a hydroxide, a chloride, and a bromide of one or more kinds of compounds selected from the group consisting of tetramethylammonium, tetraethylammonium, tetrapropylammonium, tetrabutylammonium, methyltripropylammonium, methyltributylammonium, ethyltrimethylammonium, dimethyldiethylammonium, benzyltrimethylammonium, and (2-hydroxyethyl)trimethylammonium.

26. The treatment liquid according to claim 2,
wherein the additive contains the boron-containing compound, and
the boron-containing compound is boric acid.

27. The treatment liquid according to claim 1,
wherein the additive is one or more kinds of substances selected from the group consisting of polyethylene glycol, polyethyleneimine, dodecyl benzenesulfonic acid, a phenolsulfonic acid formaldehyde condensate, and dodecyl diphenyl ether disulfonic acid.

28. The treatment liquid according to claim 1,
wherein the acetate solvent is one or more kinds of compounds selected from the group consisting of methyl acetate, ethyl acetate, n-propyl acetate, isopropyl acetate, t-butyl acetate, n-butyl acetate, isobutyl acetate, vinyl acetate, n-amyl acetate, isoamyl acetate, octyl acetate, 2-ethoxyethyl acetate, phenyl acetate, and phenethyl acetate.

29. The treatment liquid according to claim 1,
wherein the acetate solvent is one or more kinds of compounds selected from the group consisting of ethyl acetate and n-butyl acetate.

30. The treatment liquid according to claim 1,
wherein the oxidant is a peroxide.

31. The treatment liquid according to claim 1,
wherein a content of the oxidant is less than 10% by mass with respect to a total mass of the treatment liquid.

32. The treatment liquid according to claim 1,
wherein the treatment liquid is used for an object to be treated containing SiGe to remove at least a part of SiGe contained in the object to be treated.

33. The treatment liquid according to claim 1,
wherein the treatment liquid is used for an object to be treated containing SiGe to removes at least a part of SiGe contained in the object to be treated, and
an element ratio of Si:Ge in the SiGe is in a range of 95:5 to 50:50.

34. The treatment liquid according to claim 1,
wherein the treatment liquid is used for an object to be treated containing a metal hard mask containing one or more kinds of substances among Cu, Co, W, AlOₓ, AlN, AlOₓN_{y}, WOₓ, Ti, TiN, ZrOₓ, HfOₓ and TaOₓ, where x represents a number of 1 to 3 and y represents a number of 1 or 2.

35. A treatment liquid container comprising:
a container; and
the treatment liquid according to claim 1 stored in the container,
wherein the container has a degassing mechanism that adjusts internal pressure of the container.
